(19) United States
(12) Patent Application Publication
(10) Pub. No.: US 2026/0313892 A1
(43) Pub. Date: Oct. 8, 2026

(54) THREE-DIMENSIONAL MEMORY DEVICE CONTAINING PERIPHERAL CIRCUIT WITH FIN FIELD EFFECT TRANSISTORS AND METHOD OF MAKING THE SAME

(71) Applicant: Sandisk Technologies, Inc., Milpitas, CA (US)

(72) Inventors: Satoru MAYUZUMI, Cupertino, CA (US); Eiichi FUJIKURA, Yokkaichi (JP); Yangyin CHEN, Leuven (BE); Mohan DUNGA, Santa Clara, CA (US)

(21) Appl. No.: 19/715,601

(22) Filed: Jun. 22, 2026

Related U.S. Application Data
(63) Continuation-in-part of application No. 18/396,150, filed on Dec. 26, 2023.
Application No. 18/396,150 is a continuation-in-part of application No. 18/361,550, filed on Jul. 28, 2023.
(60) Provisional application No. 63/499,822, filed on May 3, 2023.

(51) Int. Cl. H10B 43/20; H10B 43/10; H10D 80/30; H10D 84/83; H10W 90/00

(52) U.S. Cl. CPC H10B 43/20; H10B 43/10; H10D 80/30; H10D 84/8311; H10D 84/8312; H10D 84/834; H10W 90/792

(57) ABSTRACT

A semiconductor structure includes a logic die containing a fin field effect transistor having at least one semiconductor fin, and a planar field effect transistor, and a memory die containing a three-dimensional memory device bonded to the logic die.

### RELATED APPLICATIONS

This application is a continuation-in-part (CIP) application of U.S. application Ser. No. 18/396,150 filed on Dec. 26, 2023, which is a CIP application of U.S. application Ser. No. 18/361,550 filed on Jul. 28, 2023, which claims priority from U.S. Provisional Application Ser. No. 63/499,822 filed on May 3, 2023, the entire contents of which are incorporated herein by reference.

### FIELD

The present disclosure relates generally to the field of semiconductor devices, and particularly to a semiconductor device including a three-dimensional memory array and a peripheral circuit including fin field effect transistors and methods for manufacturing the same.

### BACKGROUND

Three-dimensional vertical NAND strings having one bit per cell are disclosed in an article by T. Endoh et al., titled “Novel Ultra High-Density Memory With A Stacked-Surrounding Gate Transistor (S-SGT) Structured Cell”, IEDM Proc. (2001) 33-36.

### SUMMARY

According to an aspect of the present disclosure, a semiconductor structure comprises a logic die containing a fin field effect transistor (finFET), and a memory die bonded to the logic die. The memory die comprises a three-dimensional memory device. The finFET comprises at least one semiconductor fin extending along a first horizontal direction; a finFET channel region located in the at least one semiconductor fin; a finFET source extension region contacting the finFET channel region; a finFET drain extension region contacting the finFET channel region; a finFET source region contacting the finFET source extension region; a finFET drain region contacting the finFET drain extension region; a finFET gate electrode overlying the finFET channel region; and a finFET gate dielectric located between the finFET channel region and the finFET gate electrode.

### BRIEF DESCRIPTION OF THE DRAWINGS

FIG. 1 is a schematic vertical cross-sectional view of a first exemplary structure for forming a memory die after formation of a stopper insulating layer, source-level material layers, and an alternating stack of insulating layers and sacrificial material layers over a substrate according to an embodiment of the present disclosure.

FIG. 2 is a schematic vertical cross-sectional view of the first exemplary structure after formation of stepped surfaces and a retro-stepped dielectric material portion according to an embodiment of the present disclosure.

FIG. 3A is a schematic vertical cross-sectional view of the first exemplary structure after forming memory openings and support openings according to an embodiment of the present disclosure.

FIG. 3B is a top-down view of the first exemplary structure of FIG. 3A. The vertical plane A-A′ is the cut plane of the vertical cross-sectional view of FIG. 3A.

FIG. 4 is a schematic vertical cross-sectional view of the first exemplary structure after formation of support pillar structures according to an embodiment of the present disclosure.

FIG. 5A-5D are sequential vertical cross-sectional views of a memory opening during formation of a memory opening fill structure according to an embodiments of the present disclosure.

FIG. 6A is a vertical cross-sectional view of the first exemplary structure after formation of memory opening fill structures according to an embodiment of the present disclosure.

FIG. 6B is a top-down view of the first exemplary structure of FIG. 6A. The vertical plane A-A′ is the cut plane of the vertical cross-sectional view of FIG. 6A.

FIG. 7A is a vertical cross-sectional view of the first exemplary structure after formation of isolation trenches according to an embodiment of the present disclosure.

FIG. 7B is a top-down view of the first exemplary structure of FIG. 7A. The vertical plane A-A′ is the cut plane of the vertical cross-sectional view of FIG. 7A.

FIG. 8 is a vertical cross-sectional view of the first exemplary structure after formation of a source-level cavity according to an embodiment of the present disclosure.

FIG. 9 is a vertical cross-sectional view of the first exemplary structure after formation of a source contact layer according to an embodiment of the present disclosure.

FIG. 10 is a vertical cross-sectional view of the first exemplary structure after formation of laterally-extending cavities according to an embodiment of the present disclosure.

FIG. 11 is a vertical cross-sectional view of the first exemplary structure after formation of electrically conductive layers according to an embodiment of the present disclosure.

FIG. 12A is a vertical cross-sectional view of the first exemplary structure after formation of lateral isolation trench fill structures and contact via structures according to an embodiment of the present disclosure.

FIG. 12B is a top-down view of the first exemplary structure of FIG. 12A. The vertical plane A-A′ is the cut plane of the vertical cross-sectional view of FIG. 12A.

FIG. 13 is a vertical cross-sectional view of the first exemplary structure after formation of a memory die according to an embodiment of the present disclosure.

FIG. 14A is a vertical cross-sectional view of a second exemplary structure for forming a logic die after formation of semiconductor fins and a semiconductor active region according to an embodiment of the present disclosure.

FIG. 14B is a top-down view of the second exemplary structure of FIG. 14A. The vertical plane A-A′ is the cut plane of the vertical cross-sectional view of FIG. 14A.

FIG. 15A is a vertical cross-sectional view of the second exemplary structure after formation of a dielectric isolation layer according to an embodiment of the present disclosure.

FIG. 15B is a top-down view of the second exemplary structure of FIG. 15A. The vertical plane A-A′ is the cut plane of the vertical cross-sectional view of FIG. 15A.

FIG. 16A is a vertical cross-sectional view of the second exemplary structure after formation of gate cavities according to an embodiment of the present disclosure.

FIG. 16B is a top-down view of the second exemplary structure of FIG. 16A. The vertical plane A-A′ is the cut plane of the vertical cross-sectional view of FIG. 16A.

FIG. 16C is a vertical cross-sectional view of the second exemplary structure along the vertical plane C-C′ of FIG. 16B.

FIG. 17A is a vertical cross-sectional view of the second exemplary structure after formation of gate dielectrics according to an embodiment of the present disclosure.

FIG. 17B is a top-down view of the second exemplary structure of FIG. 17A. The vertical plane A-A′ is the cut plane of the vertical cross-sectional view of FIG. 17A.

FIG. 17C is a vertical cross-sectional view of the second exemplary structure along the vertical plane C-C′ of FIG. 17B.

FIG. 18A is a vertical cross-sectional view of the second exemplary structure after formation of a gate electrode material layer according to an embodiment of the present disclosure.

FIG. 18B is a top-down view of the second exemplary structure of FIG. 18A. The vertical plane A-A′ is the cut plane of the vertical cross-sectional view of FIG. 18A.

FIG. 18C is a vertical cross-sectional view of the second exemplary structure along the vertical plane C-C′ of FIG. 18B.

FIGS. 19A and 19D are vertical cross-sectional views of the second exemplary structure after formation of a finFET gate electrode according to alternative embodiments of the present disclosure.

FIG. 19B is a top-down view of the second exemplary structure of FIG. 19A. The vertical plane A-A′ is the cut plane of the vertical cross-sectional view of FIG. 19A.

FIG. 19C is a vertical cross-sectional view of the second exemplary structure along the vertical plane C-C′ of FIG. 19B.

FIG. 20A is a vertical cross-sectional view of the second exemplary structure after formation of finFET source/drain extension regions according to an embodiment of the present disclosure.

FIG. 20B is a top-down view of the second exemplary structure of FIG. 20A. The vertical plane A-A′ is the cut plane of the vertical cross-sectional view of FIG. 20A.

FIG. 20C is a vertical cross-sectional view of the second exemplary structure along the vertical plane C-C′ of FIG. 20B.

FIG. 21A is a vertical cross-sectional view of the second exemplary structure after formation of a gate-level dielectric layer according to an embodiment of the present disclosure.

FIG. 21B is a top-down view of the second exemplary structure of FIG. 21A. The vertical plane A-A′ is the cut plane of the vertical cross-sectional view of FIG. 21A.

FIG. 21C is a vertical cross-sectional view of the second exemplary structure along the vertical plane C-C′ of FIG. 21B.

FIGS. 22A and 22C are vertical cross-sectional views of the second exemplary structure after formation of a planar-FET gate electrode according to alternative embodiments of the present disclosure.

FIG. 22B is a top-down view of the second exemplary structure of FIG. 22A. The vertical plane A-A′ is the cut plane of the vertical cross-sectional view of FIG. 22A.

FIG. 23A is a vertical cross-sectional view of the second exemplary structure after formation of planar-FET source/drain extension regions and a dielectric gate spacer according to an embodiment of the present disclosure.

FIG. 23B is a top-down view of the second exemplary structure of FIG. 23A. The vertical plane A-A′ is the cut plane of the vertical cross-sectional view of FIG. 23A.

FIG. 24A is a vertical cross-sectional view of the second exemplary structure after formation of source/drain openings through the gate-level dielectric layer according to an embodiment of the present disclosure.

FIG. 24B is a top-down view of the second exemplary structure of FIG. 24A. The vertical plane A-A′ is the cut plane of the vertical cross-sectional view of FIG. 24A.

FIG. 24C is a vertical cross-sectional view of the second exemplary structure along the vertical plane C-C′ of FIG. 24B.

FIG. 25A is a vertical cross-sectional view of the second exemplary structure after formation of source/drain regions according to an embodiment of the present disclosure.

FIG. 25B is a top-down view of the second exemplary structure of FIG. 25A. The vertical plane A-A′ is the cut plane of the vertical cross-sectional view of FIG. 25A.

FIG. 25C is a vertical cross-sectional view of the second exemplary structure along the vertical plane C-C′ of FIG. 25B.

FIG. 26A is a vertical cross-sectional view of the second exemplary structure after formation of metal-semiconductor alloy regions according to an embodiment of the present disclosure.

FIG. 26B is a top-down view of the second exemplary structure of FIG. 26A. The vertical plane A-A′ is the cut plane of the vertical cross-sectional view of FIG. 26A.

FIG. 26C is a vertical cross-sectional view of the second exemplary structure along the vertical plane C-C′ of FIG. 26B.

FIG. 27A is a vertical cross-sectional view of the second exemplary structure after formation of a contact-level dielectric layer according to an embodiment of the present disclosure.

FIG. 27B is a top-down view of the second exemplary structure of FIG. 27A. The vertical plane A-A′ is the cut plane of the vertical cross-sectional view of FIG. 27A.

FIG. 27C is a vertical cross-sectional view of the second exemplary structure along the vertical plane C-C′ of FIG. 27B.

FIG. 28A is a vertical cross-sectional view of the second exemplary structure after formation of contact via structures according to an embodiment of the present disclosure.

FIG. 28B is a top-down view of the second exemplary structure of FIG. 28A. The vertical plane A-A′ is the cut plane of the vertical cross-sectional view of FIG. 28A.

FIG. 28C is a vertical cross-sectional view of the second exemplary structure along the vertical plane C-C′ of FIG. 28B.

FIG. 29A is a vertical cross-sectional view of an alternative configuration of the second exemplary structure after formation of contact via structures according to an embodiment of the present disclosure.

FIG. 29B is a top-down view of the second exemplary structure of FIG. 29A. The vertical plane A-A′ is the cut plane of the vertical cross-sectional view of FIG. 29A.

FIG. 29C is a vertical cross-sectional view of the second exemplary structure along the vertical plane C-C′ of FIG. 29B.

FIG. 30 is a vertical cross-sectional view of a logic die incorporating the second exemplary structure(s) illustrated in FIG. 28A-28C and/or FIG. 29A-29C according to an embodiment of the present disclosure.

FIG. 31 is a vertical cross-sectional view of an exemplary bonded assembly of the memory die illustrated in FIG. 13 and a logic die illustrated in FIG. 30 according to an embodiment of the present disclosure.

FIG. 32A is a vertical cross-sectional view of a third exemplary structure after recessing a second region of a logic-side substrate according to an embodiment of the present disclosure.

FIG. 32B is a top-down view of the third exemplary structure of FIG. 32A. The vertical plane A-A′ is the cut plane of the view of FIG. 32A.

FIG. 33A is a vertical cross-sectional view of the third exemplary structure after formation of a second gate dielectric and a planar-FET gate electrode material layer according to an embodiment of the present disclosure.

FIG. 33B is a top-down view of the third exemplary structure of FIG. 33A. The vertical plane A-A′ is the cut plane of the view of FIG. 33A.

FIG. 34A is a vertical cross-sectional view of the third exemplary structure after formation of a pad silicon oxide layer and a hard mask layer according to an embodiment of the present disclosure.

FIG. 34B is a top-down view of the third exemplary structure of FIG. 34A. The vertical plane A-A′ is the cut plane of the view of FIG. 34A.

FIG. 35A is a vertical cross-sectional view of the third exemplary structure after formation of a continuous recess cavity according to an embodiment of the present disclosure.

FIG. 35B is a top-down view of the third exemplary structure of FIG. 35A. The vertical plane A-A′ is the cut plane of the view of FIG. 35A.

FIG. 36A is a vertical cross-sectional view of the third exemplary structure after formation of a dielectric isolation layer according to an embodiment of the present disclosure.

FIG. 36B is a top-down view of the third exemplary structure of FIG. 36A. The vertical plane A-A′ is the cut plane of the view of FIG. 36A.

FIG. 37A is a vertical cross-sectional view of the third exemplary structure after formation of a gate cavity according to an embodiment of the present disclosure.

FIG. 37B is a top-down view of the third exemplary structure of FIG. 37A. The vertical plane A-A′ is the cut plane of the view of FIG. 37A.

FIG. 38A is a vertical cross-sectional view of the third exemplary structure after formation of sacrificial semiconductor oxide layers according to an embodiment of the present disclosure.

FIG. 38B is a top-down view of the third exemplary structure of FIG. 38A. The vertical plane A-A′ is the cut plane of the view of FIG. 38A.

FIG. 39A is a vertical cross-sectional view of the third exemplary structure after removal of the pad silicon oxide layer and the hard mask layer according to an embodiment of the present disclosure.

FIG. 39B is a top-down view of the third exemplary structure of FIG. 39A. The vertical plane A-A′ is the cut plane of the view of FIG. 39A.

FIG. 40A is a vertical cross-sectional view of the third exemplary structure after formation of a first gate dielectric layer and a finFET gate electrode material layer according to an embodiment of the present disclosure.

FIG. 40B is a top-down view of the third exemplary structure of FIG. 40A. The vertical plane A-A′ is the cut plane of the view of FIG. 40A.

FIG. 41A is a vertical cross-sectional view of the third exemplary structure after removal of portions of the first gate dielectric layer and the finFET gate electrode material layer in a second device region according to an embodiment of the present disclosure.

FIG. 41B is a top-down view of the third exemplary structure of FIG. 41A. The vertical plane A-A′ is the cut plane of the view of FIG. 41A.

FIG. 42A is a vertical cross-sectional view of the third exemplary structure after deposition of an upper gate electrode material layer according to an embodiment of the present disclosure.

FIG. 42B is a top-down view of the third exemplary structure of FIG. 42A. The vertical plane A-A′ is the cut plane of the view of FIG. 42A.

FIG. 43A is a vertical cross-sectional view of the third exemplary structure after formation of a finFET gate electrode and a planar-FET gate electrode according to an embodiment of the present disclosure.

FIG. 43B is a top-down view of the third exemplary structure of FIG. 43A. The vertical plane A-A′ is the cut plane of the view of FIG. 43A.

FIG. 44A is a vertical cross-sectional view of the third exemplary structure after formation of source/drain extension regions according to an embodiment of the present disclosure.

FIG. 44B is a top-down view of the third exemplary structure of FIG. 44A. The vertical plane A-A′ is the cut plane of the view of FIG. 44A.

FIG. 45A is a vertical cross-sectional view of the third exemplary structure after formation of dielectric gate spacers and deep source/drain regions according to an embodiment of the present disclosure.

FIG. 45B is a top-down view of the third exemplary structure of FIG. 45A. The vertical plane A-A′ is the cut plane of the view of FIG. 45A.

FIG. 46A is a vertical cross-sectional view of the third exemplary structure after formation of a contact-level dielectric layer according to an embodiment of the present disclosure.

FIG. 46B is a top-down view of the third exemplary structure of FIG. 46A. The vertical plane A-A′ is the cut plane of the view of FIG. 46A.

FIG. 46C is a vertical cross-sectional view of the third exemplary structure along the vertical plane C-C′ of FIG. 46B.

FIG. 46D is a vertical cross-sectional view of the third exemplary structure along the vertical plane D-D′ of FIG. 46B.

FIG. 47A is a vertical cross-sectional view of a fourth exemplary structure after formation of a continuous recess cavity and a dielectric isolation layer according to an embodiment of the present disclosure.

FIG. 47B is a top-down view of the fourth exemplary structure of FIG. 47A. The vertical plane A-A′ is the cut plane of the view of FIG. 47A.

FIG. 48A is a vertical cross-sectional view of the fourth exemplary structure after formation of a second gate dielectric and a planar-FET gate electrode material layer according to an embodiment of the present disclosure.

FIG. 48B is a top-down view of the fourth exemplary structure of FIG. 48A. The vertical plane A-A′ is the cut plane of the view of FIG. 48A.

FIG. 49A is a vertical cross-sectional view of the fourth exemplary structure after removal of a portion of the planar-FET gate electrode material layer in a first device region according to an embodiment of the present disclosure.

FIG. 49B is a top-down view of the fourth exemplary structure of FIG. 49A. The vertical plane A-A′ is the cut plane of the view of FIG. 49A.

FIG. 50A is a vertical cross-sectional view of the fourth exemplary structure after formation of a gate cavity according to an embodiment of the present disclosure.

FIG. 50B is a top-down view of the fourth exemplary structure of FIG. 50A. The vertical plane A-A′ is the cut plane of the view of FIG. 50A.

FIG. 51A is a vertical cross-sectional view of the fourth exemplary structure after formation of a first gate dielectric layer and a finFET gate electrode material layer according to an embodiment of the present disclosure.

FIG. 51B is a top-down view of the fourth exemplary structure of FIG. 51A. The vertical plane A-A′ is the cut plane of the view of FIG. 51A.

FIG. 52A is a vertical cross-sectional view of the fourth exemplary structure after removal of portions of the first gate dielectric layer and the finFET gate electrode material layer in a second device region according to an embodiment of the present disclosure.

FIG. 52B is a top-down view of the fourth exemplary structure of FIG. 52A. The vertical plane A-A′ is the cut plane of the view of FIG. 52A.

FIG. 53A is a vertical cross-sectional view of the fourth exemplary structure after formation of a finFET gate electrode and a planar-FET gate electrode according to an embodiment of the present disclosure.

FIG. 53B is a top-down view of the fourth exemplary structure of FIG. 53A. The vertical plane A-A′ is the cut plane of the view of FIG. 53A.

FIG. 54A is a vertical cross-sectional view of the fourth exemplary structure after formation of source/drain extension regions according to an embodiment of the present disclosure.

FIG. 54B is a top-down view of the fourth exemplary structure of FIG. 54A. The vertical plane A-A′ is the cut plane of the view of FIG. 54A.

FIG. 55A is a vertical cross-sectional view of the fourth exemplary structure after formation of dielectric gate spacers and deep source/drain regions according to an embodiment of the present disclosure.

FIG. 55B is a top-down view of the fourth exemplary structure of FIG. 55A. The vertical plane A-A′ is the cut plane of the view of FIG. 55A.

FIG. 56A is a vertical cross-sectional view of the fourth exemplary structure after formation of a contact-level dielectric layer according to an embodiment of the present disclosure.

FIG. 56B is a top-down view of the fourth exemplary structure of FIG. 56A. The vertical plane A-A′ is the cut plane of the view of FIG. 56A.

FIG. 56C is a vertical cross-sectional view of the fourth exemplary structure along the vertical plane C-C′ of FIG. 56B.

FIG. 56D is a vertical cross-sectional view of the fourth exemplary structure along the vertical plane D-D′ of FIG. 56B.

FIG. 57A is a vertical cross-sectional view of a first device region and a second device region of a fifth exemplary structure after formation of a dielectric isolation layer according to an embodiment of the present disclosure.

FIG. 57B is a vertical cross-sectional view of a third device region of the fifth exemplary structure at the processing steps of FIG. 57A.

FIG. 57C is a top-down view of the fifth exemplary structure illustrated in FIGS. 57A and 57B. The vertical plane A-A′ is the cut plane of the view of the FIG. 57A. The vertical plane B-B′ is the cut plane of the view of FIG. 57B.

FIG. 58A is a vertical cross-sectional view of the first device region and the second device region of the fifth exemplary structure after formation of a first gate cavity according to an embodiment of the present disclosure.

FIG. 58B is a vertical cross-sectional view of the third device region of the fifth exemplary structure at the processing steps of FIG. 58A.

FIG. 59A is a vertical cross-sectional view of the first device region and the second device region of the fifth exemplary structure after formation of a first gate dielectric layer according to an embodiment of the present disclosure.

FIG. 59B is a vertical cross-sectional view of the third device region of the fifth exemplary structure at the processing steps of FIG. 59A.

FIG. 60A is a vertical cross-sectional view of the first device region and the second device region of the fifth exemplary structure after formation of a second gate cavity according to an embodiment of the present disclosure.

FIG. 60B is a vertical cross-sectional view of the third device region of the fifth exemplary structure at the processing steps of FIG. 60A.

FIG. 61A is a vertical cross-sectional view of the first device region and the second device region of the fifth exemplary structure after formation of a first gate electrode material layer and a dielectric capping layer according to an embodiment of the present disclosure.

FIG. 61B is a vertical cross-sectional view of the third device region of the fifth exemplary structure at the processing steps of FIG. 61A.

FIG. 62A is a vertical cross-sectional view of the first device region and the second device region of the fifth exemplary structure after formation of a third gate cavity according to an embodiment of the present disclosure.

FIG. 62B is a vertical cross-sectional view of the third device region of the fifth exemplary structure at the processing steps of FIG. 62A.

FIG. 63A is a vertical cross-sectional view of the first device region and the second device region of the fifth exemplary structure after formation of a third gate dielectric and a third gate electrode material layer according to an embodiment of the present disclosure.

FIG. 63B is a vertical cross-sectional view of the third device region of the fifth exemplary structure at the processing steps of FIG. 63A.

FIG. 64A is a vertical cross-sectional view of the first device region and the second device region of the fifth exemplary structure after removal of portions of the third gate electrode material layer from the first device region and the second device region according to an embodiment of the present disclosure.

FIG. 64B is a vertical cross-sectional view of the third device region of the fifth exemplary structure at the processing steps of FIG. 64A.

FIG. 65A is a vertical cross-sectional view of the first device region and the second device region of the fifth exemplary structure after formation of gate electrodes and source/drain extension regions according to an embodiment of the present disclosure.

FIG. 65B is a vertical cross-sectional view of the third device region of the fifth exemplary structure at the processing steps of FIG. 65A.

FIG. 66A is a vertical cross-sectional view of the first device region and the second device region of the fifth exemplary structure after formation of dielectric gate spacers and deep source/drain regions according to an embodiment of the present disclosure.

FIG. 66B is a vertical cross-sectional view of the third device region of the fifth exemplary structure at the processing steps of FIG. 66A.

FIG. 67A is a vertical cross-sectional view of the first device region and the second device region of the fifth exemplary structure after formation of a contact-level dielectric layer according to an embodiment of the present disclosure.

FIG. 67B is a vertical cross-sectional view of the third device region of the fifth exemplary structure at the processing steps of FIG. 67A.

FIG. 68A is a schematic perspective view of a sixth exemplary structure according to an embodiment of the present disclosure.

FIG. 68B is a top-down schematic view of the sixth exemplary structure of FIG. 68A. The size of the regions in the schematic perspective view of FIG. 68A is not to scale with the top-down schematic view of FIG. 68B.

FIG. 69A is a schematic perspective view of a seventh exemplary structure according to an embodiment of the present disclosure.

FIG. 69B is a top-down schematic view of the seventh exemplary structure of FIG. 69A. The size of the regions in the schematic perspective view of FIG. 69A is not to scale with the top-down schematic view of FIG. 69B.

### DETAILED DESCRIPTION

As discussed above, the present disclosure is directed to a three-dimensional memory array and a peripheral circuit including fin field effect transistors and methods for manufacturing the same, of which various aspects are described below. Embodiments of the disclosure can be employed to form a semiconductor structure including a multilevel memory structure, non-limiting examples of which include three-dimensional memory devices comprising a plurality of memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

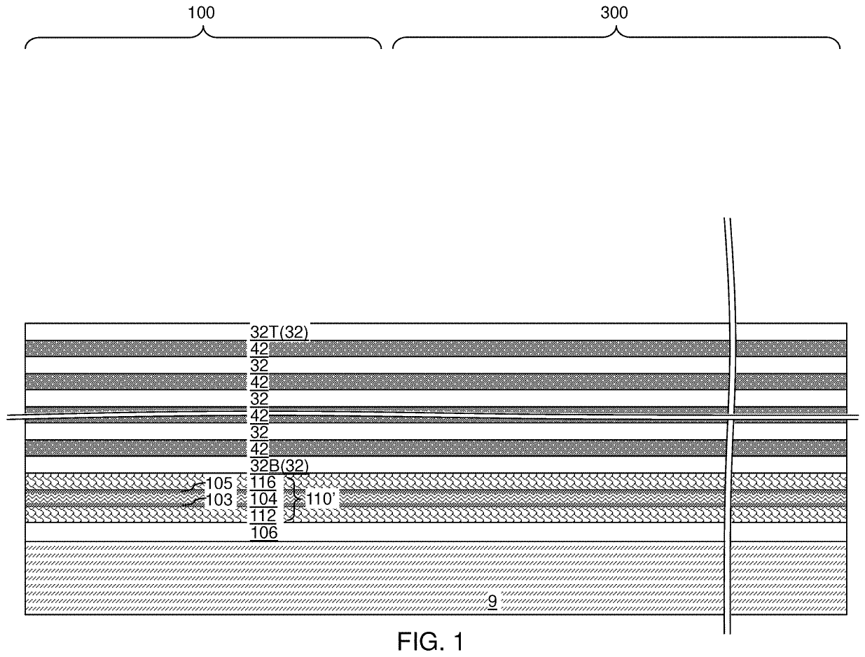

Referring to FIG. 1, a first exemplary structure according to an embodiment of the present disclosure is illustrated. The first exemplary structure comprises a substrate 9, which may be a semiconductor substrate. For example, the substrate 9 may comprise a commercially available silicon wafer. Alternatively, the substrate 9 may comprise any material that may be removed selective the materials of insulating layers 32 and dielectric material portions to be subsequently formed.

If the substrate 9 comprises a sacrificial carrier substrate, then an optional insulating material layer can be formed on a top surface of the substrate 9. The insulating material layer can be subsequently employed as a stopping material layer for a process that removes the substrate 9, and is herein referred to as a stopper insulating layer 106, or as a backside pad dielectric layer. Alternatively, the stopper insulating layer 106 may be omitted.

In-process source-level material layers 110′ can be formed over the substrate 9 and over the stopper insulating layer 106 (if present). The in-process source-level material layers 110′ may include various layers that are subsequently modified to form source-level material layers. The source-level material layers, upon formation, include a source contact layer that functions as a common source region for vertical field effect transistors of a three-dimensional memory device. In one embodiment, the in-process source-level material layers 110′ may include, from bottom to top, a lower source-level semiconductor layer 112, an optional lower sacrificial liner 103, a source-level sacrificial layer 104, an optional upper sacrificial liner 105, and an upper source-level semiconductor layer 116.

The lower source-level semiconductor layer 112 and the upper source-level semiconductor layer 116 may include a doped semiconductor material such as doped polysilicon or doped amorphous silicon. The conductivity type of the lower source-level semiconductor layer 112 and the upper source-level semiconductor layer 116 may be the opposite of the conductivity of vertical semiconductor channels to be subsequently formed. For example, if the vertical semiconductor channels to be subsequently formed have a doping of a first conductivity type, the lower source-level semiconductor layer 112 and the upper source-level semiconductor layer 116 have a doping of a second conductivity type that is the opposite of the first conductivity type. The thickness of each of the lower source-level semiconductor layer 112 and the upper source-level semiconductor layer 116 may be in a range from 10 nm to 300 nm, such as from 20 nm to 150 nm, although lesser and greater thicknesses may also be used.

The source-level sacrificial layer 104 includes a sacrificial material that may be removed selective to the lower sacrificial liner 103 (or selective to the lower source-level semiconductor layer 112) and the upper sacrificial liner 105 (or selective to the upper source-level semiconductor layer 116). In one embodiment, the source-level sacrificial layer 104 may include an insulating material, such as silicon nitride, or a semiconductor material such as undoped amorphous silicon or polysilicon. The thickness of the source-level sacrificial layer 104 may be in a range from 30 nm to 400 nm, such as from 60 nm to 200 nm, although lesser and greater thicknesses may also be used. The lower sacrificial liner 103 (if present) and the upper sacrificial liner 105 (if present) include materials that may function as an etch stop material during removal of the source-level sacrificial layer 104. For example, the lower sacrificial liner 103 and the upper sacrificial liner 105 may include silicon oxide, silicon nitride, and/or a dielectric metal oxide. In one embodiment, each of the lower sacrificial liner 103 and the upper sacrificial liner 105 may include a silicon oxide layer having a thickness in a range from 2 nm to 30 nm, although lesser and greater thicknesses may also be used.

An alternating stack of first material layers and second material layers can be formed over the in-process source-level material layer 110′. The first material layers may be insulating layers, and the second material layers may be spacer material layers. In one embodiment, the spacer material layers may comprise sacrificial material layers 42. In this case, an alternating stack (32, 42) of insulating layers 32 and sacrificial material layers 42 can be formed over the in-process source-level material layer 110′. The insulating layers 32 comprise an insulating material such as undoped silicate glass or a doped silicate glass, and the sacrificial material layers 42 comprise a sacrificial material such as silicon nitride or a silicon-germanium alloy. In one embodiment, the insulating layers 32 (i.e., the first material layers) may comprise silicon oxide layers, and the sacrificial material layers 42 (i.e., the second material layers) may comprise silicon nitride layers. The alternating stack (32, 42) may comprise multiple repetitions of a unit layer stack including an insulating layer 32 and a sacrificial material layer 42. The total number of repetitions of the unit layer stack within the alternating stack (32, 42) may be, for example, in a range from 8 to 1,024, such as from 32 to 256, although lesser and greater number of repetitions may also be employed. The topmost one of the insulating layers 32 is hereafter referred to as a topmost insulating layer 32T. The bottommost one of the insulating layers 32 is an insulating layer 32 that is most proximal to the substrate 9 is herein referred to as a bottommost insulating layer 32B.

Each of the insulating layers 32 other than the topmost insulating layer 32 may have a thickness in a range from 20 nm to 100 nm, such as from 30 nm to 60 nm, although lesser and greater thicknesses may also be employed. Each of the sacrificial material layers 42 may have a thickness in a range from 20 nm to 100 nm, such as from 30 nm to 60 nm, although lesser and greater thicknesses may also be employed. In one embodiment, the topmost insulating layer 32 may have a thickness of about one half of the thickness of other insulating layers 32.

The first exemplary structure comprises a memory array region 100 in which a three-dimensional array of memory elements is to be subsequently formed, and a contact region 300 in which layer contact via structures contacting word lines are to be subsequently formed.

While an embodiment is described in which the spacer material layers are formed as sacrificial material layers 42, the spacer material layers may be formed as electrically conductive layers in an alternative embodiment. Generally, spacer material layers may be formed as, or may be subsequently replaced at least partly with, electrically conductive layers.

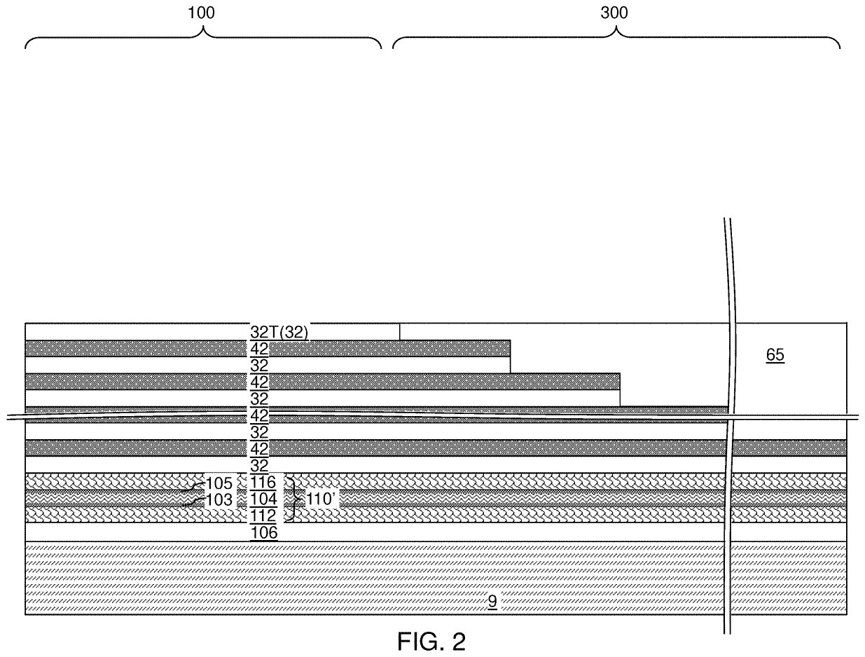

Referring to FIG. 2, stepped surfaces are formed in the contact region 300. As used herein, “stepped surfaces” refer to a set of surfaces that include at least two horizontal surfaces and at least two vertical surfaces such that each horizontal surface is adjoined to a first vertical surface that extends upward from a first edge of the horizontal surface, and is adjoined to a second vertical surface that extends downward from a second edge of the horizontal surface. A stepped cavity is formed within the volume from which portions of the alternating stack (32, 42) are removed through formation of the stepped surfaces. A “stepped cavity” refers to a cavity having stepped surfaces.

The stepped cavity can have various stepped surfaces such that the horizontal cross-sectional shape of the stepped cavity changes in steps as a function of the vertical distance from the top surface of the in-process source-level material layer 110′. In one embodiment, the stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each sacrificial material layer 42 other than a topmost sacrificial material layer 42 within the alternating stack (32, 42) laterally extends farther than any overlying sacrificial material layer 42 within the alternating stack (32, 42) in the terrace region. The stepped surfaces of the alternating stack (32, 42) continuously extend from a bottommost layer within the alternating stack (32, 42) (such as the bottommost insulating layer 32B) to a topmost layer within the alternating stack (32, 42) (such as the topmost insulating layer 32T).

A retro-stepped dielectric material portion 65 (i.e., an insulating fill material portion) can be formed in the stepped cavity by deposition of a dielectric material therein. For example, a dielectric material such as silicon oxide can be deposited in the stepped cavity. Excess portions of the deposited dielectric material can be removed from above the top surface of the topmost insulating layer 32T, for example, by chemical mechanical planarization (CMP). The remaining portion of the deposited dielectric material filling the stepped cavity constitutes the retro-stepped dielectric material portion 65. As used herein, a “retro-stepped” element refers to an element that has stepped surfaces and a horizontal cross-sectional area that increases monotonically as a function of a vertical distance from a top surface of a substrate on which the element is present. If silicon oxide is employed for the retro-stepped dielectric material portion 65, the silicon oxide of the retro-stepped dielectric material portion 65 may, or may not, be doped with dopants such as B, P, and/or F.

Optionally, drain-select-level isolation structures (not shown) can be formed through the topmost insulating layer 32T and a subset of the sacrificial material layers 42 located at drain-select-levels. The drain-select-level isolation structures can be formed, for example, by forming drain-select-level lateral isolation trenches and filling the drain-select-level lateral isolation trenches with a dielectric material such as silicon oxide. Excess portions of the dielectric material can be removed from above the top surface of the topmost insulating layer 32T.

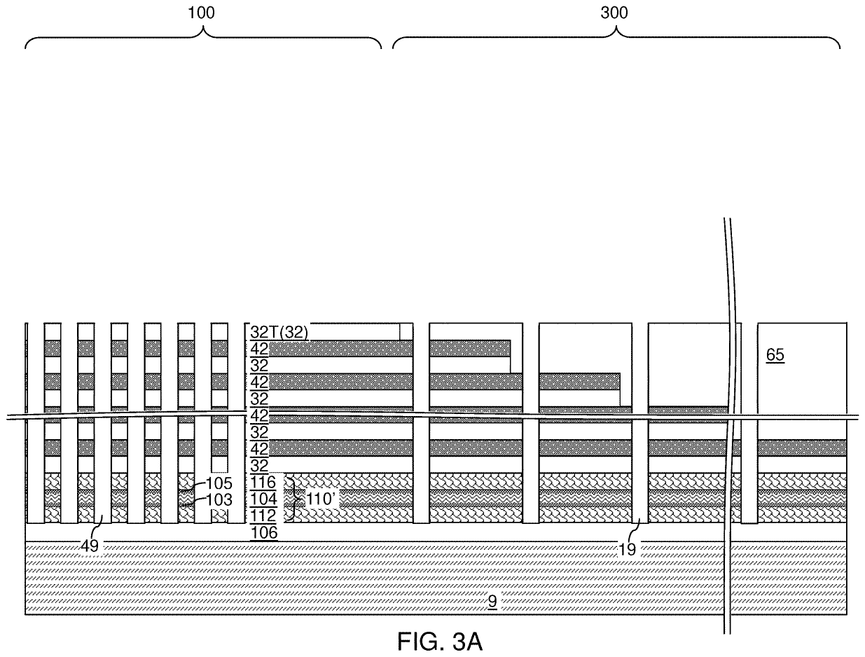

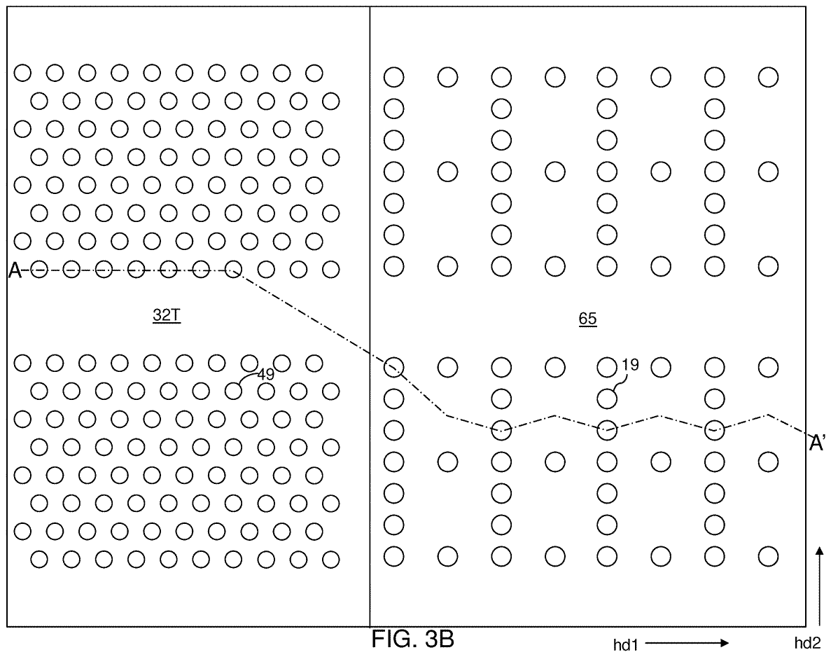

Referring to FIGS. 3A and 3B, an etch mask layer (not shown) can be formed over the alternating stack (32, 42), and can be lithographically patterned to form various openings therein. An anisotropic etch process can be performed to transfer the pattern of the openings in the etch mask layer through the alternating stack (32, 42). Various openings can be formed through the alternating stack (32, 42). The various openings may comprise memory openings 49 that are formed in the memory array region 100 and support openings 19 that are formed in the contact region 300. Each of the memory openings 49 and the support openings 19 can vertically extend through the alternating stack (32, 42) and into the in-process source-level material layers 110′ In one embodiment, bottom surfaces of the memory openings 49 and the support openings 19 may be formed within the lower source-level semiconductor layer 112 or at an interface between the lower source-level semiconductor layer and the stopper insulating layer 106.

The support openings 19 may have a diameter in a range from 60 nm to 400 nm, such as from 120 nm to 300 nm, although lesser and greater thicknesses may be employed. The memory openings 49 may have a diameter in a range from 60 nm to 400 nm, such as from 120 nm to 300 nm, although lesser and greater thicknesses may be employed.

In one embodiment, the memory array region 100 may be laterally spaced apart from the contact region 300 along a first horizontal direction hd1 (e.g., word line direction). The memory openings 49 may comprise rows of memory openings 49 that are arranged along the first horizontal direction hd1 and laterally spaced apart along a second horizontal direction hd2 that is perpendicular to the first horizontal direction hd2. Multiple clusters of memory openings 49, each containing a respective two-dimensional periodic array of memory openings 49, may be formed in the memory array region 100. The clusters of memory openings 49 may be laterally spaced apart along the second horizontal direction hd2.

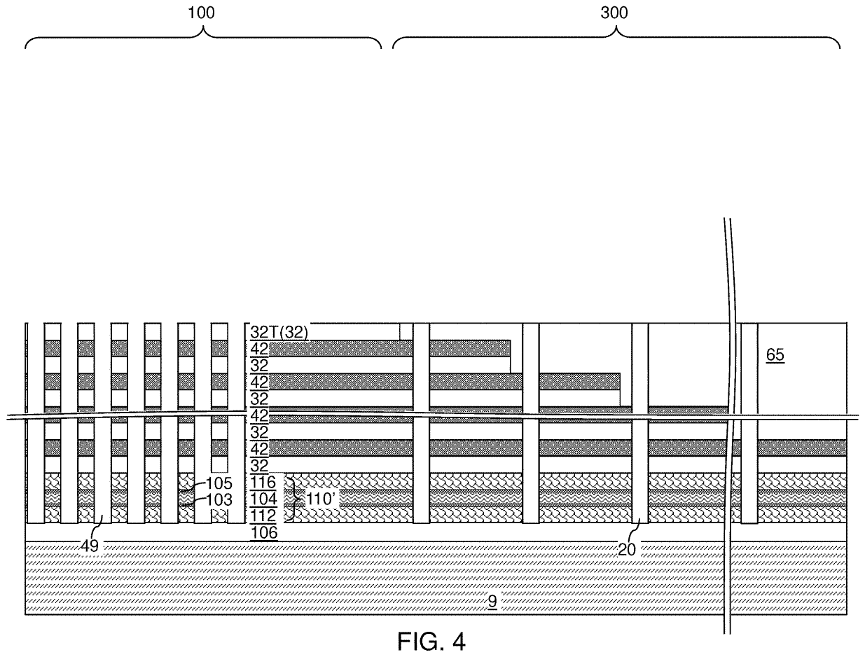

Referring to FIG. 4, an optional etch stop liner (not shown) and a sacrificial fill material (not shown) can be deposited in the memory openings 49 and the support openings 19. The optional etch stop liner (if present) comprises a thin dielectric material layer comprising silicon oxide, silicon nitride, or a dielectric metal oxide and having a thickness in a range from 1 nm to 6 nm. The sacrificial fill material may comprise a carbon-based material (such as amorphous carbon or diamond-like carbon), a semiconductor material (such as amorphous silicon or polysilicon), a dielectric fill material (such as borosilicate glass or organosilicate glass), or a polymer material. Excess portions of the sacrificial fill material can be removed from above the horizontal plane including the topmost layer of the alternating stack (32, 42) by a planarization process such as an etch back process. Remaining portions of the sacrificial fill material that fill the memory openings 49 and the support openings 19 constitute sacrificial memory opening fill structures (not shown) and sacrificial support opening fill structures (not shown).

A photoresist layer (not shown) can be applied over the alternating stack (32, 42) and the retro-stepped dielectric material portion 65, and can be lithographically patterned to cover the memory array region 100 without covering the contact region 300. The sacrificial support opening fill structures and portions of the optional etch stop liner in the support openings 19 located in the contact region 300 can be removed selective to the materials of the retro-stepped dielectric material portion 65 and the alternating stack (32, 42). For example, an etch process or an ashing process may be employed to remove the sacrificial support opening fill structures and portions of the optional etch stop liner in the contact region 300. The photoresist layer can be subsequently removed.

A dielectric fill material such as silicon oxide can be deposited in the support openings 19 by a conformal deposition process. Excess portions of the dielectric fill material can be removed from above the top surface of the topmost insulating layer 32T, for example, by a recess etch process. Each portion of the dielectric fill material that fills a respective support opening 19 constitutes a support pillar structure 20, which can be employed to provide structural support to the insulating layers 32 and the retro-stepped dielectric material portion 65 during replacement of the sacrificial material layers 42 with electrically conductive layers.

Subsequently, the sacrificial memory opening fill structures and portions of the optional etch stop liner in the memory array region 100 can be removed selective to the materials of the retro-stepped dielectric material portion 65 and the alternating stack (32, 42). For example, an etch process or an ashing process may be employed to remove the sacrificial memory opening fill structures and portions of the optional etch stop liner in the memory array region 100. Voids are formed in the volumes of the memory openings 49.

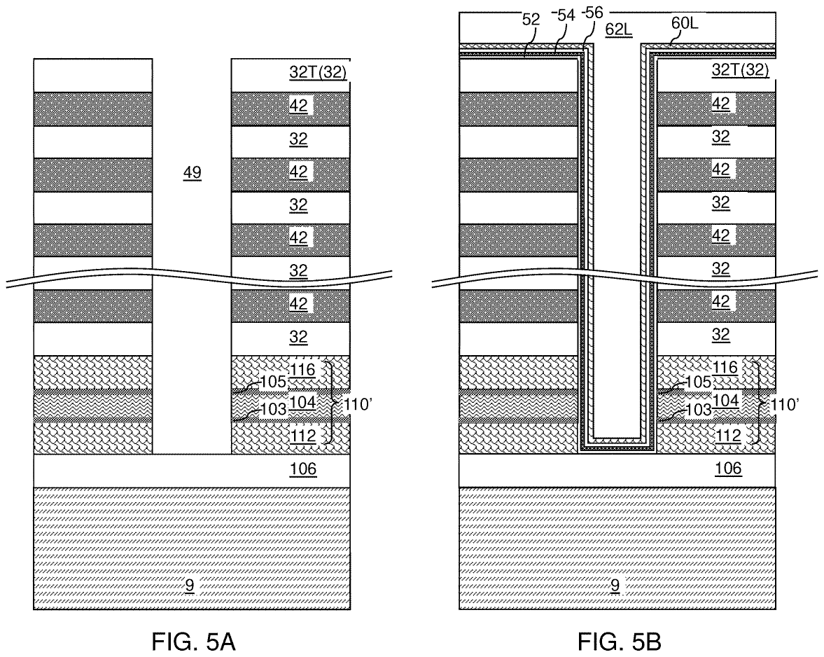

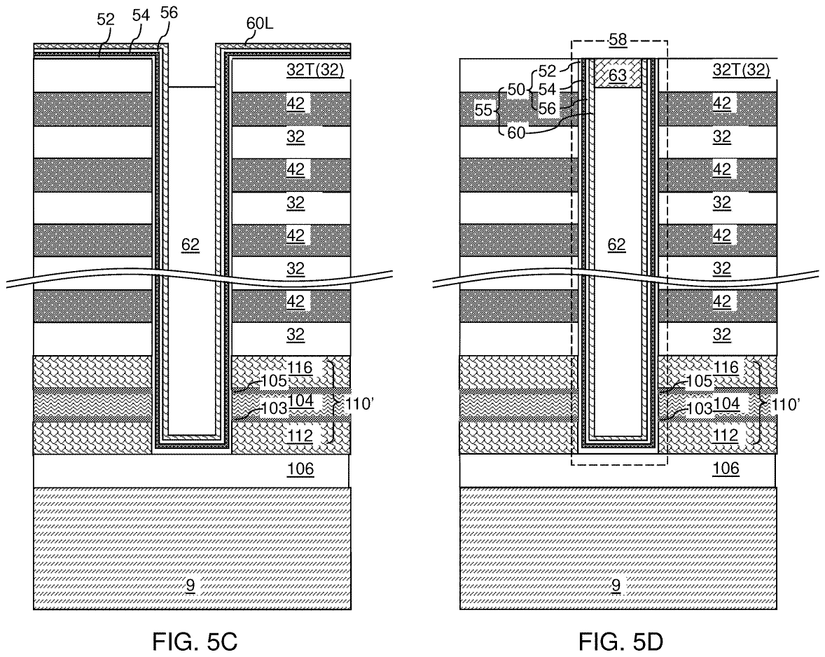

FIG. 5A-5D are sequential vertical cross-sectional views of a memory opening 49 during formation of a memory opening fill structure 58 according to an embodiment of the present disclosure.

Referring to FIG. 5A, a memory opening 49 is illustrated after the processing steps of FIG. 4.

Referring to FIG. 5B, a layer stack including a memory material layer 54 can be conformally deposited. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride), a ferroelectric material, a phase change memory material, or any other memory material that can store data bits by inducing a change in the electrical resistivity, ferroelectric polarization, or any other measurable physical property. In case the memory material layer 54 comprise a charge storage material, the optional dielectric liner 56 may comprise a tunneling dielectric layer.

A semiconductor channel material layer 60L can be deposited over the layer stack (52, 54, 56) by performing a conformal deposition process. If the semiconductor channel material layer 60L is doped, the semiconductor channel material layer 60L may have a doping of a first conductivity type, which may be p-type or n-type. In one embodiment, the first semiconductor material comprises a first doped silicon material having a doping of the first conductivity type. In an illustrative example, the atomic concentration of dopants of the first conductivity type in the semiconductor channel material layer 60L may be in a range from 1.0×10¹³/cm³ to 3.0 x 10¹⁷/cm³, such as 1.0×10¹⁴/cm³ to 3.0 x 10¹⁶/cm³, although lesser and greater atomic concentrations may also be employed. A dielectric core layer 62L comprising a dielectric fill material can be deposited in remaining volumes of the memory openings 49 and over the alternating stack (32, 42).

Referring to FIG. 5C, the dielectric core layer 62L can be vertically recessed such that each remaining portion of the dielectric core layer 62L has a top surface at, or about, the horizontal plane including the bottom surface of the topmost insulating layers 32T. Each remaining portion of the dielectric core layer 62L constitutes a dielectric core 62.

Referring to FIG. 5D, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5.0 x 10¹⁸/cm³ to 2.0×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination of a memory stack structure 55, a dielectric core 62, and a drain region 63 within a memory opening 49 constitutes a memory opening fill structure 58. Each memory opening fill structure 58 comprises a respective vertical stack of memory elements, which may comprise portions of the memory material layer 54 located at levels of the sacrificial material layers 42, or generally speaking, at levels of spacer material layers that may be formed as, or may be subsequently replaced at least partly with, electrically conductive layers.

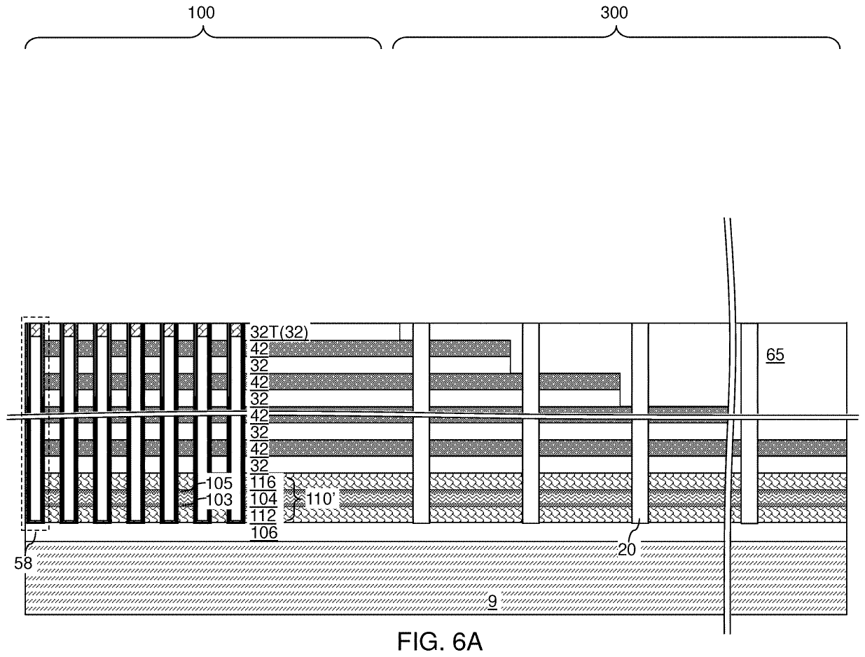

Referring to FIGS. 6A and 6B, the exemplary structure is illustrated after formation of memory opening fill structures 58 within the memory openings 49. Each of the memory opening fill structures 58 may comprise a memory film 50 and a vertical semiconductor channel 60.

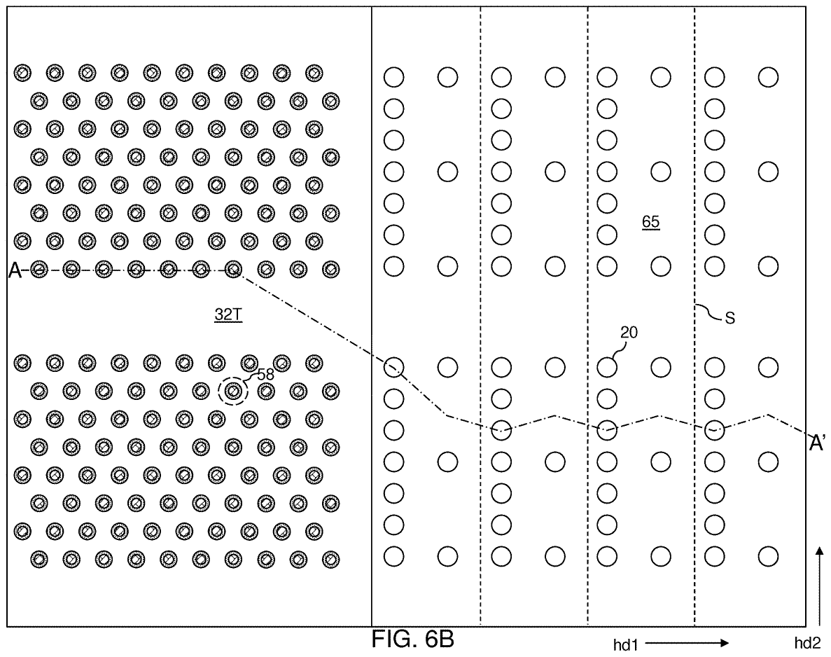

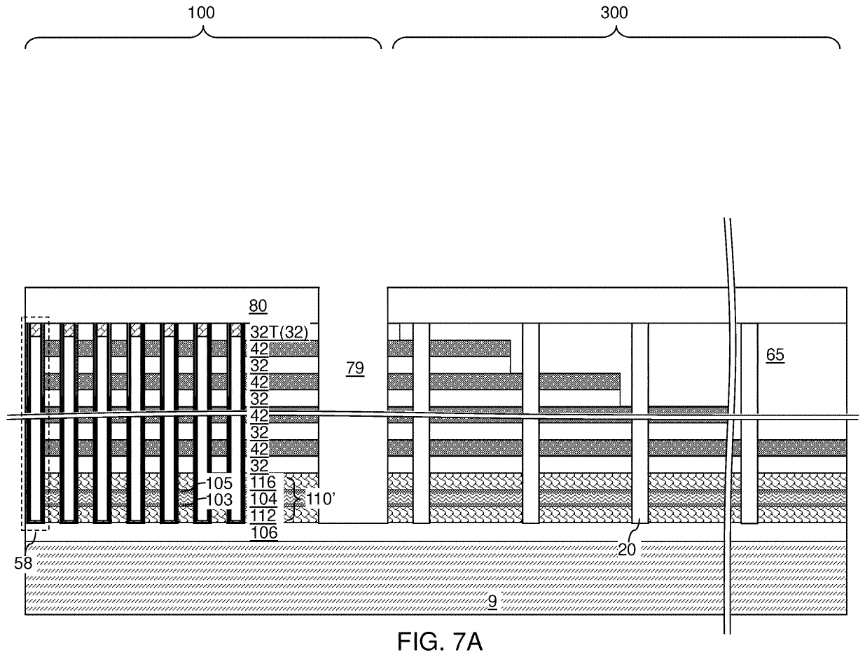

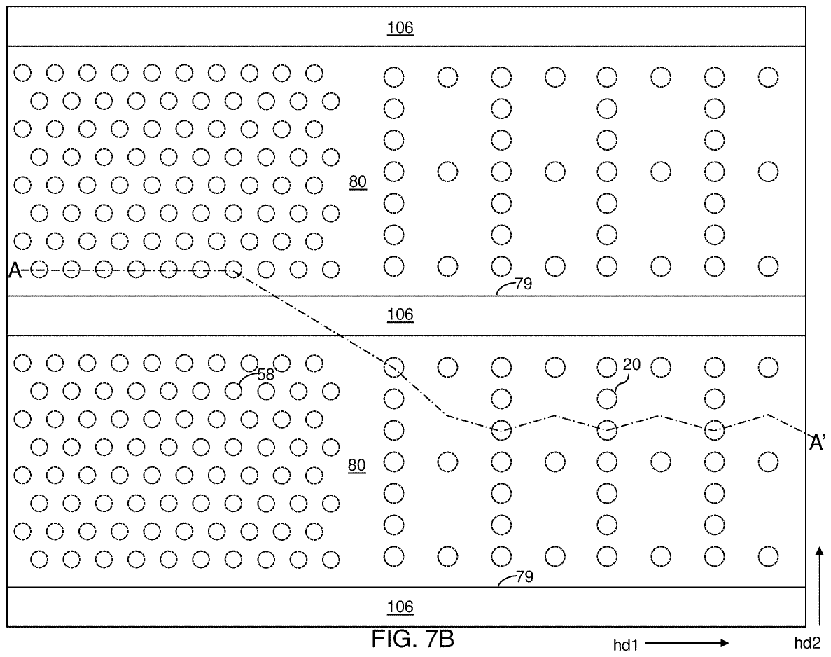

Referring to FIGS. 7A and 7B, a dielectric material such as undoped silicate glass or a doped silicate glass can be deposited over the alternating stack (32, 42) to form a contact-level dielectric layer 80. The thickness of the contact-level dielectric layer 80 may be in a range from 100 nm to 600 nm, such as from 200 nm to 400 nm, although lesser and greater thicknesses may also be employed.

A photoresist layer (not shown) can be applied over the contact-level dielectric layer 80, and can be lithographically patterned to form elongated openings that laterally extend along the first horizontal direction hd1 between neighboring clusters of memory opening fill structures 58. An anisotropic etch process can be performed to transfer the pattern of the openings in the photoresist layer through the contact-level dielectric layer 80, the alternating stack (32, 42), the stepped dielectric material portion 65, and the in-process source-level material layers 110′. Lateral isolation trenches 79 laterally extending along the first horizontal direction hd1 can be formed through the alternating stack (32, 42), the stepped dielectric material portion 65, the contact-level dielectric layer 80, and the in-process source-level material layers 110′. Each of the lateral isolation trenches 79 may comprise a respective pair of lengthwise sidewalls that are parallel to the first horizontal direction hd1 and vertically extend from the stopper insulating layer 106 to the top surface of the contact-level dielectric layer 80. A top surface of the stopper insulating layer 106 can be physically exposed underneath each lateral isolation trench 79. The photoresist layer can be subsequently removed, for example, by ashing.

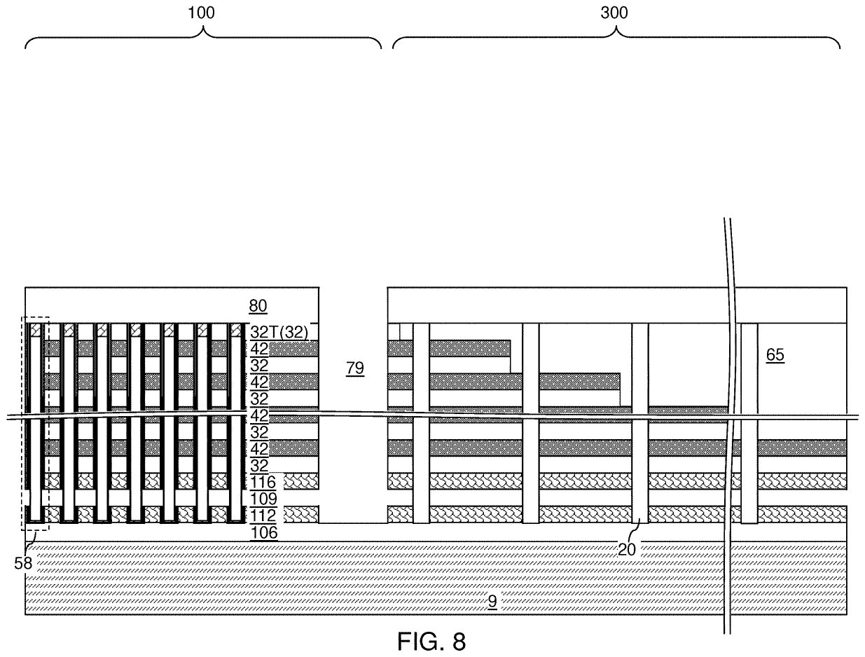

Referring to FIG. 8, an etchant that etches the material of the source-level sacrificial layer 104 selective to the materials of the alternating stack (32, 42), the contact level dielectric layer 80, the stepped dielectric material portion 65, the lower source-level semiconductor layer 112, the upper source-level semiconductor layer 116, the upper sacrificial liner 105 (if present), and the lower sacrificial liner 103 (if present) may be introduced into the lateral isolation trenches 79 by performing an isotropic etch process. For example, if the source-level sacrificial layer 104 includes undoped amorphous silicon, then a wet etch process using hot trimethyl-2 hydroxyethyl ammonium hydroxide (“hot TMY”) or tetramethyl ammonium hydroxide (TMAH) may be used to remove the source-level sacrificial layer 104 selective to the alternating stack (32, 42), the contact level dielectric layer 80, the stepped dielectric material portion 65, the lower source-level semiconductor layer 112, and the upper source-level semiconductor layer 116. Alternatively, if the source-level sacrificial layer 104 includes silicon nitride, then silicon oxide and/or semiconductor sidewalls spacers may be formed on sidewalls of the isolation trenches 79, such that the source-level sacrificial layer 104 is exposed below the sidewall spacers, followed by performing a selective wet etch process using phosphoric acid to selectively remove the source-level sacrificial layer 104. A source cavity 109 is formed in the volume from which the source-level sacrificial layer 104 is removed.

Each of the memory opening fill structures 58 is physically exposed to the source cavity 109. Specifically, each of the memory opening fill structures 58 includes a sidewall that is physically exposed to the source cavity 109.

A sequence of isotropic etchants, such as wet etchants, may be applied through the source cavity 109 to the physically exposed portions of the memory films 50 to sequentially etch the various component layers of the memory films 50 from outside to inside, and to physically expose cylindrical surfaces of the vertical semiconductor channels 60 at the level of the source cavity 109. The upper sacrificial liner 105 (if present) and the lower sacrificial liner 103 (if present) may be collaterally etched during removal of the portions of the memory films 50 located at the level of the source cavity 109. The source cavity 109 may be expanded in volume by removal of the portions of the memory films 50 at the level of the source cavity 109 and the upper and lower sacrificial liners. A top surface of the lower source-level semiconductor layer 112 and a bottom surface of the upper source-level semiconductor layer 116 may be physically exposed to the source cavity 109. The source cavity 109 is formed by isotropically etching the source-level sacrificial layer 104 and a bottom sidewall portion of each of the memory films 50 selective to at least one source-level semiconductor layer (such as the lower source-level semiconductor layer 112 and the upper source-level semiconductor layer 116) and the vertical semiconductor channels 60.

Referring to FIG. 9, a semiconductor material having a doping of the second conductivity type may be deposited on the physically exposed semiconductor surfaces around the source cavity 109. The physically exposed semiconductor surfaces include bottom portions of outer sidewalls of the vertical semiconductor channels 60 and a horizontal surface of the at least one source-level semiconductor layer (such as a bottom surface of the upper source-level semiconductor layer 116 and/or a top surface of the lower source-level semiconductor layer 112). For example, the physically exposed semiconductor surfaces may include the bottom portions of outer sidewalls of the vertical semiconductor channels 60, the top horizontal surface of the lower source-level semiconductor layer 112, and the bottom surface of the upper source-level semiconductor layer 116.

In one embodiment, the doped semiconductor material of the second conductivity type may be deposited on the physically exposed semiconductor surfaces around the source cavity 109 by a selective semiconductor deposition process. The deposited doped semiconductor material forms a source contact layer 114, which contacts sidewalls of the vertical semiconductor channels 60. The atomic concentration of the dopants of the second conductivity type in the deposited semiconductor material may be in a range from 1.0×10¹⁹/cm³ to 2.0×10²¹/cm³, such as from 2.0×10¹⁹/cm³ to 8.0×10²⁰/cm³. The source contact layer 114 as initially formed may consist essentially of semiconductor atoms and dopant atoms of the second conductivity type. Alternatively, at least one non-selective doped semiconductor material deposition process may be used to form the source contact layer 114. Optionally, one or more etch back processes may be used in combination with a plurality of selective or non-selective deposition processes to provide a source contact layer 114.

The duration of the selective semiconductor deposition process may be selected such that the source cavity 109 is filled with the source contact layer 114. In one embodiment, the source contact layer 114 may be formed by selectively depositing a doped semiconductor material having a doping of the second conductivity type from semiconductor surfaces around the source cavity 109. In one embodiment, the doped semiconductor material may include doped polysilicon. Thus, the source-level sacrificial layer 104 may be replaced with the source contact layer 114. The layer stack including the lower source-level semiconductor layer 112, the source contact layer 114, and the upper source-level semiconductor layer 116 constitutes a source layer 110, which replaces the in-process source-level material layers 110′. The source layer 110 contacts an end portion of each of the vertical semiconductor channels 60.

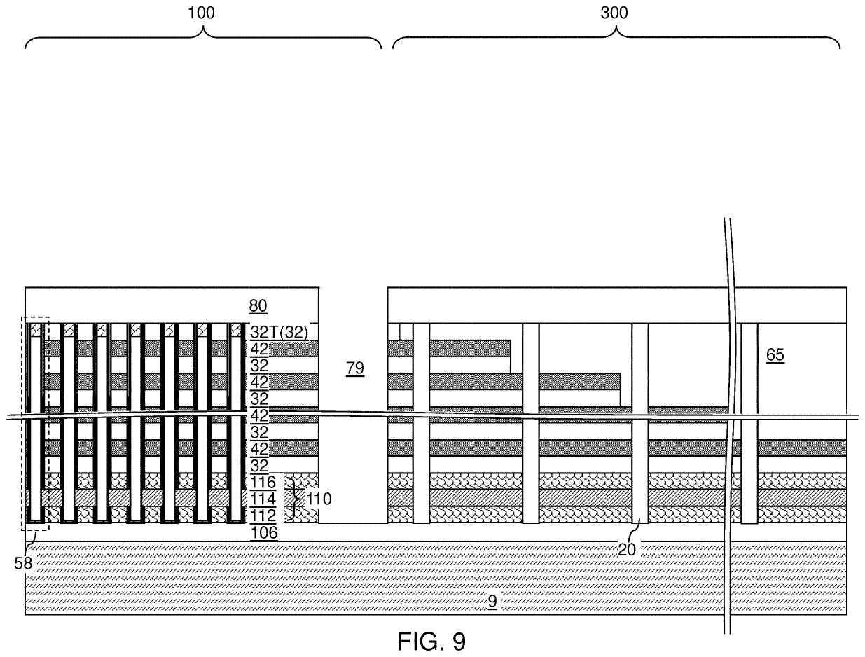

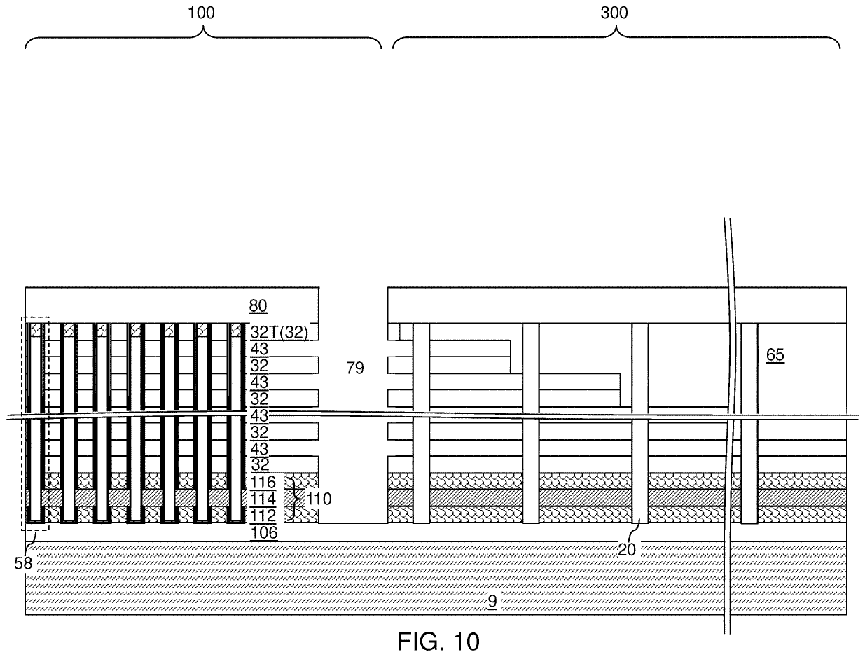

Referring to FIG. 10, an isotropic etch process can be performed to remove the sacrificial material layers 42 selective to the insulating layers 32, the stopper insulating layer 106, the memory opening fill structures 58, and the source layer 110. Laterally-extending cavities 43 can be formed in volumes from which the sacrificial material layers 42 are removed. Sidewall surface segments of the memory opening fill structures 58 can be physically exposed to the laterally-extending cavities 43. In an illustrative example, if the sacrificial material layers 42 comprise silicon nitride, the isotropic etch process may comprise a wet etch process employing hot phosphoric acid.

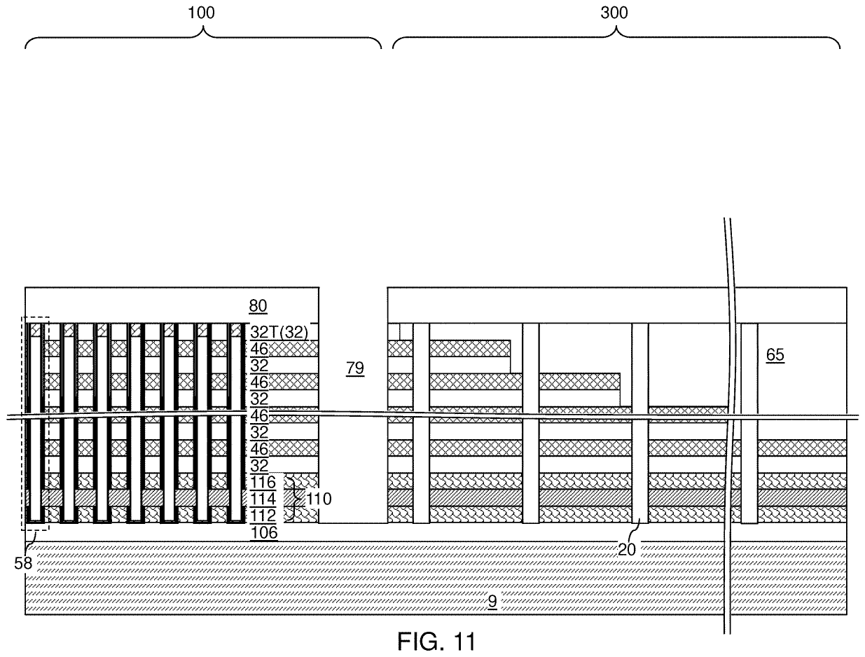

Referring to FIG. 11, a backside blocking dielectric layer (not shown) can be optionally formed in the laterally-extending cavities 43 by a conformal deposition process. At least one conductive material, such as at least one metallic material, can be conformally deposited in the laterally-extending cavities 43. The at least one conductive material may comprise, for example, a combination of a metallic barrier material and a metallic fill material. The metallic barrier material may comprise, for example, TiN, TaN, WN, MoN, TiC, TaC, WC, or a combination thereof. The metallic fill material may comprise, for example, Ti, Ta, Mo, Co, Ru, W, Cu, other transition metals, and/or alloys or layer stacks thereof. Excess portions of the at least one conductive material that are deposited in the lateral isolation trenches 79 or above the contact-level dielectric layer 80 can be removed by performing an etch-back process, which may comprise an isotropic etch process and/or an anisotropic etch process. Each remaining portion of the at least one conductive material filling a respective one of the laterally-extending cavities 43 constitutes an electrically conductive layer 46. An alternating stack of insulating layers 32 and electrically conductive layers 46 can be formed between each neighboring pair of lateral isolation trenches 79 over the substate 9. A plurality of alternating stacks of insulating layers 32 and electrically conductive layers 46 can be laterally spaced apart from each other by the lateral isolation trenches 79.

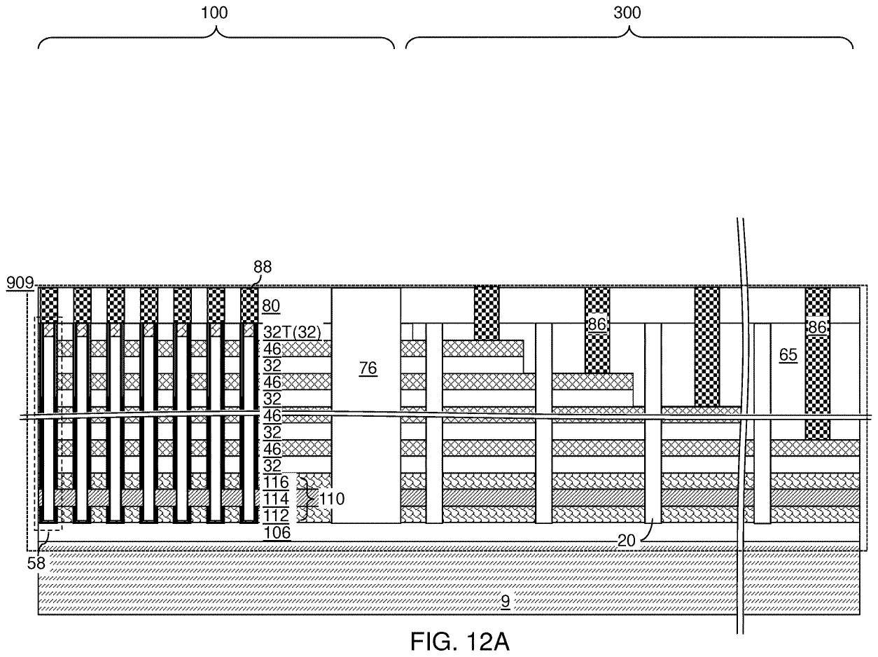

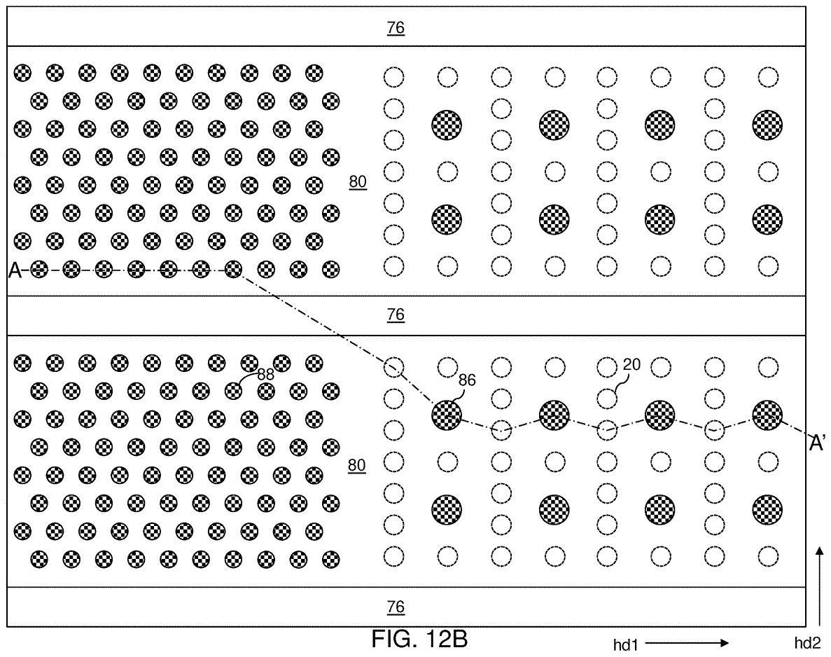

Referring to FIGS. 12A and 12B, an insulating fill material may be conformally deposited in the lateral isolation trenches 79. Excess portions of the insulating fill material may be removed from above the contact-level dielectric layer 80, for example, by a recess etch process. Each remaining portion of the insulating fill material that fills a respective lateral isolation trench 79 constitutes an isolation trench fill structure 76. Alternatively, each isolation trench fill structure 76 may comprise a combination of a tubular insulating spacer (not expressly shown) and a conductive connection via structure (not expressly shown) that is laterally surrounded by the tubular insulating spacer.

A photoresist layer (not shown) can be applied over the contact-level dielectric layer 80, and can be lithographically patterned to form openings over each of the memory opening fill structures 58 over the horizontally-extending surfaces of the stepped surfaces in the contact region. An anisotropic etch process can be performed to transfer the pattern of the openings in the photoresist layer through the contact-level dielectric layer 80 and the retro-stepped dielectric material portion 65. Drain contact via cavities can be formed through the contact-level dielectric layer 80 over the memory opening fill structures 58. Layer contact via structures can be formed through the contact-level dielectric layer 80 and the retro-stepped dielectric material portion 65 on a top surface of a respective one of the electrically conductive layers 46. The photoresist layer can be subsequently removed, for example, by ashing.

At least one conductive material, such as a combination of a metallic barrier material and a metallic fill material, can be deposited in the drain contact via cavities and the layer contact via cavities. Excess portions of the at least one conductive material can be removed from above the horizontal plane including the top surface of the contact-level dielectric layer 80 by a planarization process, which may employ a recess etch process and/or a chemical mechanical polishing process. Remaining portions of the at least one conductive material that fill the drain contact via cavities constitute drain contact via structures 88 contacting a top surface of a respective one of the drain regions 63. Remaining portions of the at least one conductive material that fill the layer contact via cavities constitute layer contact via structures 86 contacting a top surface of a respective one of the electrically conductive layers 46.

Thus, a three-dimensional memory device 909 is formed. The three-dimensional memory device 909 includes an alternating stack of insulating layers 32 and electrically conductive layers 46 (some of which comprise word lines), and memory opening fill structures (e.g., vertical NAND strings) extending through the alternating stack (32, 46).

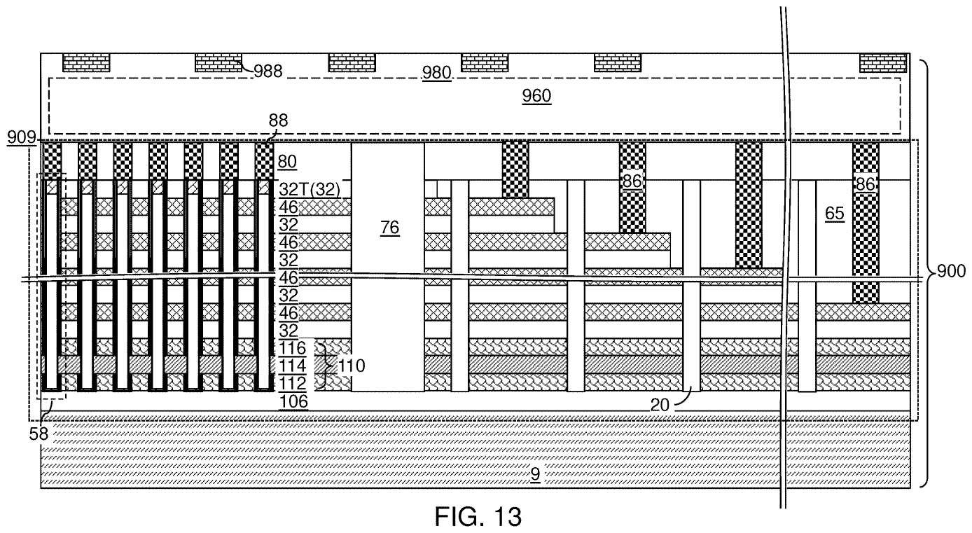

Referring to FIG. 13, additional dielectric material layers and additional metal interconnect structures can be formed over the contact-level dielectric layer 80. The additional dielectric material layers may include at least one via-level dielectric layer, at least one additional line-level dielectric layer, and/or at least one additional line-and-via-level dielectric layer. The additional metal interconnect structures may comprise metal via structures, metal line structures (e.g., bit lines), and/or integrated metal line-and-via structures. The additional dielectric material layers that are formed above the contact-level dielectric layer 80 are herein referred to as memory-side dielectric material layers 960. The additional metal interconnect structures are collectively referred to as memory-side metal interconnect structures 980. The memory-side dielectric material layers 960 comprise a bit-line-level dielectric material layer embedding bit lines, which are a subset of the memory-side metal interconnect structures 980.

Metal bonding pads, which are herein referred to as upper bonding pads 988, may be formed at the topmost level of the memory-side dielectric material layers 960. The upper bonding pads 988 may be electrically connected to the memory-side metal interconnect structures 980 and various nodes of the three-dimensional memory array including electrically conductive layers (e.g., word lines and select gate electrodes) 46 and the bit lines which are electrically connected to the drain regions 63 of the memory opening fill structures 58. A memory die 900 can thus be provided.

The memory-side dielectric material layers 960 are formed over the alternating stacks (32, 46). The memory-side metal interconnect structures 980 are embedded in the memory-side dielectric material layers 960. The memory-side bonding pads 988 can be embedded within the memory-side dielectric material layers 960, and specifically, within the topmost layer of the memory-side dielectric material layers 960. The memory-side bonding pads 988 can be electrically connected to the memory-side metal interconnect structures 980.

In one embodiment, the memory die 900 may comprise: a three-dimensional memory array underlying the first dielectric material layer 110 and comprising an alternating stack (32, 46) of insulating layers 32 and electrically conductive layers 46, a two-dimensional array of memory openings 49 vertically extending through the alternating stack (32, 46), and a two-dimensional array of memory opening fill structures 58 located in the two-dimensional array of memory openings 49 and comprising a respective vertical stack of memory elements and a respective vertical semiconductor channel 60; a two-dimensional array of drain contact via structures 88 electrically connected to a respective one of the vertical semiconductor channels 60; and a two-dimensional array of layer contact via structures 86 electrically connected to a respective one of the electrically conductive layers 46, a subset of which functions as word lines of the three-dimensional memory array.

Generally speaking, a memory die 900 is provided, which comprises a memory array, memory-side metal interconnect structures 980, and memory-side bonding pads 988 embedded within memory-side dielectric material layers 960. The memory array may comprise a three-dimensional memory array including an alternating stack of insulating layers 32 and electrically conductive layers 46, and further comprises a two-dimensional array of NAND strings (e.g., memory opening fill structures 58) vertically extending through the alternating stack (32, 46). In one embodiment, the electrically conductive layers 46 comprise word lines of the two-dimensional array of NAND strings. In one embodiment, the memory-side metal interconnect structures 980 comprise bit lines for the two-dimensional array of NAND strings.

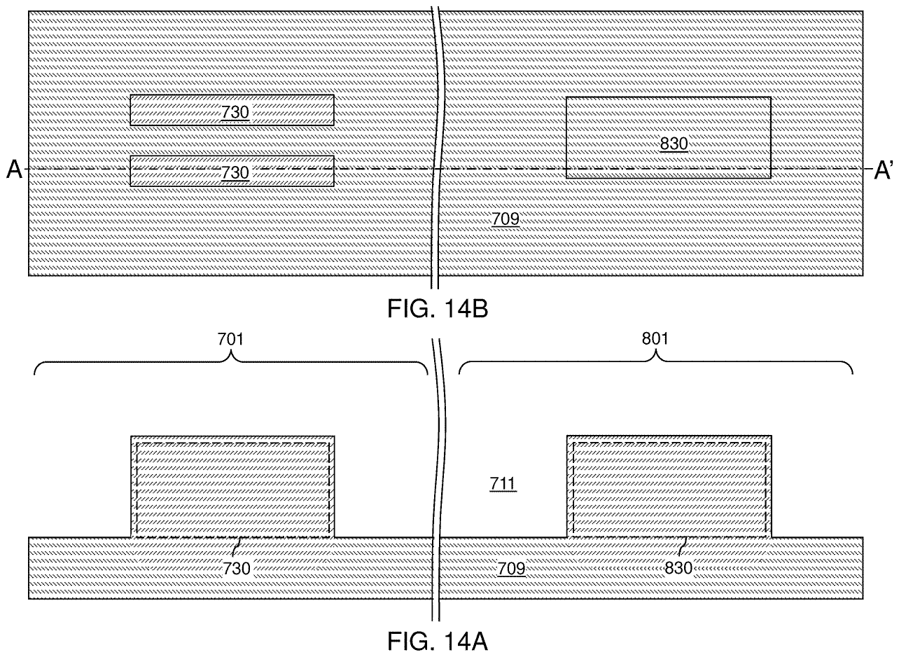

Referring to FIGS. 14A and 14B, a second exemplary structure for forming a logic die 700 is illustrated. The illustrated portion of the second exemplary structure may be a portion of semiconductor substrate (such as a commercially available silicon wafer) after performing a set of processing steps that patterns surface portions of the semiconductor substrate. The semiconductor substrate is herein referred to as a logic-side substrate 709. The second exemplary structure can include many device regions, which comprises a first device region 701 for forming a fin field effect transistor and a second device region 801 for forming a planar field effect transistor. As used herein, a “planar” field effect transistor or a planar FET refers to a field effect transistor in which the channel current flows through a channel that is parallel to a top surface of the substrate 709. As used herein, a “fin” field effect transistor or a finFET refers to a field effect transistor in which a fraction of the channel is located on a side of a vertical or substantially vertical surface which is perpendicular to the top surface of the substrate 709. The finFET may be a high voltage transistor and the planar FET may be a low voltage transistor which operates at a lower voltage than the high voltage transistor. The finFET and the planar FET may comprise portions of the word line switching circuit which is used to control the voltage applied to the word lines 46 of the memory array.

The logic-side substrate 709 comprises a semiconductor material layer at least at an upper portion thereof, and may comprise a commercially available bulk silicon wafer. In one embodiment, a photoresist layer (not shown) can be applied over the top surface of the logic-side substrate 709, and can be patterned into discrete photoresist material portions over areas of the logic-side substrate 709 in which semiconductor fins 730 or semiconductor active regions 830 are to be subsequently formed. An anisotropic etch process can be performed to etch an upper portion of the logic-side substrate 709 that is not masked by the photoresist layer. A continuous recess cavity 711 is formed around etched portions of the logic-side substate 709. The depth of the continuous recess cavity 711 may be in a range from 150 nm to 800 nm, such as from 300 nm to 600 nm, although lesser and greater depths may also be employed. At least one semiconductor fin 730 may be formed in the first device region 701, and a semiconductor active region 830 may be formed in the second device region 801. The at least one semiconductor fin 730 may comprise a single semiconductor fin 730 or a plurality of semiconductor fins 730 that are parallel to each other.

Each semiconductor fin 730 is a patterned portion of the logic-side substrate 709, and each semiconductor active region 830 is a patterned portion of the logic-side substrate 709. In one embodiment, each semiconductor fin 730 and each semiconductor active region 830 may have a doping of a first conductivity type, which may be p-type or n-type. The atomic concentration of dopants of the first conductivity type in each semiconductor fin 730 and each semiconductor active region 830 may be in a range from 1.0×10¹⁴/cm³ to 3.0×10¹⁷/cm³, such as from 1.0×10¹⁵/cm³ to 1.0×10¹⁷/cm³, although lesser and greater atomic concentrations of dopants of the first conductivity type may also be employed. In one embodiment, the entirety of the logic-side substrate 709, each semiconductor fin 730, and each semiconductor active region 830 may be single crystalline (e.g., single crystal silicon), and may be epitaxially aligned to each other with a same set of crystallographic orientations throughout.

In an illustrative example, the width of a semiconductor fin 730 may be in a range from 30 nm to 300 nm, and the length of a semiconductor fin 730 may be in a range from 500 nm to 10,000 nm. In the embodiment in which a plurality of semiconductor fins 730 are formed in a row, the total number of semiconductor fins 730 may be in a range from 2 to 20, although a greater number may also be employed. The width of a semiconductor active region 830 may be in a range from 100 nm to 5,000 nm, such as from 200 nm to 2,500 nm, although lesser and greater widths may also be employed. The length of a semiconductor active region 830 may be in a range from 200 nm to 5,000 nm, although lesser and greater lengths may also be employed. In one embodiment, a plurality of semiconductor fins 730 having a same length and having a same width can be formed such that the lengthwise sidewalls of the semiconductor fins 730 are aligned to a first horizontal direction, and the semiconductor fins 730 are laterally spaced apart from each other along a second horizontal direction that is perpendicular to the first horizontal direction.

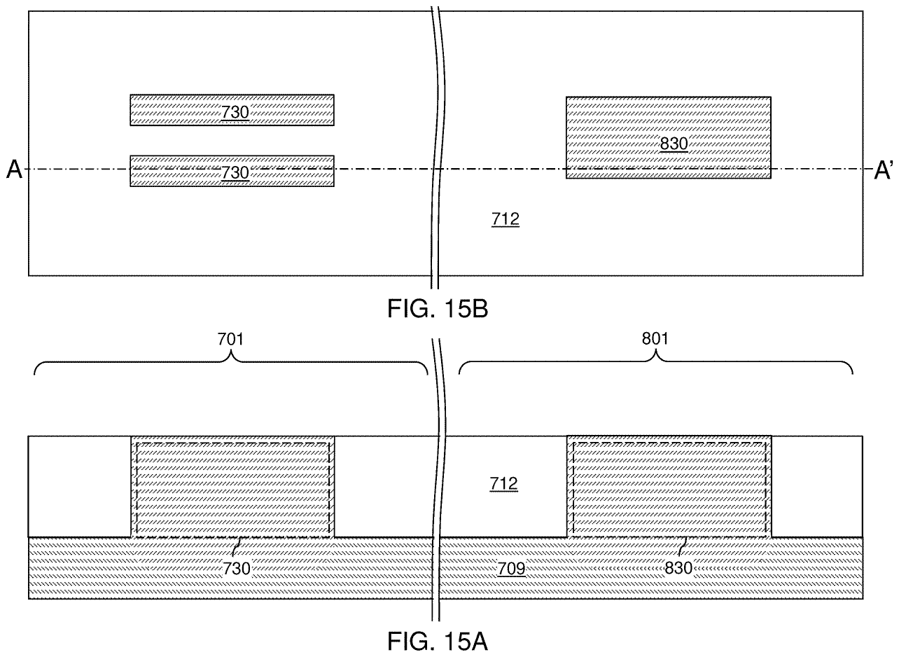

Referring to FIGS. 15A and 15B, a dielectric fill material, such as undoped silicate glass (i.e., silicon oxide), a doped silicate glass, or a flowable oxide (FOX) material can be deposited in the continuous recess cavity 711. A densification process may be optionally performed. Portions of the dielectric fill material that overlie the horizontal plane including the top surfaces of the semiconductor fins 730 and the semiconductor active region 830 can be removed by performing a planarization process, such as a chemical mechanical planarization process.

Generally, top surfaces of the planarized portions of the dielectric fill material may be coplanar with the top surfaces of the semiconductor fin(s) 730 and the semiconductor active region 830. The remaining portion of the dielectric fill material constitutes a dielectric isolation layer 712. The dielectric isolation layer 712 may continuously extend across the first device region 701 and the second device region 801. Accordingly, the dielectric isolation layer 712 may comprise a first portion located in the first device region 701, and a second portion located in the second device region 801 and adjoined to the first portion, i.e., extending continuously to the first region. The first portion of the dielectric isolation layer 712 laterally surrounds the at least one semiconductor fin 730, and the second portion of the dielectric isolation layer 712 laterally surrounds the semiconductor active region 830. In one embodiment, a top surface of the first portion of the dielectric isolation layer 712 is coplanar with a top surface of the at least one semiconductor fin 730 at least at this step in the process. Optionally, doped well regions may be formed in the substrate 709 by implanting dopants into the substrate 709 through the dielectric isolation layer 712.

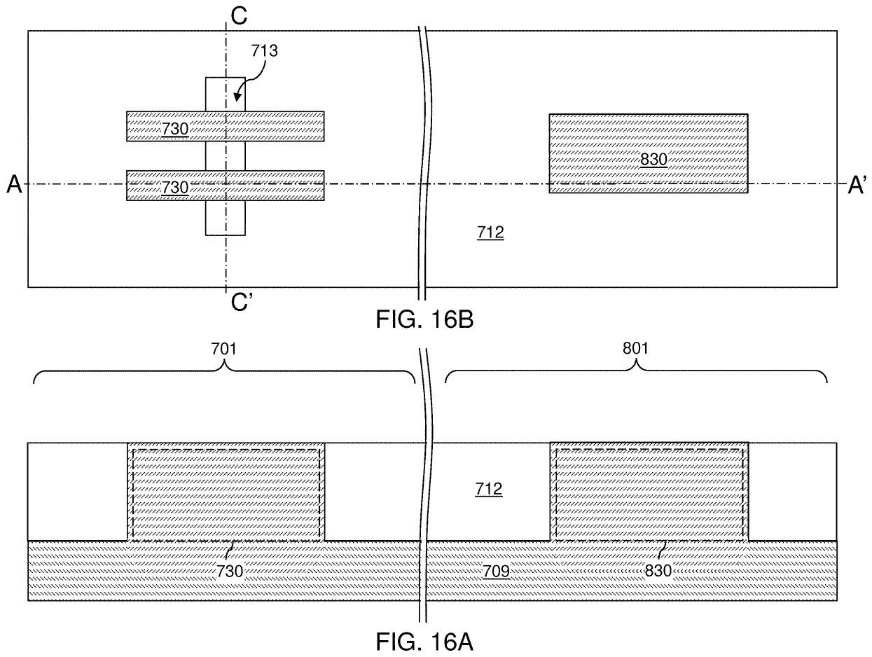

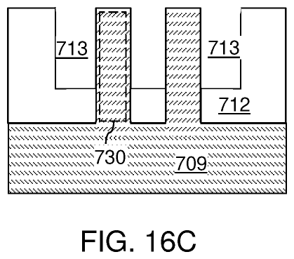

Referring to FIG. 16A-16C, a photoresist layer (not shown) can be applied over the dielectric isolation layer 712, the semiconductor fins 730, and the semiconductor active region 830, and can be lithographically patterned to form an opening in an area that straddles the semiconductor fins 730. For example, a continuous opening that straddles each of the semiconductor fins 730 and having a uniform width along the lengthwise direction of the semiconductor fins 730 can be formed in the photoresist layer.

An anisotropic etch process can be performed to etch unmasked portions of the dielectric isolation layer 712 selective to the semiconductor material of the semiconductor fins 730. As used herein, an etch process that etches a first material is “selective” to a second material if the etch rate for the first material is greater than three times the etch rate for the second material. In one embodiment, the anisotropic etch process may comprise a reactive ion etch (RIE) process employing a fluorine-based chemistry. For example, a mixture of a fluorine-containing etchant and an inert gas may be employed. During the anisotropic etch process, the fluorine-containing etchant can react with a silicon oxide material in the dielectric isolation layer 712 to form volatile gaseous molecules of silicon tetrafluoride (SiF₄), while a protective silicon fluoride layer is formed on the silicon surfaces of the semiconductor fins 730. The thin silicon fluoride film comprises an amorphous silicon fluoride that acts as a passivation layer that protects the underlying silicon material. The thin silicon fluoride film contains a mixture of silicon, fluorine, and optionally other elements such as carbon and/or oxygen. The thin silicon fluoride film protects underlying silicon from structural damage due to ion bombardment during the anisotropic etch process.

Gate cavities 713 can be formed in volumes from which the material of the dielectric isolation layer 712 is removed by the anisotropic etch process. The depth of the gate cavities 713 may be in a range from 10% to 90%, such as from 25% to 75%, of the height of the semiconductor fins 730 and the semiconductor active region 830. The photoresist layer can be subsequently removed, for example, by ashing. A suitable clean process can be performed after the anisotropic etch process to remove any remaining portion of the thin silicon fluoride film. The lateral dimension of the gate cavities 713 along the lengthwise direction of the semiconductor fins 730 may be in a range from 200 nm to 2,000 nm, such as from 300 nm to 1,000 nm, although lesser and greater lateral dimensions may also be employed.

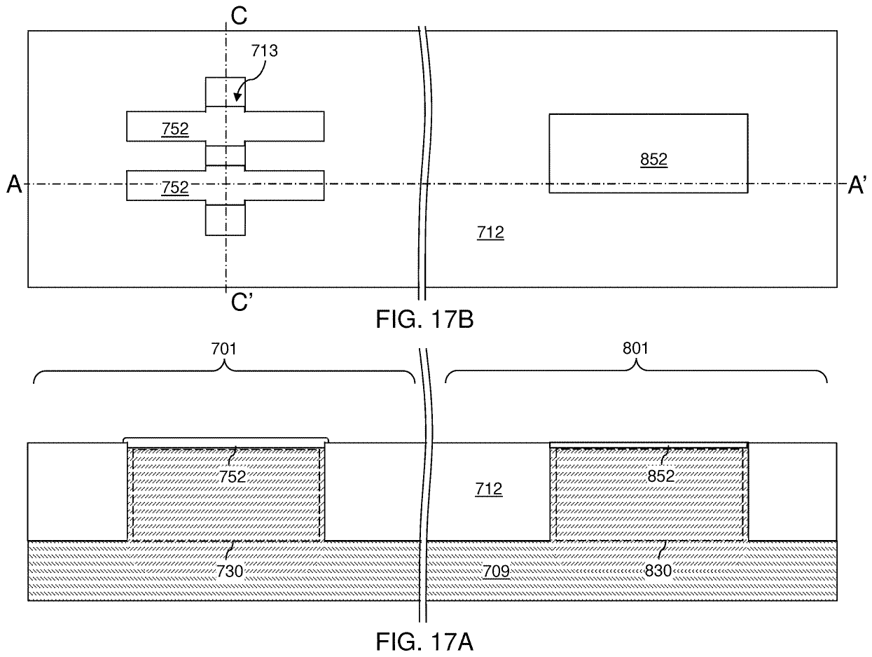

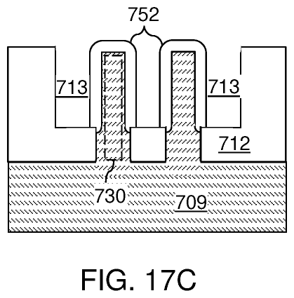

Referring to FIG. 17A-17C, gate dielectrics (752, 852) can be formed on the physically exposed surfaces of the semiconductor fins 730 and the semiconductor active

region 830. Specifically, a first gate dielectric 752 having a first thickness can be formed on each physically exposed surface of the semiconductor fins 730, and a second gate dielectric 852 having a second thickness can be formed on the physically exposed surface of the semiconductor active region 830. According to an aspect of the present disclosure, a high voltage transistor (e.g., finFET) capable of switching voltages in a range from 10 V to 50 V can be formed in the first device region 701, and a low voltage transistor (e.g., planar FET) capable of switching voltages in a range from 1 V to 10 V, such as from 1.2 V to 6 V, can be formed in the second device region 801. In this case, the first thickness of the first gate dielectric 752 may be in a range from 10 nm to 100 nm, and the second thickness of the second gate dielectric 852 may be in a range from 1 nm to 15 nm, such as from 2 nm to 10 nm, although lesser and greater thicknesses may also be employed for each of the first thickness and the second thickness.

In one embodiment, the first gate dielectrics 752 may comprise a first thermal silicon oxide material, and the second gate dielectric 852 may comprise a second thermal silicon oxide material. In a non-limiting illustrative example, a first thermal oxidation process can be performed to simultaneously form at least one first semiconductor oxide layer on the at least one semiconductor fin 730 and a sacrificial semiconductor oxide layer on the semiconductor active region 830. Each first semiconductor oxide layer may comprise an oxidized surface portion of a respective semiconductor fin 730, and the sacrificial semiconductor oxide layer may comprise an oxidized surface portion of the semiconductor active region 830. A photoresist layer can be formed over the at least one first semiconductor oxide layer and the sacrificial semiconductor oxide layer, and can be lithographically patterned to cover the at least one first semiconductor oxide layer without covering the sacrificial semiconductor oxide layer. An isotropic etch process that removes silicon oxide selective to silicon can be performed to remove the sacrificial semiconductor oxide layer selective to the semiconductor active region 830. For example, a wet etch process employing dilute hydrofluoric acid can be performed to remove the sacrificial semiconductor oxide layer. Thus, the sacrificial semiconductor oxide layer can be removed without removing the at least one first semiconductor oxide layer. A top surface of the semiconductor active region 830 can be physically exposed after the isotropic etch process. The photoresist layer can be subsequently removed, for example, by ashing. A second oxidation process can be subsequently performed. The at least one first semiconductor oxide layer can be converted into the least one first gate dielectric 752, for example, by additional oxidation of underlying surface portions of the at least one semiconductor fin 730. The second oxidation process forms the second gate dielectric 852 on the semiconductor active region 830 by converting a surface portion of the semiconductor active region 830 that underlies the top surface of the semiconductor active region 830.

In an alternative embodiment, the at least one first gate dielectric 752 is formed by deposition of an insulating layer over the at least one semiconductor fin 730, following by photolithography and etching to pattern the insulating layer into the at least one first gate dielectric 752. The second gate dielectric 852 is formed by deposition of another insulating layer over the semiconductor active region 830, following by photolithography and etching to pattern the insulating layer into the at second gate dielectric 852. The second gate dielectric 852 may be formed before, after or at the same time as the at least one first gate dielectric 752. The at least one first gate dielectric 752 and the second gate dielectric 852 may each comprise the same or different insulating materials, such as silicon oxide, silicon oxynitride or a high-k dielectric material (e.g., a metal oxide, such as aluminum oxide or hafnium oxide).

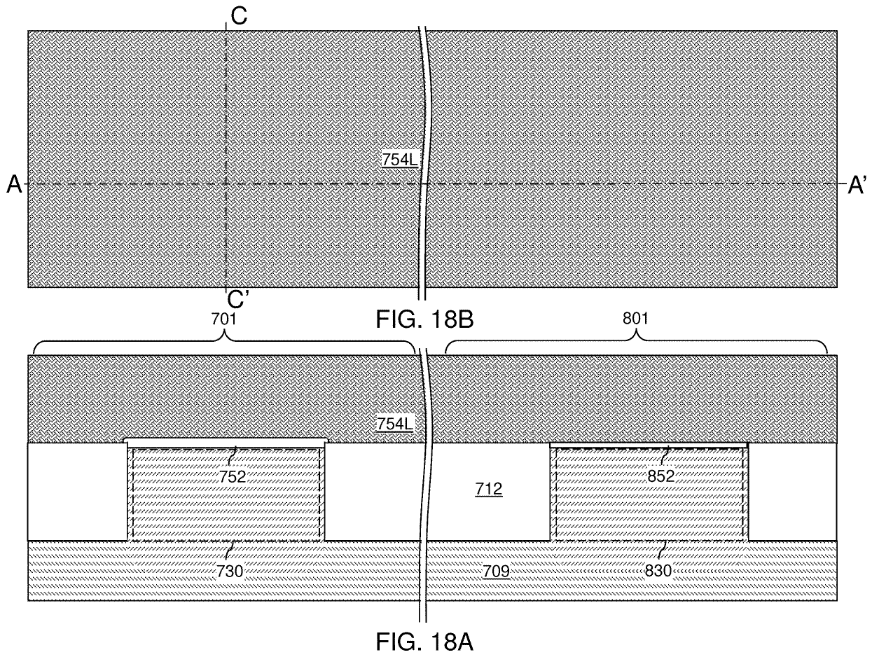

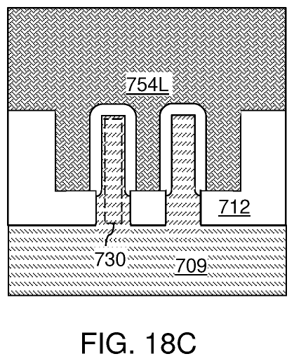

Referring to FIG. 18A-18C, a gate electrode material layer 754L can be formed over the at least one first gate dielectric 752, the second gate dielectric 852, and the dielectric isolation layer 712. The gate electrode material layer 754L may comprise a heavily-doped semiconductor (e.g., polysilicon) material and/or at least one metal material. The thickness of the gate electrode material layer 754L may be in a rage from 150 nm to 800 nm, such as from 300 nm to 600 nm, although lesser and greater thicknesses may also be employed. The gate cavities 713 are filled within the gate electrode material layer 754L.

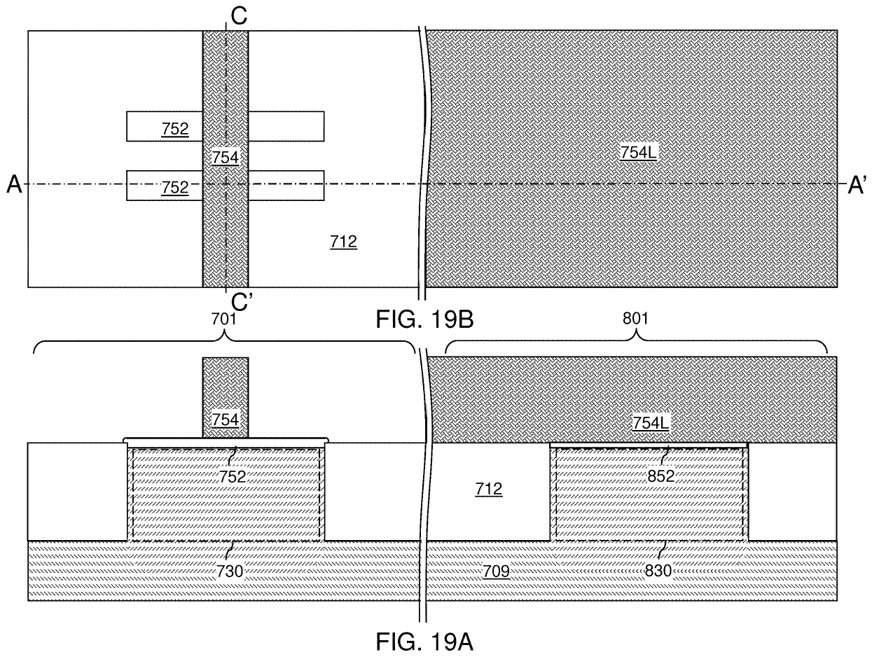

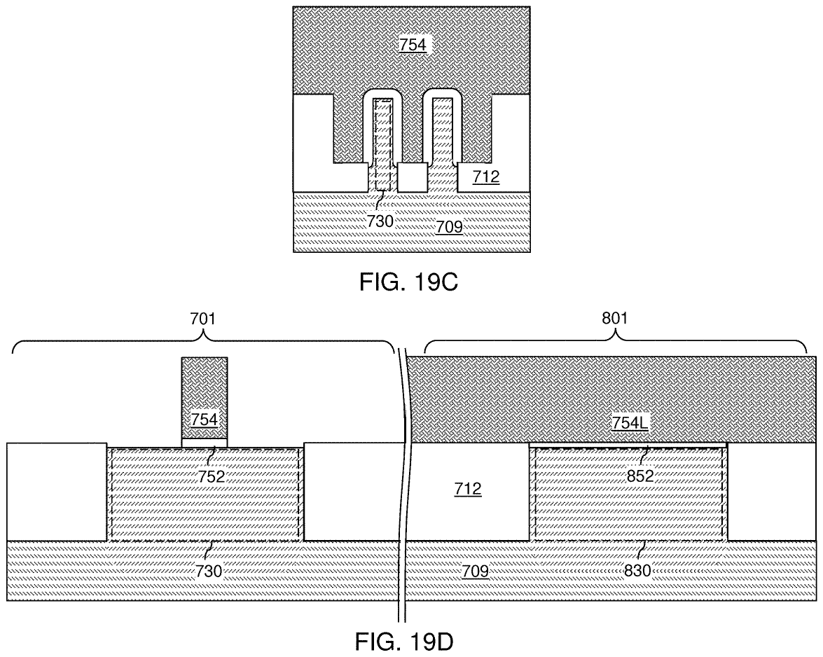

Referring to FIG. 19A-19C, a photoresist layer (not shown) can be applied over the gate electrode material layer 754L, and can be lithographically patterned to form a discrete photoresist material portion that continuously extends over the areas of the gate cavities 713, and to form a continuously-extending patterned photoresist material portion that covers the entirety of the second device region 801. An anisotropic etch process can be performed to etch unmasked portions of the gate electrode material layer 754L. A patterned portion of the gate electrode material layer 754L that underlies the discrete photoresist material portion constitutes a gate electrode 754 for a fin field effect transistor to be subsequently formed, which is hereafter referred to as a finFET gate electrode 754 or as a first gate electrode 754. The finFET gate electrode 754 straddles each of the at least one semiconductor fin 730.

In an alternative embodiment shown in FIG. 19D, the exposed portions of the first gate dielectric 752 that do not underlie the finFET gate electrode 754 can be etched away at the same time as the gate electrode material layer 754L. Thus, the sidewalls of the first gate dielectric 752 and the finFET gate electrode 754 can be vertically coincident. In this case, an upper portion of the dielectric isolation layer 712 may also be etched.

The finFET gate electrode 754 may have a uniform width along the lengthwise direction of the at least one semiconductor fin 730. The uniform width may be the same as, or may be greater than, the width of the gate cavities 713. Generally, the entire volume of the gate cavities 713 can be filled with downward-protruding portions of the finFET gate electrode 754. A remaining portion of the gate electrode material layer 754L can cover the entire area of the second device region 801. Remaining portions of the photoresist layer can be subsequently removed, for example, by ashing.

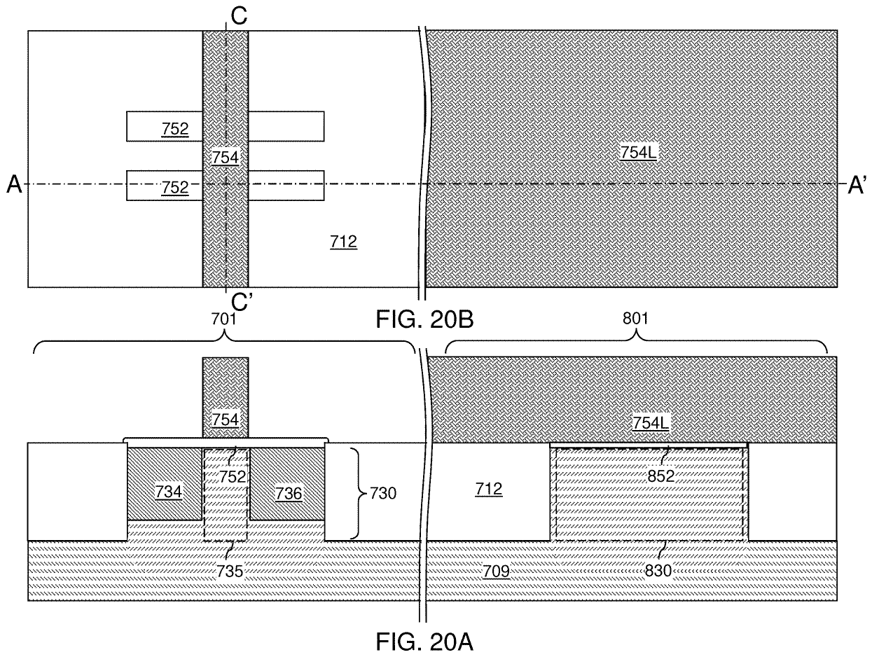

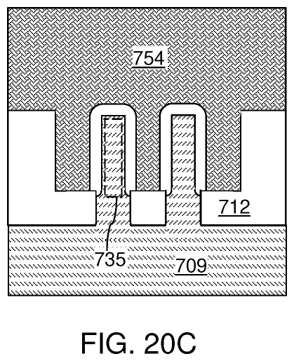

Referring to FIG. 20A-20C, a first extension (i.e., low-doped drain (LDD)) implantation process can be performed to implant dopants of a second conductivity type into portions of each semiconductor fin 730 that are not covered by the finFET gate electrode 754. In other words, portions of each semiconductor fin 730 that do not have an areal overlap with the finFET gate electrode 754 can be implanted with the dopants of the second conductivity type during an ion implantation process that employs the finFET gate electrode 754 as an etch mask.

Source/drain extension regions (i.e., LDD regions) are formed in portions of the at least one semiconductor fin 730 that are implanted with the dopants of the second conductivity type. The source/drain extension regions that are formed in the at least one semiconductor fin 730 are herein referred to as finFET source/drain extension regions (734, 736) or first source/drain extension regions (734, 736). The finFET source/drain extension regions (734, 736) comprise finFET source extension regions 734 and finFET drain extension regions 736. Unimplanted portions of the at least one semiconductor fin 730 are herein referred to as finFET channel regions 735 or first channel regions 735.

In one embodiment, the height of the finFET source/drain extension regions (734, 736) may be the same as, or may be less than, the thickness of the finFET gate electrode 754 (which is the same as the thickness of the gate electrode material layer 754L). For example, the height of the finFET source/drain extension regions (734, 736) may be in a range from 100 nm to 800 nm, such as from 200 nm to 600 nm, although lesser and greater heights may also be employed. Generally, the height of the finFET source/drain extension regions (734, 736) may be the same as, or may be less than, the height of the semiconductor fins 730. The atomic concentration of dopants of the second conductivity type in the finFET source/drain extension regions (734, 736) is higher than the atomic concentration of dopants of the first conductivity type in the finFET channel regions 735. For example, the atomic concentration of dopants of the second conductivity type in the finFET source/drain extension regions (734, 736) may be in a range from 1.0×10¹⁸/cm³ to 1.0×10²⁰/cm³, such as from 3.0×10¹⁸/cm³ to 3.0×10¹⁹/cm³. Each semiconductor fin 730 comprises a respective finFET channel region 735 located between a respective finFET source extension region 734 and a respective finFET drain extension region 736.

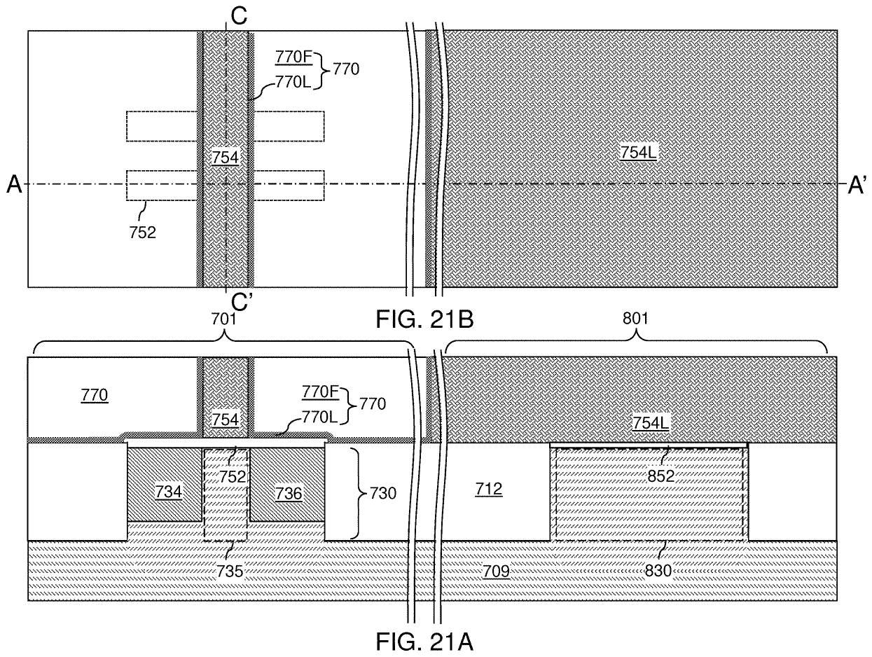

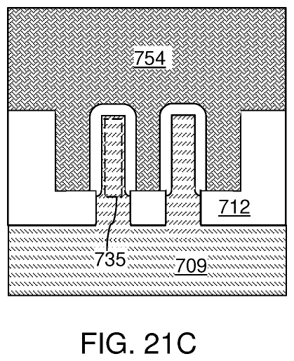

Referring to FIG. 21A-21C, at least one dielectric material can be deposited over the dielectric isolation layer 712, the gate electrode material layer 754L, and the finFET gate electrode 754. In one embodiment, the at least one dielectric material may comprise an optional dielectric liner material (such as a silicon nitride material and/or a dielectric metal oxide material) and a dielectric fill material (such as undoped silicate glass or a doped silicate glass). The deposited dielectric material(s) can be subsequently planarized to remove portions of the deposited dielectric material that overlie the horizontal plane including the top surface of the gate electrode material layer 754L. For example, a chemical mechanical polishing process may be performed to remove portions of the deposited dielectric material(s) from above the horizontal plane including the top surface of the gate electrode material layer 754L. The remaining portion of the deposited dielectric material(s) is herein referred to as a gate-level dielectric layer 770. The top surface of the gate-level dielectric layer 770 may be coplanar with the top surfaces of the gate electrode material layer 754L and the finFET gate electrode 754.

In one embodiment, the deposited dielectric materials may comprise a dielectric liner material and a dielectric fill material. In this case, the gate-level dielectric layer 770 may comprise a gate-level dielectric liner 770L and a gate-level dielectric fill material layer 770F. The gate-level dielectric liner 770L may comprise silicon nitride, silicon oxynitride, and/or at least one dielectric metal oxide (such as aluminum oxide, hafnium oxide, lanthanum oxide, tantalum oxide, titanium oxide, etc.). The thickness of the gate-level dielectric liner 770L may be in a range from 1 nm to 20 nm, such as from 2 nm to 10 nm, although lesser and greater thicknesses may also be employed. The gate-level dielectric fill material layer 770F may comprise a silicon oxide-based material such as undoped silicate glass (i.e., undoped silicon oxide) or a doped silicate glass.

Thus, the gate-level dielectric layer 770 can be formed around the finFET gate electrode 754 and on a sidewall of the remaining portion of the gate electrode material layer 754L, which may have a sidewall located at an interface between the first device region 701 and the second device region 801. The gate-level dielectric layer 770 can be planarized such that a top surface of the gate-level dielectric layer 770 is formed within a horizontal plane including a top surface of the remaining portion of the gate electrode material layer 754L. In one embodiment, the gate-level dielectric layer 770 continuously extends from each top surface of the at least one first gate dielectric 752 to a top surface of the first portion of the dielectric isolation layer 712, i.e., the portion of the dielectric isolation layer 712 located in the first device region 701. In one embodiment, the gate-level dielectric layer 770 continuous extends from sidewalls of the finFET gate electrode 754 to the top surface of the first portion of the dielectric isolation layer 712. In case a gate-level dielectric liner 770L is employed, the gate-level dielectric liner 770L may contact the top surface of the first portion of the dielectric isolation layer 712, the sidewalls of the finFET gate electrode 754, and a sidewall of the gate electrode material layer 754L, and may have a top surface in a horizontal plane including the top surface of the finFET gate electrode 754.

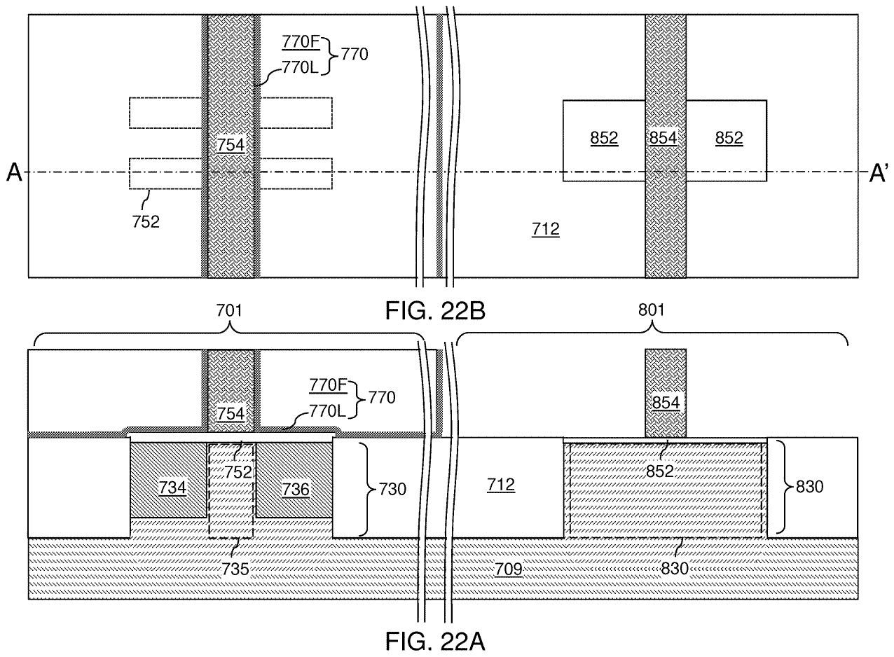

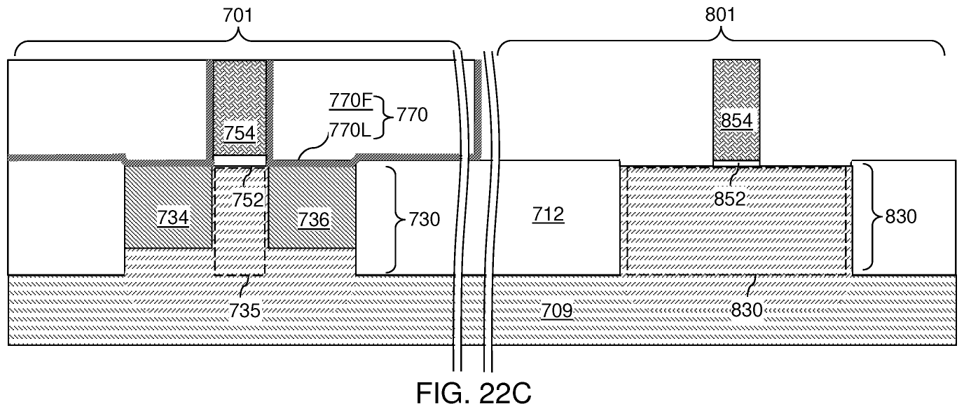

Referring to FIG. 22A-22B, a photoresist layer (not shown) can be applied over the gate-level dielectric layer 770 and the gate electrode material layer 754L, and can be lithographically patterned to cover the entirety of the first device region 701 and a portion of the gate electrode material layer 754L that overlies a center portion of the semiconductor active region 830 without covering portions of the gate electrode material layer 754L that does not overlie the center portion of the semiconductor active region 830. An anisotropic etch process can be performed to etch unmasked portions of the gate electrode material layer 754L in the second device region 801. The photoresist layer can be employed as an etch mask layer for the anisotropic etch process.

The anisotropic etch process can etch the unmasked portions of the gate electrode material layer 754L employing the second gate dielectric 852 and the dielectric isolation layer 712 as etch stop material portions. In other words, the etch chemistry of the anisotropic etch process can be selected such that the anisotropic etch process etches the material(s) of the gate electrode material layer 754L selective to the materials of the second gate dielectric 852 and the dielectric isolation layer 712. The etch selectivity of a terminal portion of the anisotropic etch process may be in range from 10 to 1,000. A patterned portion of the gate electrode material layer 754L that overlies the semiconductor active region 830 constitutes a gate electrode 854 for a planar field effect transistor, and is herein referred to as a planar-FET gate electrode 854 or a second gate electrode 854. The photoresist layer can be subsequently removed, for example, by ashing. Generally, the planar-FET gate electrode 854 is formed over the semiconductor active region 830 by patterning the remaining portion of the gate electrode material layer 754L. A sidewall of the gate-level dielectric layer 770, such as a sidewall of the gate-level dielectric liner 770L, may be physically exposed between the first device region 701 and the second device region 801.

In an alternative embodiment shown in FIG. 22C, the exposed portions of the second gate dielectric 852 that do not underlie the planar-FET gate electrode 854 can be etched away at the same time as the gate electrode material layer 754L. Thus, the sidewalls of the second gate dielectric 852 and the planar-FET gate electrode 854 can be vertically coincident. In this case, an upper portion of the dielectric isolation layer 712 may also be etched.

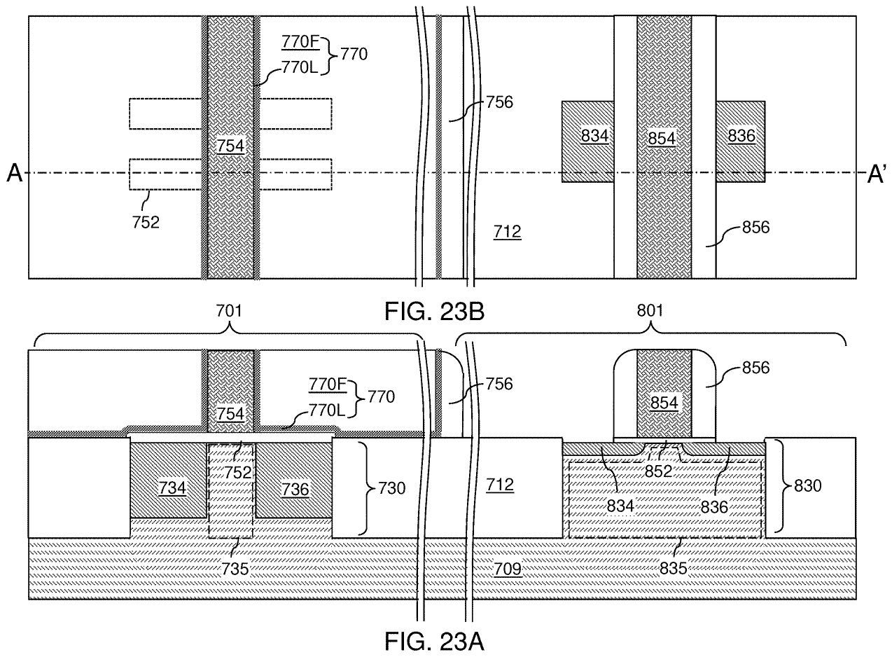

Referring to FIGS. 23A and 23B, a second extension (e.g., LDD) implantation process can be performed to implant dopants of the second conductivity type into portions of the semiconductor active region 830 that are not covered by the planar-FET gate electrode 854. In other words, portions of the semiconductor active region 830 that do not have an areal overlap with the planar-FET gate electrode 854 can be implanted with the dopants of the second conductivity type during an ion implantation process that employs the planar-FET gate electrode 854 as an etch mask.

Source/drain extension regions (e.g., LDD regions) are formed in portions of the semiconductor active region 830 that are implanted with the dopants of the second conductivity type. The source/drain extension regions that are formed in the semiconductor active region 830 are herein referred to as planar-FET source/drain extension regions (834, 836) or second source/drain extension regions (834, 836). The planar-FET source/drain extension regions (834, 836) comprise planar-FET source extension regions 834 and planar-FET drain extension regions 836. Unimplanted portions of the semiconductor active region 830 are herein referred to as planar-FET channel regions 835 or second channel regions 835.

In one embodiment, the thickness of the planar-FET source/drain extension regions (834, 836) may be the same as, or may be less than, the thickness of the planar-FET gate electrode 854. For example, the thickness of the planar-FET source/drain extension regions (834, 836) may be in a range from 30 nm to 200 nm, such as from 50 nm to 100 nm, although lesser and greater thicknesses may also be employed. The atomic concentration of dopants of the second conductivity type in the planar-FET source/drain extension regions (734, 836) is higher than the atomic concentration of dopants of the first conductivity type in the planar-FET channel region 835. For example, the atomic concentration of dopants of the second conductivity type in the planar-FET source/drain extension regions (834, 836) may be in a range from 1.0×10¹⁸/cm³ to 1.0×10²⁰/cm³, such as from 3.0×10¹⁸/cm³ to 3.0×10¹⁹/cm³. Each semiconductor active region 830 comprises a respective planar-FET channel region 835 located between a respective planar-FET source extension region 834 and a respective planar-FET drain extension region 836. Generally, the average atomic concentration of dopants of the second conductivity type in the planar-FET source/drain extension regions (834, 836) may be optimized for performance of the planar field effect transistor to be formed in the second device region 801, and can be different from the average atomic concentration of dopants of the second conductivity type in the finFET source/drain extension regions (734, 736).

At least one dielectric material layer, such as a silicon oxide layer and/or a silicon nitride layer, can be conformally deposited around the planar-FET gate electrode 854 by a respective conformal deposition process (such as a chemical vapor deposition process). An anisotropic etch process can be performed to etch horizontally-extending potions of the at least one dielectric material layer. A remaining vertically-extending portion of the at least one dielectric material layer that laterally surrounds the planar-FET gate electrode 854 constitutes a dielectric gate spacer (i.e., sidewall spacer) 856. A remaining vertically extending portion of the at least one dielectric material layer that contacts a sidewall of the gate-level dielectric layer 770 (such as a sidewall of a gate-level dielectric liner 770L) constitutes a dielectric gate spacer 756. Each of the dielectric gate spacer 856 and the dielectric gate spacer 756 may comprise a same set of at least one dielectric material, may have the same lateral thickness, and may comprise a respective straight inner sidewall and a respective contoured outer sidewall including a respective convex upper sidewall segment and a respective straight lower sidewall segment. The dielectric gate spacer 856 that laterally surrounds the planar-FET gate electrode 854 may have a different material composition than the gate-level dielectric layer 770 and/or the components thereof.

The planar-FET gate dielectric 852 may be collaterally patterned by the anisotropic etch process. For example, portions of the planar-FET gate dielectric 852 that do not underlie the planar-FET gate electrode 854 or the dielectric gate spacer 856 can be etched so that sidewalls of the planar-FET gate dielectric 852 are vertically coincident with (i.e., located within same vertical planes as) outer sidewalls of the dielectric gate spacer 856.

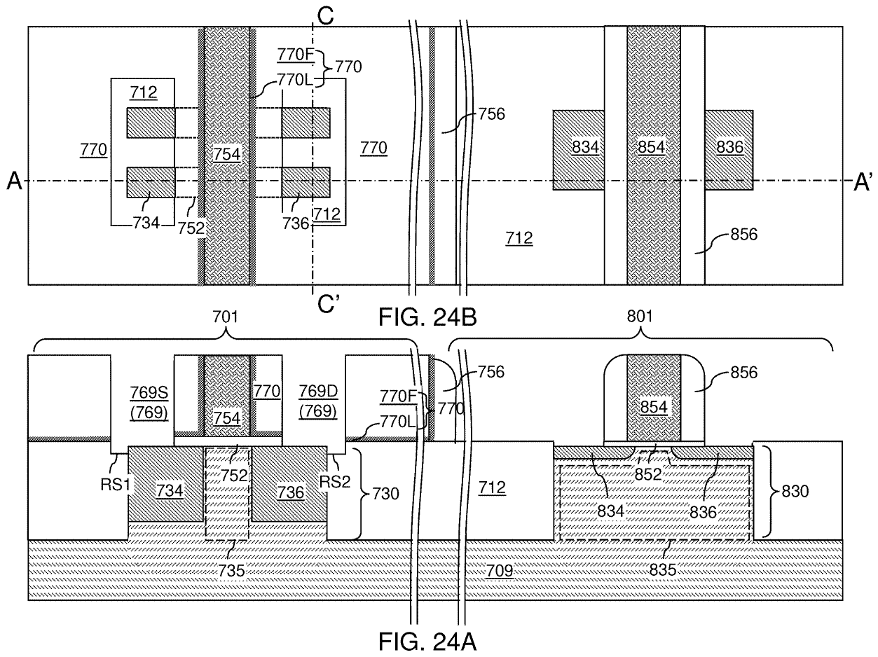

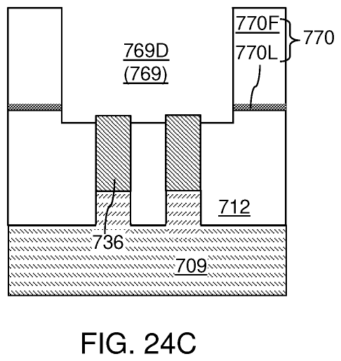

Referring to FIG. 24A-24C, a photoresist layer (not shown) can be applied over the dielectric isolation layer 712 and the gate-level dielectric layer 770, and can be lithographically patterned to form openings over portions of the finFET source/drain extension regions (734, 736) that are distal from the finFET gate electrode 754. The openings may comprise at least one first opening that is formed over a distal portion of at least one finFET source extension region 734, and at least one second opening that is formed over a distal portion of at least one finFET drain extension region 736. In one embodiment, the openings in the photoresist layer may comprise a first opening that overlies distal portions of multiple finFET source extension regions 734 and a second opening that overlies distal portions of multiple finFET drain extension regions 736. Alternatively, the openings in the photoresist layer may comprise multiple first openings that overlie a distal portion of a respective finFET source extension region 734 and multiple second openings that overlie a distal portion of a respective finFET drain extension region 736.

An anisotropic etch process can be performed to etch portions of the gate-level dielectric layer 770 that are not masked by the photoresist layer. The anisotropic etch process can etch the dielectric material(s) of the gate-level dielectric layer 770 selective to the semiconductor material (such as silicon) of the semiconductor fins 730. The anisotropic etch process may collaterally etch unmasked portions of the dielectric isolation layer 712 such that a first recessed surface RS1 can be formed around the distal portions of the finFET source extension regions 734, and a second recessed surface RS2 can be formed around the distal portions of the finFET drain extension region 736.

Source/drain openings 769 can be formed through the gate-level dielectric layer 770 and optionally into an upper portion of the dielectric isolation layer 712. The source/drain openings 769 comprise at least one source opening 769S that overlies at least one distal end of the finFET source extension regions 734, and at least one drain opening 769D that overlies at least one distal end of the finFET drain extension regions 736. Each finFET source extension region 734 may have a top surface segment and three sidewall surface segments that are exposed to a respective source opening 769S; and each finFET drain extension region 736 may have a top surface segment and three sidewall surface segments that are exposed to a respective drain opening 769D.

Generally, the source/drain openings 769 can be formed through the gate-level dielectric layer 770 around the finFET gate electrode 754. In one embodiment, the source/drain openings 769 may be laterally spaced from a respective proximal sidewall of the finFET gate electrode 754 by a minimum lateral spacing, which is selected such that electrical field in the finFET channel region 735 is substantially unaffected by small lateral changes in the position of the source/drain regions to be subsequently formed underneath the source/drain openings 769. In other words, a sufficient lateral distance is provided between proximal edges of the source/drain openings 769 and the finFET gate electrode 754 such that small changes in the lateral distance does not affect the functionality of the fin field effect transistor. In one embodiment, the lateral distance is provided between proximal edges of the source/drain openings 769 and the finFET gate electrode 754 may be greater than 50 nm, and/or 100 nm, and/or 200 nm, and/or 500 nm, and/or 800nm, and/or 1000nm.

In one embodiment, the first portion of the dielectric isolation layer 712 located in the first device region 701 may comprise at least one source-side recess region that underlies the at least one source opening 769S and at least one drain-side recess region that underlies the at least one drain opening 769D. In one embodiment, the at least one source-side recess region may have a first recessed surface RS1 that underlies a horizontal plane between an interface between the first portion of the dielectric isolation layer 712 and the gate-level dielectric layer 770, and may have a first vertical surface segment that is vertically coincident with a surface segment (i.e., a sidewall) of the at least one source opening 769S and is adjoined to the first recessed surface RS1. Further, the at least one drain-side recess region may have a second recessed surface RS2 that underlies the horizontal plane and having a second vertical surface segment that is vertically coincident with a surface segment (such as a sidewall) of the at least one drain opening 769D and is adjoined to the second recessed surface RS2. The depth of the first recessed surface RS1 and the second recessed surface RS2, as measured from the horizontal plane including the top surface of the first portion of the dielectric isolation layer 712 that contacts the gate-level dielectric layer 770 may be in a range from 3 nm to 100 nm, such as from 6 nm to 60 nm, although lesser and greater depths may also be employed. The photoresist layer can be subsequently removed, for example, by ashing.

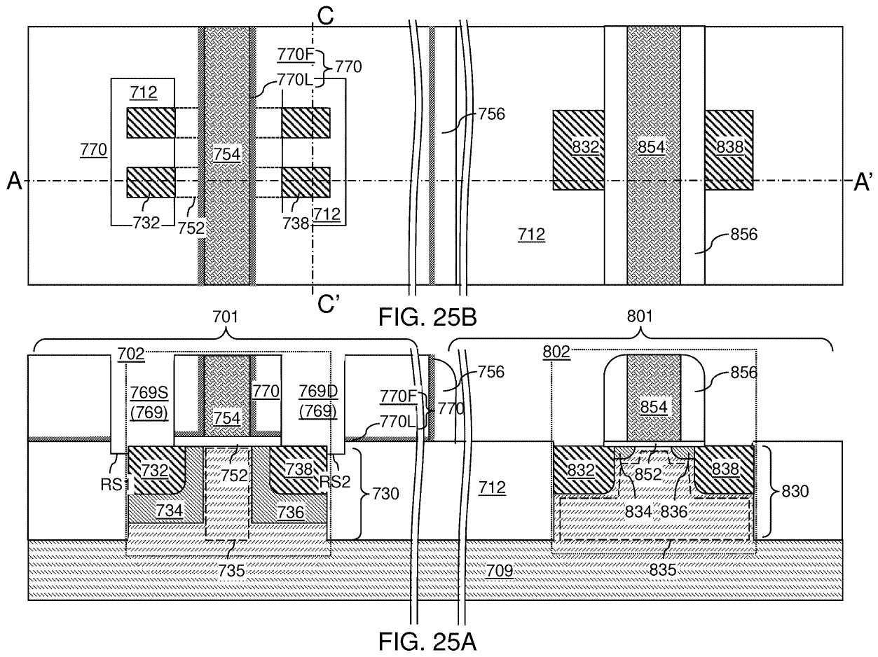

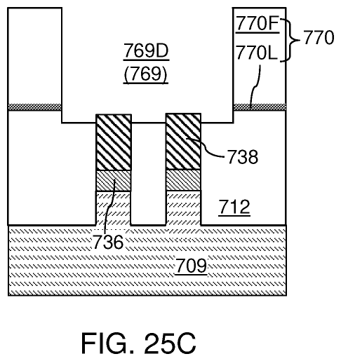

Referring to FIG. 25A-25C, an ion implantation process can be performed to implant dopants of the second conductivity type into portions of the semiconductor fins 730 that underlie the source/drain openings 769 and into portions of the semiconductor active region 830 that are not covered by the combination of the planar-FET gate electrode 854 and the dielectric gate spacer 856. Source/drain regions are formed in the implanted portions of the semiconductor fins 730 and the semiconductor active region 830. The source/drain regions comprise at least one finFET source region 732 that is formed in an upper corner of a respective finFET source extension region 734, at least one finFET drain region 738 that is formed in an upper corner of a respective finFET drain extension region 736, a planar-FET source region 832 that incorporates an implanted portion of the planar-FET source extension region 834 and a proximal implanted portion of the planar-FET channel region 835, and a planar-FET drain region 838 that incorporates an implanted portion of the planar-FET drain extension region 836 and a proximal implanted portion of the planar-FET channel region 835.

In one embodiment, the average atomic concentration of dopants of the second conductivity type in the source/drain regions (732, 738, 832, 838) may be in range from 5.0×10¹⁸/cm³ to 2.0×10²¹/cm³, such as from 1.0×10¹⁹/cm³ to 1.0×10²¹/cm³, although lesser and greater average atomic concentrations may also be employed. In one embodiment, the vertical thickness of the finFET source/drain regions (732, 738) may be the same as the vertical thickness of the planar-FET source/drain regions (832, 838). For example, the vertical thickness of the various source/drain extension regions (732, 738, 832, 838) may be the same, and may be in a range from 60 nm to 600 nm, such as from 100 nm to 300 nm, although lesser and greater thicknesses may also be employed.

In one embodiment, the vertical thickness of the finFET source/drain regions (732, 738) may be less than the vertical thickness of the finFET source/drain extension regions (734, 736). In contrast, the vertical thickness of the planar-FET source/drain regions (832, 838) may be greater than the vertical thickness of the planar-FET source/drain extension regions (834, 836).

Generally, at least one finFET source region 732 and at least one finFET drain region 738 can be formed within the at least one semiconductor fin 730 underneath the source/drain openings 769 through the gate-level dielectric layer 770, and a planar-FET source region 832 and a planar-FET drain region 838 can be formed within the semiconductor active region 830. Each of the at least one semiconductor fin 730 comprises a respective finFET channel region 735 located between a respective finFET source region 732 and a respective finFET drain region 738. In one embodiment, the gate-level dielectric layer 770 comprises at least one source opening 769S overlying each finFET source region 732 and at least one drain opening 769D overlying each finFET drain region 738.

A fin field effect transistor (finFET) 702 can be formed in the first device region 701. The finFET 702 comprises at least one semiconductor fin 730 that is laterally surrounded by a first portion of a dielectric isolation layer 712, at least one first gate dielectric 752 overlying the at least one semiconductor fin 730, a first gate electrode 754 straddling the at least one semiconductor fin 730, a gate-level dielectric layer 770 laterally surrounding the first gate electrode 754 and having a planar top surface that is coplanar with a top surface of the first gate electrode 754. A planar field effect transistor (planar FET) 802 can be formed in the second device region 801. The planar FET 802 comprises a semiconductor active region 830 that is laterally surrounded by a second portion of the dielectric isolation layer 712, a second gate dielectric 852 overlying a top surface of the semiconductor active region 830, and a second gate electrode 854 overlying the second gate dielectric 852.

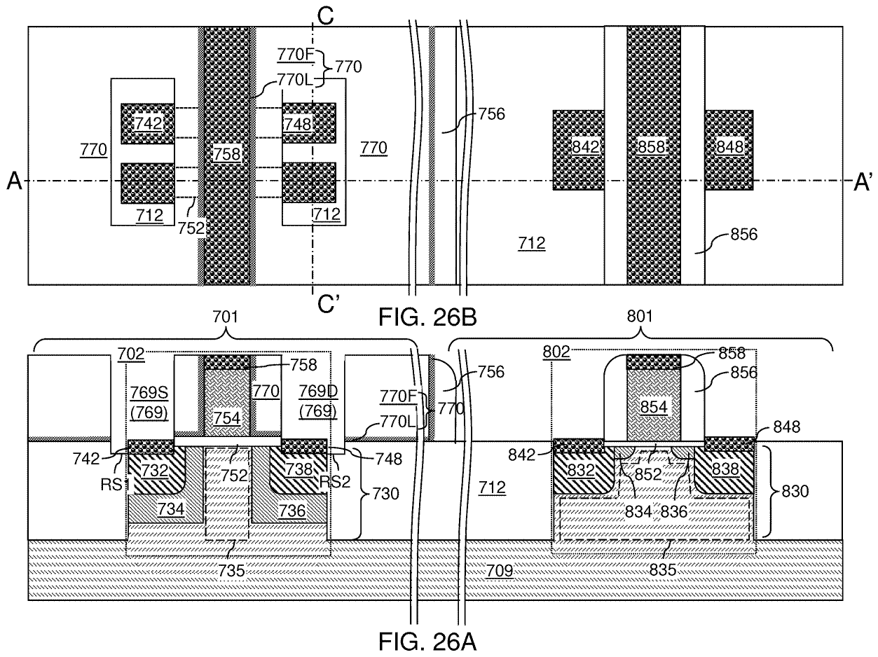

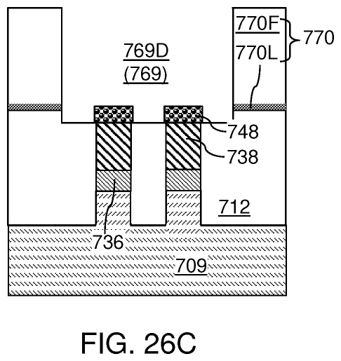

Referring to FIG. 26A-26C, a metal that forms a metal-semiconductor alloy (e.g., metal silicide) can be deposited on the physically exposed surfaces of the various source/drain regions (732, 738, 832, 838). The metal may also optionally the be deposited on top surfaces of the gate electrodes (754, 854) if the top surface of the gate electrodes comprises polysilicon. The metal may comprise, for example, tungsten, molybdenum, titanium, cobalt, nickel, platinum or palladium. An anneal process can be performed to induce formation of a metal-semiconductor alloy (such as a metal silicide) between the deposited metal and proximal surface portions of the various source/drain regions (732, 738, 832, 838) and optionally the gate electrodes (754, 854) that include a semiconductor material (such as silicon). The anneal may comprise a thermal anneal process conducted at a temperature in a range from 500 degrees Celsius to 900 degrees Celsius, a laser anneal or a rapid thermal anneal. Subsequently, a wet etch process that etches metal selective to a metal silicide material can be performed to remove unreacted portions of the deposited metal.

Metal-semiconductor alloy (e.g., metal silicide) regions (742, 748, 842, 848) can be formed on exposed portions of the source/drain regions (732, 738, 832, 838). Optional metal silicide regions (758, 858) may be formed on top surfaces of the gate electrodes (754, 854). The metal-semiconductor alloy regions (742, 748, 842, 848) may comprise a finFET source-side metal-semiconductor alloy region 742 that is formed on the finFET source region 732, a finFET drain-side metal-semiconductor alloy region 748 that is formed on the finFET drain region 738, a planar-FET source-side metal-semiconductor alloy region 842 that is formed on the planar-FET source region 832, and a planar-FET drain-side metal-semiconductor alloy region 848 that is formed on the planar-FET drain region 838. Each of the metal-semiconductor alloy regions (742, 748, 842, 848) may have a same thickness and a same material composition. The thickness of each metal-semiconductor alloy regions (742, 748, 842, 848) may be in range from 8 nm to 40 nm, such as from 10 nm to 30 nm, although lesser and greater thicknesses may also be employed. The metal silicide regions may be formed on the finFET 702 and the planar FET 802 at the same time during the same processing steps.

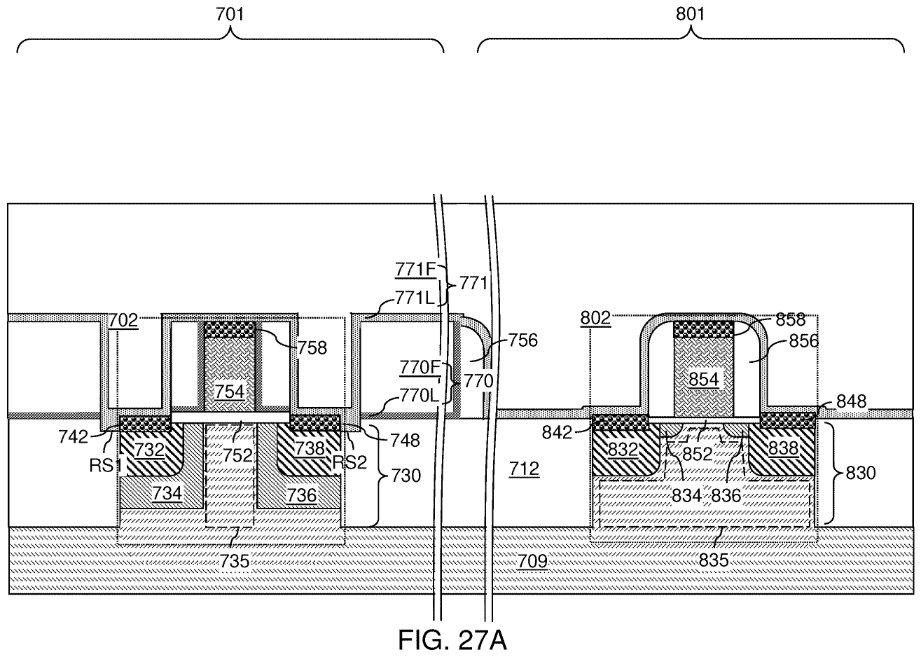

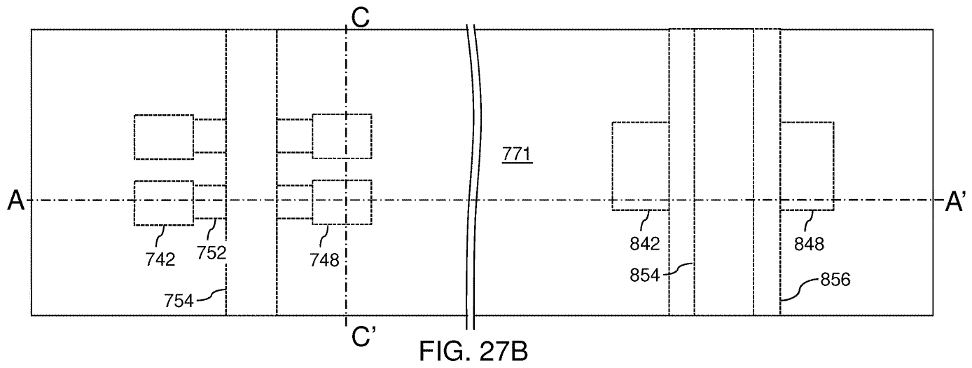

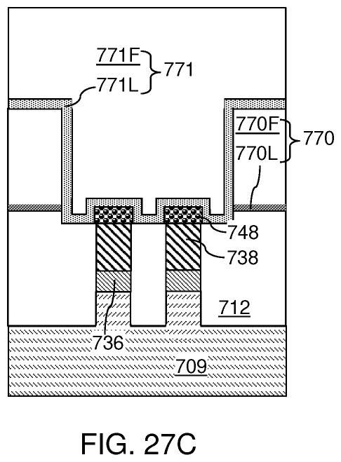

Referring to FIG. 27A-27C, at least one dielectric material can be deposited over the dielectric isolation layer 712 and the gate-level dielectric layer 770. In one embodiment, the at least one dielectric material may comprise an optional dielectric liner material (such as a silicon nitride material and/or a dielectric metal oxide material) and a dielectric fill material (such as undoped silicate glass or a doped silicate glass). The dielectric fill material may be self-planarizing, or may be planarized by performing a planarization process (such as a chemical mechanical polishing process). The deposited dielectric material(s) form a contact-level dielectric layer 771.

In one embodiment, the contact-level dielectric layer 771 may comprise a dielectric liner material and a dielectric fill material. In this case, the contact-level dielectric layer 771 may comprise a contact-level dielectric liner 771L and a contact-level dielectric fill material layer 771F. The contact-level dielectric liner 771L may comprise silicon nitride, silicon oxynitride, and/or at least one dielectric metal oxide (such as aluminum oxide, hafnium oxide, lanthanum oxide, tantalum oxide, titanium oxide, etc.). The thickness of the contact-level dielectric liner 771L may be in a range from 1 nm to 20 nm, such as from 2 nm to 10 nm, although lesser and greater thicknesses may also be employed. The material composition of the contact-level dielectric liner 771L may be the same as, or may be different from, the material composition of the gate-level dielectric liner 770L. The contact-level dielectric fill material layer 771F may comprise a silicon oxide-based material such as undoped silicate glass or a doped silicate glass.

In one embodiment, the contact-level dielectric layer 771 can have a first bottom surface contacting a top surface of the second portion of the dielectric isolation layer 712 in the second device region 801, and can have a second bottom surface overlying and contacting the gate-level dielectric layer 770 in the first device region 701. In one embodiment, the gate-level dielectric layer 770 is not present within the second device region 801. In one embodiment, the entirety of a dielectric-to-dielectric interface containing the top surface of the second portion of the dielectric isolation layer 712 may be an interface between the top surface of the second portion of the dielectric isolation layer 712 and the contact-level dielectric layer 771. In one embodiment, the entirety of the top surface of the second portion of the dielectric isolation layer 712 contacts the first bottom surface of the contact-level dielectric layer 771.

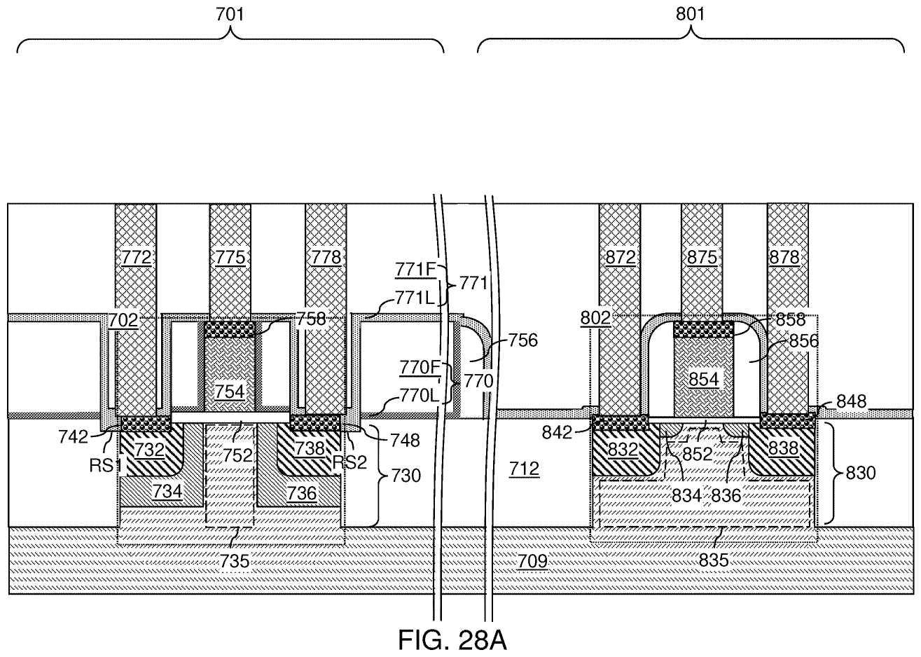

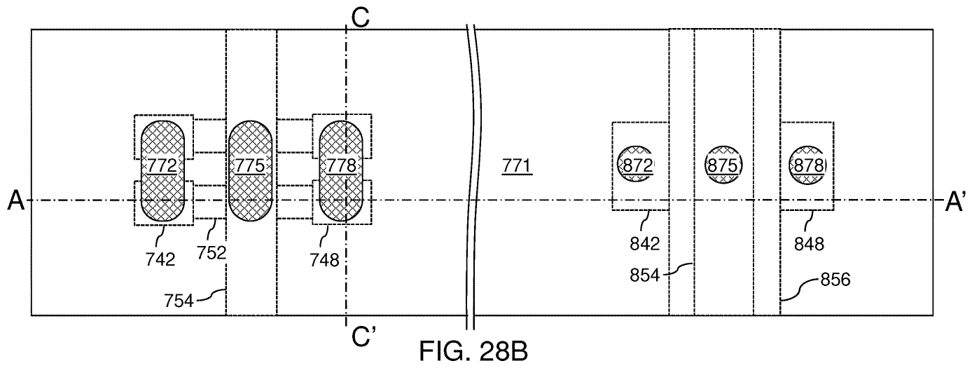

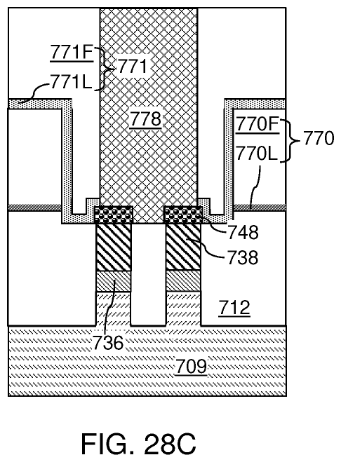

Referring to FIG. 28A-28C, a photoresist layer (not shown) can be applied over the top surface of the contact-level dielectric layer 771, and can be lithographically patterned to form openings in areas that overlie the gate electrodes (754, 854) (which may be covered with metal-semiconductor alloy regions (758, 858)) or the source/drain regions (732, 738, 832, 838) (which may be covered with metal-semiconductor alloy regions (742, 748, 842, 848)). An anisotropic etch process can be performed to form contact via cavities that vertically extend through the contact-level dielectric layer 771. The contact via cavities may comprise gate contact via cavities that overlie the gate electrodes (754, 854), source contact via cavities that overlie the source regions (732, 832), and drain contact via cavities that overlie the drain regions (738, 838). Top surfaces of the gate electrodes (754, 854) (or the overlying metal-semiconductor alloy regions (758, 858) if present) can be exposed at the bottom of the gate contact via cavities. Top surfaces of the source-side metal-semiconductor alloy regions (742, 842) can be exposed at the bottom of the source contact via cavities. Top surfaces of the drain-side metal-semiconductor alloy regions (748, 848) can be exposed at the bottom of the drain contact via cavities.

At least one conductive material, such as at least one metallic material, can be deposited in the various contact via cavities. Excess portions of the at least one conductive material can be removed from above the horizontal plane including the top surface of the contact-level dielectric layer 771 by performing a planarization process, which may comprise a recess etch process and/or a chemical mechanical polishing process. Various contact via structures (775, 875, 772, 872, 778, 878) can be formed in the various contact via cavities. The various contact via structures (775, 875, 772, 872, 778, 878) may comprise at least one finFET gate contact via structure 775 (which is also referred to as at least one first gate contact via structure 775), at least one finFET source contact via structure 772 (which is also referred to as at least one first source contact via structure 772), at least one finFET drain contact via structure 778 (which is also referred to as at least one first drain contact via structure 778), at least one planar-FET gate contact via structure 875 (which is also referred to as a second gate contact via structure 875), at least one planar-FET source contact via structure 872 (which is also referred to as at least one second source contact via structure 872), and at least one planar-FET drain contact via structure 878 (which is also referred to as at least one second drain contact via structure 878).

In one embodiment, the at least one first source contact via structure 772 does not contact and is laterally spaced by the first portion of the contact-level dielectric layer 771 from the gate-level dielectric layer 770; and the at least one first drain contact via structure

778 does not contact and is laterally spaced by the second portion of the contact-level dielectric layer 771 from the gate-level dielectric layer 770.

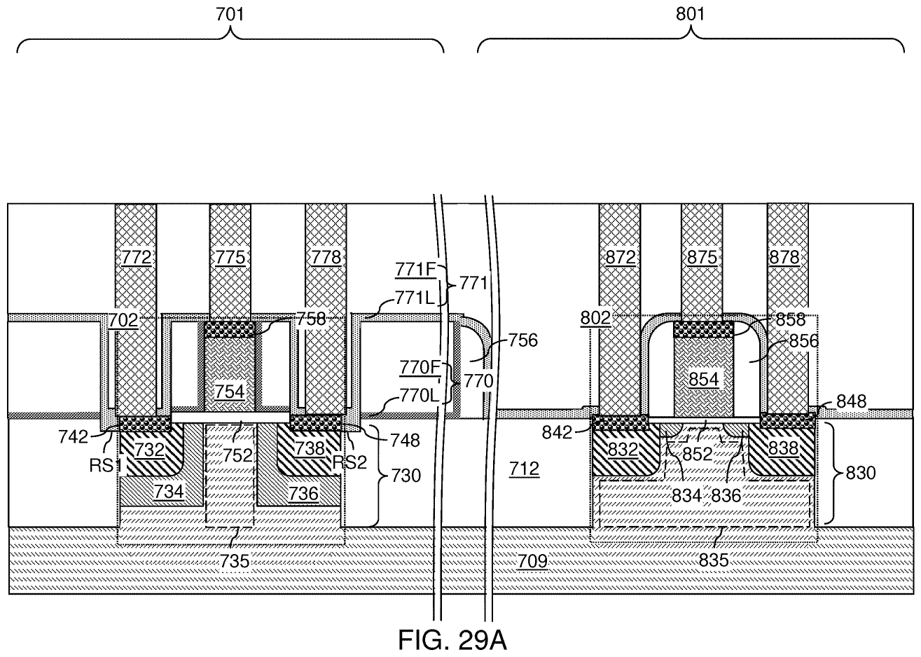

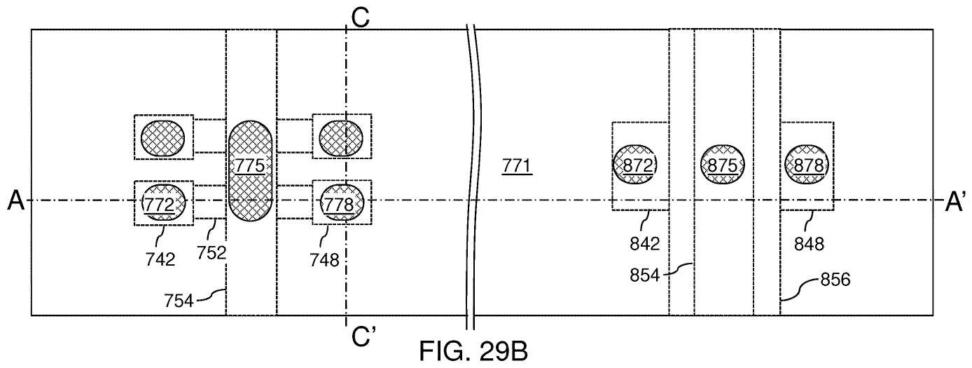

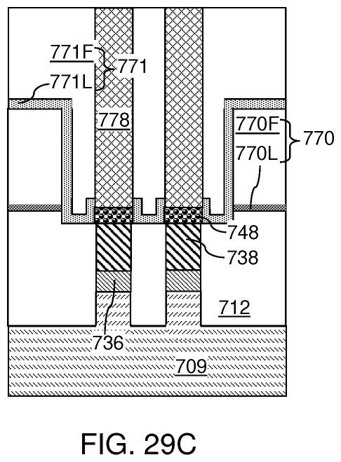

Referring to FIG. 29A-29C, an alternative configuration of the second exemplary structure can be derived from the second exemplary structure illustrated in FIG. 28A-28C forming a plurality of finFET source contact via structures 772 (which is also referred to as a plurality of first source contact via structures 772), and a plurality of finFET drain contact via structures 778 (which is also referred to as a plurality of first drain contact via structures 778) for each finFET 702. For example, as shown in FIG. 29B, there are two finFET source contact via structures 772 and two finFET drain contact via structures 778 for each finFET 702 instead of one such structures (772, 778) for each finFET illustrated in FIG. 28B. Each finFET source contact via structure 772 can contact a respective finFET source-side metal-semiconductor alloy region 742, and each finFET drain contact via structure 778 can contact a respective finFET drain-side metal-semiconductor alloy region 748.

In one embodiment, the at least one semiconductor fin 730 comprises a plurality of semiconductor fins 730 that are laterally spaced from each other; the at least one first source contact via structure 772 is in contact with a first sidewall of the gate-level dielectric layer 770; and the at least one first drain contact via structure 778 is in contact with a second sidewall of the gate-level dielectric layer 770.

Referring collectively to FIG. 28A-29C, at least one first source contact via structure 772 vertically extends through the at least one source opening 769S and is electrically connected to each finFET source region 732; and at least one first drain contact via structure 778 vertically extends through the at least one drain opening 769D and is electrically connected to each finFET drain region 738. The at least one first source contact via structure 772 contacts a first portion of the contact-level dielectric layer 771 that extends downward from second bottom surface of the contact-level dielectric layer 771 into the at least one source opening 769S of the gate-level dielectric layer 770; and the at least one first drain contact via structure 778 contacts a second portion of the contact-level dielectric layer 771 that extends downward from second bottom surface of the contact-level dielectric layer 771 into the at least one drain opening 769D of the gate-level dielectric layer 770.

In one embodiment, the semiconductor active region 830 comprises a channel region 835, a planar-FET source region 832, and a planar-FET drain region 838; a second source contact via structure 872 vertically extends through the contact-level dielectric layer 771 and is electrically connected to the planar-FET source region 832; and a second drain contact via structure 878 vertically extends through the contact-level dielectric layer 771 and is electrically connected to the planar-FET drain region 838.

In one embodiment, top surfaces of the at least one first source contact via structure 772, the at least one first drain contact via structure 778, the second source contact via structure 872, and the second drain contact via structure 878 are located within a horizontal plane including a top surface of the contact-level dielectric layer 771.

Referring to FIG. 30, the second exemplary structure is shown in a zoom-out view. Multiple instances of the second exemplary structure(s) illustrated in FIG. 28A-28C and/or FIG. 29A-29C can be formed over the logic-side substrate 709 to form a peripheral circuit 720. According to an aspect of the present disclosure, the peripheral circuit 720 can be configured to control operation of the memory array within the memory die 900 illustrated in FIG. 13. The finFET 702 and the planar FET 802 illustrated in FIGS. 28A and 29A may comprise portions of the word line switching circuit of the peripheral devices. The word line switching circuit controls the operation of the word lines 46 within the memory die 900.

A logic die 700 includes logic-side metal interconnect structures 780 embedded within logic-side dielectric material layers 760 formed over the logic-side substrate 709 (which may comprise a semiconductor substrate) and peripheral circuitry 720 including multiple instances of the second exemplary structure (e.g., the transistors 702 and 802). Generally, the fin field effect transistors 702 and the planar field effect transistors 802 are formed within a logic die 700 including a logic-side semiconductor substrate 709. Each semiconductor fin 730 and each semiconductor active region 830 may comprise portions of the logic-side semiconductor substrate 709. The logic die 700 comprises logic-side bonding pads 788 embedded within logic-side dielectric material layers 760.

In one embodiment, the logic die 700 comprises multiple instances of the fin field effect transistor 702 and multiple instances of the planar field effect transistors 802 illustrated in FIG. 28A-28C and/or FIG. 29A-29C. The multiple instances of the fin field effect transistor 702 can be employed for high voltage switching devices, such as word line drivers for a two-dimensional array of NAND strings. The multiple instances of the planar field effect transistor 802 can be employed for low voltage switching devices of the peripheral circuitry of the two-dimensional array of NAND strings.

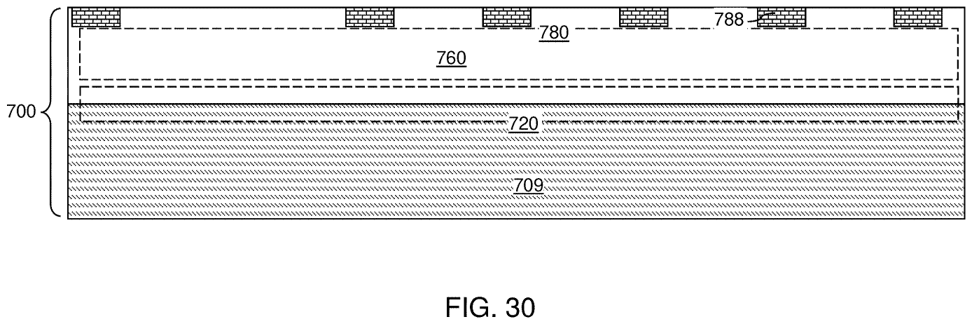

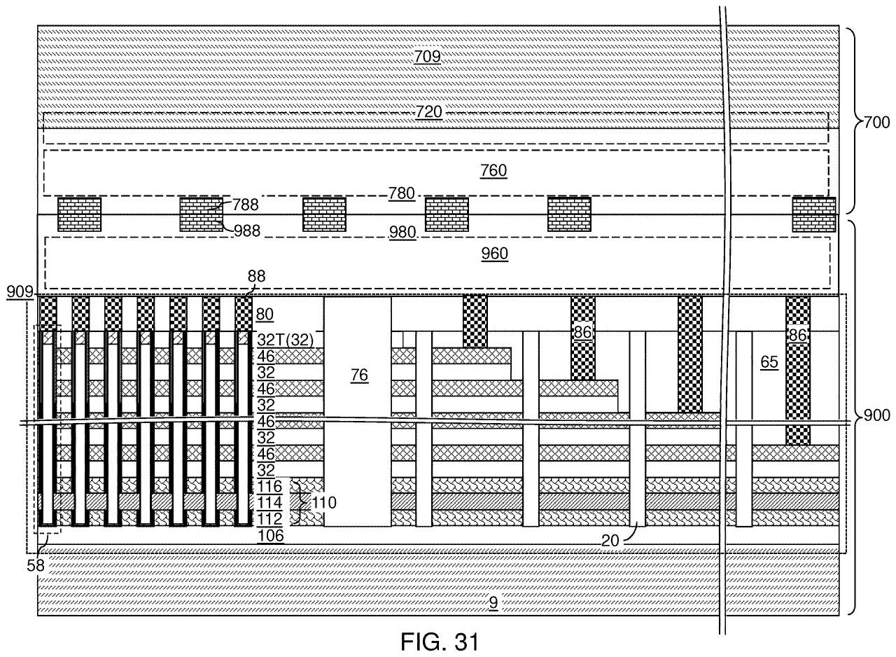

Referring to FIG. 31, a bonded assembly can be formed by bonding the logic die 700 with the memory die 900. The logic die 700 can be attached to the memory die 900, for example, by bonding the logic-side bonding pads 788 to the memory-side bonding pads 988. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

Referring to all drawings and according to various embodiments of the present disclosure, a semiconductor structure comprises a logic die 700 comprising a word line switching circuit (e.g., portion of the peripheral circuit 720) containing a fin field effect transistor 702 comprising at least one semiconductor fin 730, and a planar field effect transistor 802; and a memory die 900 bonded to the logic die, wherein the memory die comprises a three-dimensional memory device 909.

The fin field effect transistor 702 is located in a first device region 701 of the logic die 700. The fin field effect transistor 702 comprises a dielectric isolation layer 712, wherein the at least one semiconductor fin 730 is laterally surrounded by a first portion of the dielectric isolation layer 712, at least one first gate dielectric 752 overlying the at least one semiconductor fin 730, a first gate electrode 754 straddling the at least one semiconductor fin 730, a gate-level dielectric layer 770 laterally surrounding the first gate electrode 754 and having a planar top surface that is coplanar with a top surface of the first gate electrode 754. The planar field effect transistor 802 is located in a second device region 801 of the logic die 700. The planar field effect transistor 802 comprises a semiconductor active region 830 that is laterally surrounded by a second portion of the dielectric isolation layer 712, a second gate dielectric 852 overlying a top surface of the semiconductor active region 830, and a second gate electrode 854 overlying the second gate dielectric 852. The gate-level dielectric layer 770 is not present within the second device region 801.

In one embodiment, the semiconductor structure further comprises a contact-level dielectric layer 771 having a first bottom surface contacting a top surface of the second portion of the dielectric isolation layer 712 in the second device region 801 and having a second bottom surface overlying the gate-level dielectric layer 770 in the first device region 701,

In one embodiment, the semiconductor structure comprises a dielectric gate spacer 856 that laterally surrounds the second gate electrode 854 and having a different material composition than the gate-level dielectric layer 770.

In one embodiment, the gate-level dielectric layer 770 continuously extends from each top surface of the at least one first gate dielectric 752 to a top surface of the first portion of the dielectric isolation layer 712. In one embodiment, the gate-level dielectric layer 770 continuous extends from sidewalls of the first gate electrode 754 to a top surface of the first portion of the dielectric isolation layer 712.

In one embodiment, an entirety of a dielectric-to-dielectric interface containing the top surface of the second portion of the dielectric isolation layer 712 is an interface between the top surface of the second portion of the dielectric isolation layer 712 and the contact-level dielectric layer 771. In one embodiment, an entirety of the top surface of the second portion of the dielectric isolation layer 712 contacts the first bottom surface of the contact-level dielectric layer 771.

In one embodiment, each of the at least one semiconductor fin 730 comprises a respective finFET channel region 735, a respective finFET source region 732, and a respective finFET drain region 738; the gate-level dielectric layer 770 comprises at least one source opening 769S overlying each finFET source region 732 and at least one drain opening 769D overlying each finFET drain region 738; at least one first source contact via structure 772 vertically extends through the at least one source opening 769S and is electrically connected to said each finFET source region 732; and at least one first drain contact via structure 778 vertically extends through the at least one drain opening 769D and is electrically connected to said each finFET drain region 738.

In one embodiment, the at least one first source contact via structure 772 contacts a first portion of the contact-level dielectric layer 771 that extends downward from second bottom surface of the contact-level dielectric layer 771 into the at least one source opening 769S of the gate-level dielectric layer 770; and the at least one first drain contact via structure 778 contacts a second portion of the contact-level dielectric layer 771 that extends downward from second bottom surface of the contact-level dielectric layer 771 into the at least one drain opening 769D of the gate-level dielectric layer 770.

In one embodiment, the at least one semiconductor fin 730 comprises a plurality of semiconductor fins 730 that are laterally spaced from each other; the at least one first source contact via structure 772 is in contact with a first sidewall of the gate-level dielectric layer 770; and the at least one first drain contact via structure 778 is in contact with a second sidewall of the gate-level dielectric layer 770.

In one embodiment, the at least one first source contact via structure 772 does not contact, and is laterally spaced by the first portion of the contact-level dielectric layer 771 from, the gate-level dielectric layer 770; and the at least one first drain contact via structure 778 does not contact, and is laterally spaced by the second portion of the contact-level dielectric layer 771 from, the gate-level dielectric layer 770.

In one embodiment, the first portion of the dielectric isolation layer 712 comprises: at least one source-side recess region having a first recessed surface RS1 that underlies a horizontal plane between an interface between the first portion of the dielectric isolation layer 712 and the gate-level dielectric layer 770 and having a first vertical surface segment that is vertically coincident with a surface segment of the at least one source opening 769S; and at least one drain-side recess region having a second recessed surface RS2 that underlies the horizontal plane and having a second vertical surface segment that is vertically coincident with a surface segment of the at least one drain opening 769D.

In one embodiment, the semiconductor active region 830 comprises a channel region 835 located between a planar-FET source region 832 and a planar-FET drain region 838; a second source contact via structure 872 vertically extends through the contact-level dielectric layer 771 and is electrically connected to the planar-FET source region 832: and a second drain contact via structure 878 vertically extends through the contact-level dielectric layer 771 and is electrically connected to the planar-FET drain region 838. In one embodiment, top surfaces of the at least one first source contact via structure 772, the at least one first drain contact via structure 778, the second source contact via structure 872, and the second drain contact via structure 878 are located within a horizontal plane including a top surface of the contact-level dielectric layer 771.

In one embodiment, the logic die 700 comprises a logic-side semiconductor substrate 709; the at least one semiconductor fin 730 and the semiconductor active region 830 comprise portions of the logic-side semiconductor substrate 709; the logic die 700 comprises logic-side bonding pads 788 embedded within logic-side dielectric material layers 760; and the semiconductor structure comprises a memory die 900 including a memory device and memory-side bonding pads 988 that are embedded within memory-side dielectric material layers 960 and bonded to the logic-side bonding pads 788.

In the bonded assembly of the logic die 700 and memory die 900, the size of the word line switching circuit on the logic die 700 may be greater than the size of the corresponding memory array portion in the memory die 900 that is controlled by the word line switching circuit. Therefore, the use of the finFET 702 in the word line switching circuit decreases the size of the word line switching circuit because the high voltage finFET 702 takes up less area (e.g., has a lower width, such as at least 40% lower width) than a high voltage planar FET. Furthermore, the finFET 702 permits a reduction in the maximum operating voltage of the word line switching circuit compared to a high voltage planar FET. Specifically, the high voltage finFET 702 has a reduced threshold voltage at high V_{b} which leads to a back bias effect improvement by about 3V for a narrower effective transistor width, resulting in a reduced maximum chip voltage.

According to an aspect of the present disclosure, fin field effect transistors for high voltage operations, for example, within a voltage range from about 11 V to 30 V, and/or from 15 V to 25 V, and planar field effect transistors for low voltage operations, for example, with a voltage range from about 1.0 V to 10 V, and/or from about 1.5 V to 6.0 V, may be simultaneously manufactured in word line switching circuit of a logic die 700 configured to control operation of a memory array. A memory die 900 including a three-dimensional memory device can be bonded to the logic die 700. A compact logic die 700 providing a higher density of devices can be provided by employing a combination of fin field effect transistors and planar field effect transistors in the logic die 700.

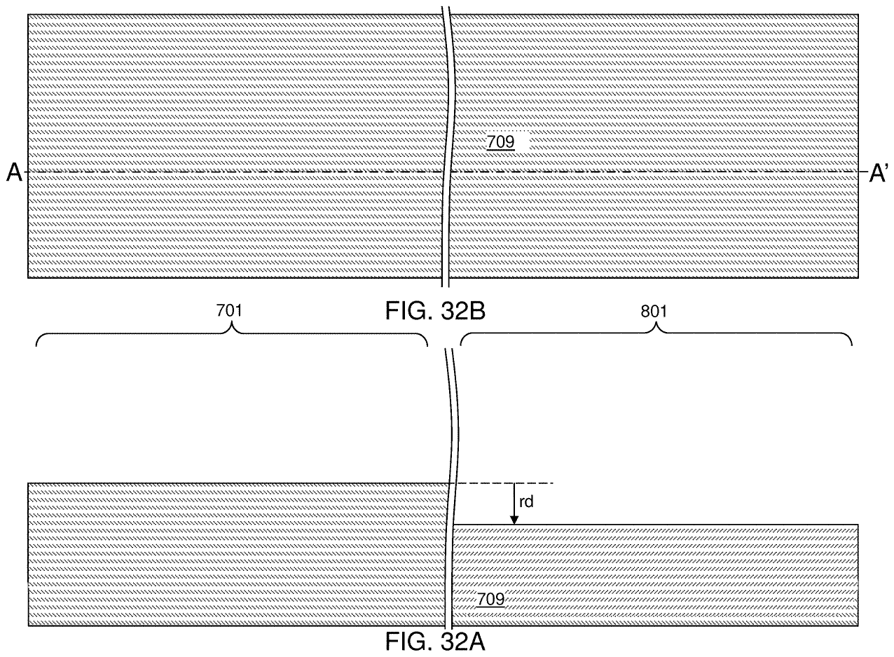

Referring to FIGS. 32A and 32B, a third exemplary structure according to an embodiment of the present disclosure comprises a logic-side substrate 709, which can be a logic-side semiconductor substrate. A photoresist layer (not shown) can be applied over a top surface of the logic-side substrate 709, and can be lithographically patterned to cover the first device region 701 without covering a second device region 801. A portion of the top surface of the logic-side substrate 709 located in the second device region 801 can be vertically recessed by a vertical recess distance rd by performing an etch process while the first device region 701 is masked by the photoresist layer. The vertical recess distance rd may be in a range from 50 nm to 200 nm, although lesser and greater vertical recess distances may also be employed.

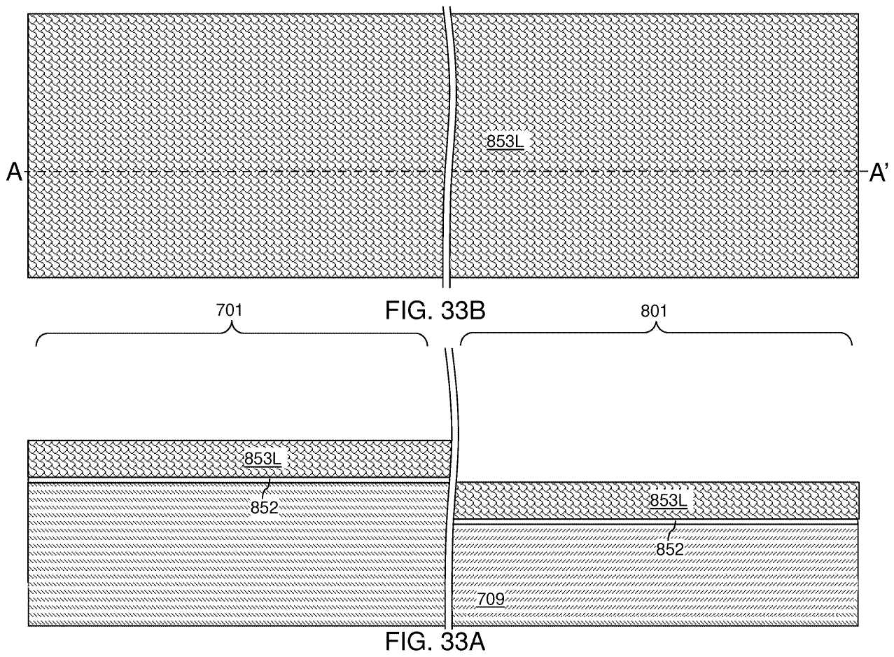

Referring to FIGS. 33A and 33B, a gate dielectric layer is formed, for example, by thermal oxidation of a surface portion of the logic-side substrate 709 and/or by deposition of a gate dielectric material. The gate dielectric layer that is formed at this processing step is subsequently employed as a gate dielectric for a second field effect transistor to be subsequently formed in the second device region 801, and may be referred to as a second gate dielectric 852, or as a planar-FET gate dielectric 852, or as a first gate dielectric layer. As discussed above, an ordinal is generally an adjective and is not a part of a name of an element. The second gate dielectric 852 may have any of the material compositions and thickness ranges as described with reference to the first exemplary structure and the second exemplary structure.

A gate electrode material layer can be deposited. This gate electrode material layer is herein referred to as a planar-FET gate electrode material layer 853L, and may also be referred to as a second gate electrode material layer or a first gate electrode material layer. In one embodiment, the planar-FET gate electrode material layer 853L may comprise polysilicon. The polysilicon may be undoped (i.e., does not include any intentionally-introduced dopants), or may be p-doped or n-doped. Generally, the planar-FET gate electrode material layer 853L may be doped during deposition (i.e., in-situ), or at a subsequent processing step, to provide electrical dopants of a suitable conductivity type at a suitable atomic concentration.

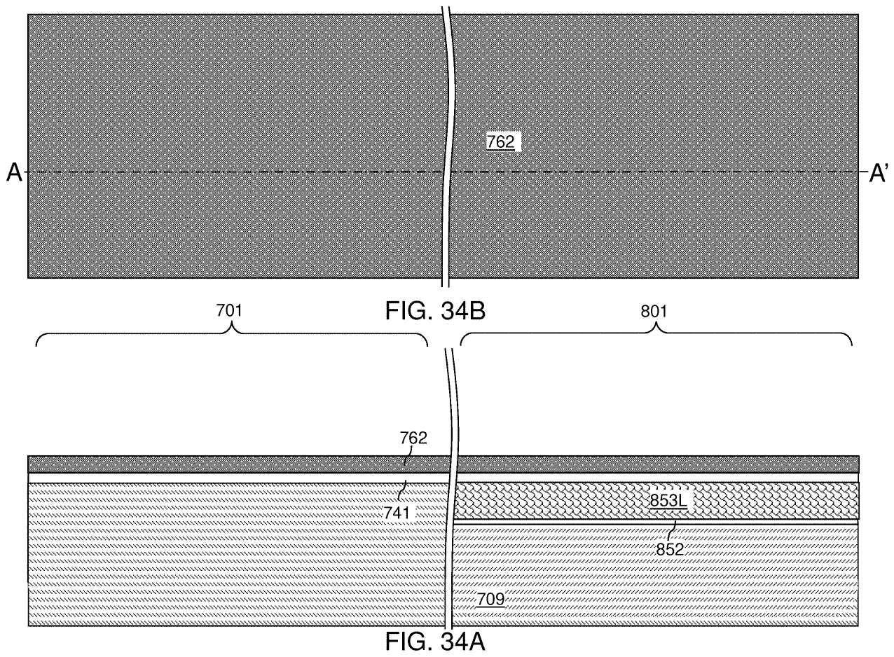

Referring to FIGS. 34A and 34B, portions of the planar-FET gate electrode material layer 853L and the planar transistor gate dielectric 852 located in the first device region 701 can be removed (e.g., by reactive ion etching) while the portions of the planar-FET gate electrode material layer 853L and the planar transistor gate dielectric 852 located in the second device region 801 are coved with a suitable patterned mask layer (not illustrated), such as a patterned photoresist layer. The patterned mask layer can be subsequently removed. An optional planarization process, such as a chemical mechanical polishing (CMP) process, can be performed to planarize top surfaces of the logic-side substrate 709 in the first device region 701 and a top surface of the planar-FET gate electrode material layer 853L in the second device region 801. In this case, the top surface of the logic-side substrate 709 in the first device region 701 and the top surface of the planar-FET gate electrode material layer 853L in the second device region 801 may be formed within a same horizontal plane.

An optional pad silicon oxide layer 741 and a hard mask layer 762 may be subsequently formed over the logic-side substrate 709 and the planar-FET gate electrode material layer 853L which is located in the second device region 801. The pad silicon oxide layer 741 (if present) may have a thickness in a range from 5 nm to 50 nm. Alternatively, the pad silicon oxide layer 741 may be omitted. The hard mask layer 762 comprises a material that can function as a planarization stopper layer during a subsequent planarization process. In one embodiment, the hard mask layer 762 comprises silicon nitride. The thickness of the hard mask layer 762 may be in a range from 100 nm to 300 nm, although lesser and greater thicknesses may also be employed.

Referring collectively to FIG. 32A-34B, a semiconductor substrate (such as a logic-side substrate 709) comprising a first device region 701 and a second device region 801 can be provided, and a planar-FET gate dielectric 852 and a first gate electrode material layer (such as a planar-FET gate electrode material layer 853L) comprising a first gate electrode material can be formed in the second device region 801 without covering the first device region 701 with the first gate electrode material. In one embodiment, the planar-FET gate dielectric 852 may be formed entirely below a horizontal plane including a topmost surface of the semiconductor substrate (such as the logic-side substrate 709).

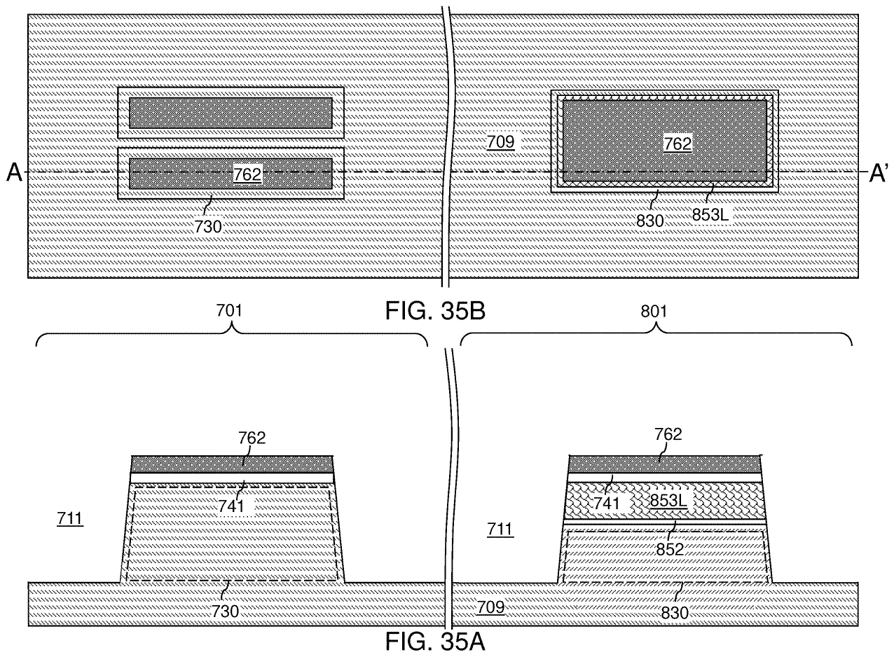

Referring to FIGS. 35A and 35B, a photoresist layer can be applied over the hard mask layer 762, and can be patterned into the pattern of semiconductor fins 730 and semiconductor active regions 830 to be subsequently formed. A first anisotropic etch process can be performed to transfer the pattern of the photoresist layer through the hard mask layer 762 and the pad silicon oxide layer 741. The photoresist layer may be subsequently removed, for example, by ashing. A second anisotropic etch process may be performed to transfer the pattern in the patterned hard mask layer 762 through the planar-FET gate electrode material layer 853L and the planar-FET gate dielectric 852 and into an upper portion of the semiconductor substrate, i.e., the logic-side substrate 709. In an alternative embodiment, the second anisotropic etch process can be performed while the photoresist layer is present over the patterned hard mask layer 762, and may be partially or fully consumed during the second anisotropic etch process. Any remaining portion of the photoresist layer, if present, may be removed after the second anisotropic etch process.

The second anisotropic etch process forms a continuous recess cavity 711, which is also referred to as a moat trench 711. Semiconductor fins 730 are formed in the first device region 701, and a semiconductor active region 830 is formed in the second device region 801. The moat trench laterally surrounds each of the semiconductor fins 730 and the semiconductor active regions 830 in a mot configuration, i.e., laterally encircles each of the semiconductor fins 730 and the semiconductor active regions 830. The pattern of the semiconductor fins 730 and the semiconductor active region 830 may be the same as described with reference to FIGS. 14A and 14B. Generally, the sidewalls of the semiconductor fins 730 and the semiconductor active region 830 may be vertical or may have a taper angle not greater than 15 degrees.

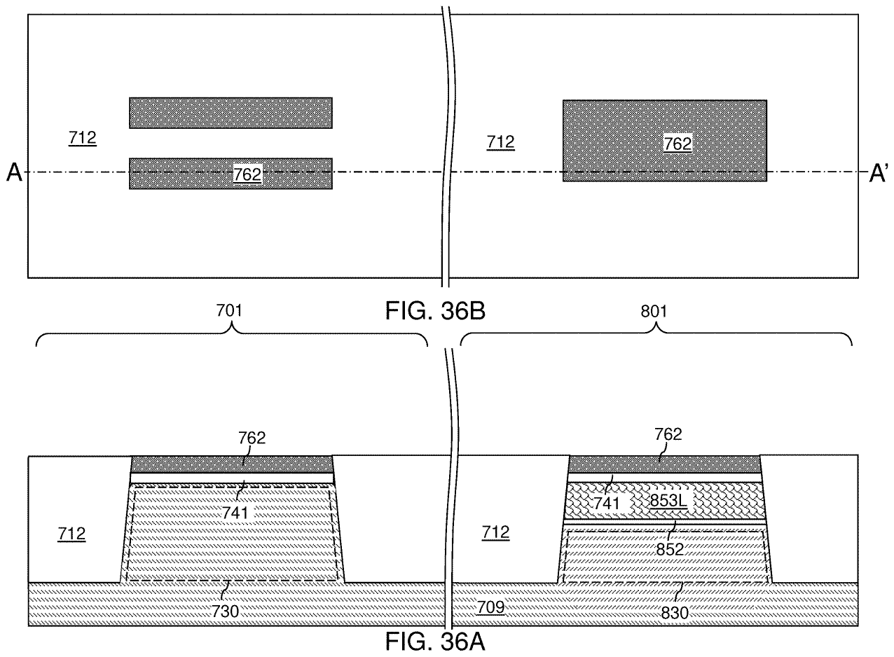

Referring to FIGS. 36A and 36B, a dielectric fill material such as silicon oxide (e.g. non-doped silicate glass) can be deposited in the continuous recess cavity 711 (i.e., the moat trench). Excess portions of the dielectric fill material located above the horizontal plane including the top surfaces of the patterned hard mask layer 762 can be removed by a planarization process, such as a chemical mechanical polishing (CMP) process. Remaining portions of the dielectric fill material filling the continuous recess cavity 711 constitute a dielectric isolation layer. The portion of the dielectric isolation layer in the first device region 701 is herein referred to as a first dielectric isolation layer 712, and the portion of the dielectric isolation layer in the second device region 801 is herein referred to as a second dielectric isolation layer 712. The first dielectric isolation layer 712 laterally surrounds the semiconductor fins 730. The second dielectric isolation layer 712 laterally surrounds the semiconductor active region 830. In one embodiment, the bottom surfaces of the dielectric isolation layers 712 may be formed within a same horizontal plane. For example, the bottom surface of the first dielectric isolation layer 712 and the bottom surface of the second dielectric isolation layer 712 may be formed within a same horizontal plane.

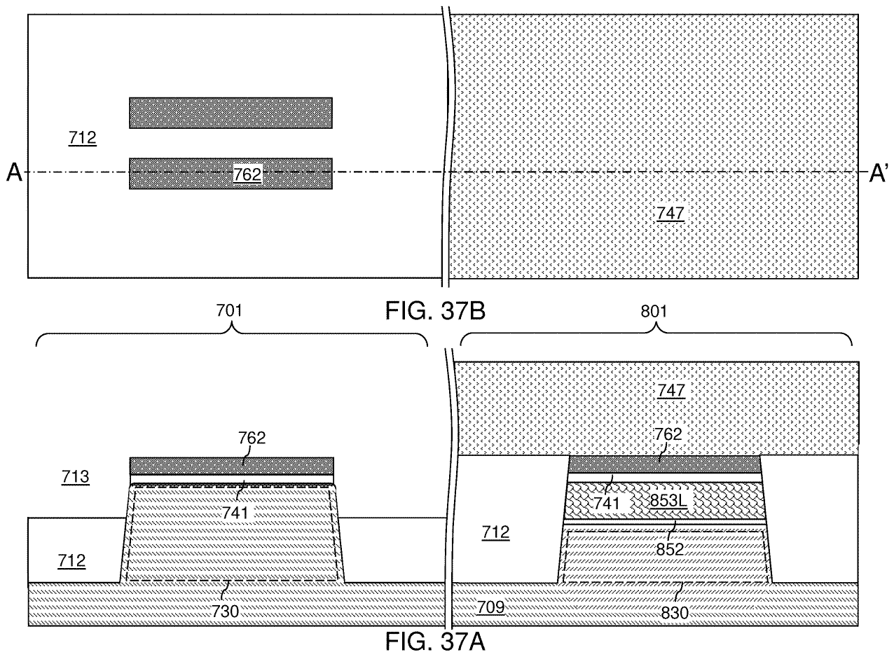

Referring to FIGS. 37A and 37B, a photoresist layer 747 can be applied over the patterned hard mask layer 762 and the dielectric isolation layers 712, and can be lithographically patterned to cover the second device region 801 without covering the first device region 701. A selective recess etch process can be performed to vertically recess the dielectric material of the first dielectric isolation layer 712 selective to the material of the patterned hard mask layer 762. A gate cavity 713 can be formed around an upper portion of the semiconductor fins 730. The ratio of the vertical distance between the bottom surface of the gate cavity 713 and the horizontal plane including the top surfaces of the semiconductor fins 730 to the height of the semiconductor fins 730 may be in a range from 0.3 to 0.9, such as from 0.5 to 0.8, although lesser and greater ratios may also be employed. The photoresist layer 747 may be subsequently removed, for example, by ashing. A lower portion of each semiconductor fin 730 is laterally surrounded by the first dielectric isolation layer 712, and an upper portion of each semiconductor fin 730 is exposed to a moat cavity, such as the gate cavity 713.

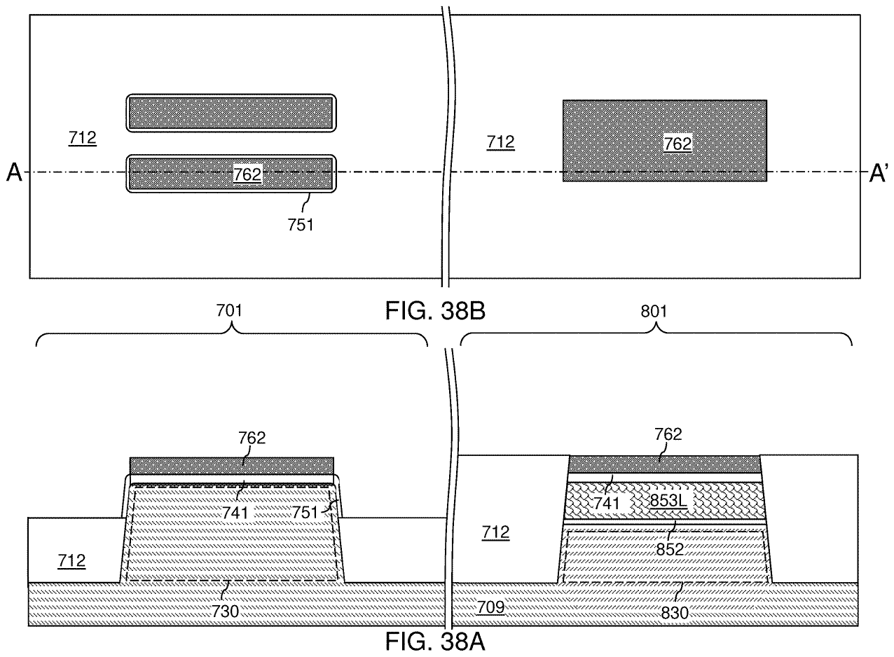

Referring to FIGS. 38A and 38B, a surface oxidation process can be performed to covert surface portions of the semiconductor fins 730 into sacrificial semiconductor oxide layers 751. In this case, top corners of the semiconductor fins 730 can be rounded by the surface oxidation process. The rounded corners of the semiconductor fins 730 improve the breakdown voltage of the fin field effect transistors to be formed in the first device region 701. The thickness of the sacrificial semiconductor oxide layers 751 may be in a range from 2 nm to 10 nm, such as from 4 nm to 7 nm, although lesser and greater thicknesses may also be employed.

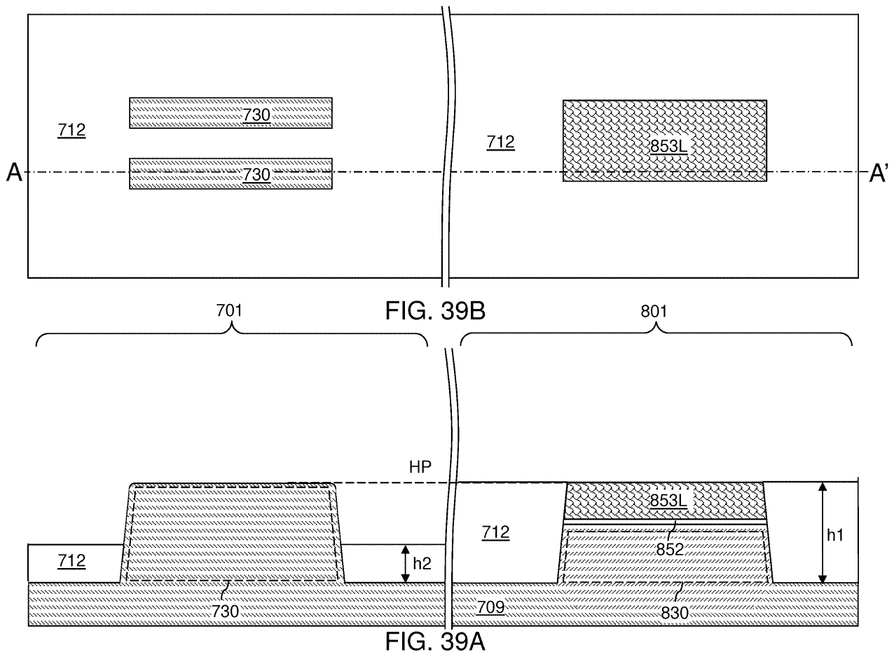

Referring to FIGS. 39A and 39B, the patterned hard mask layer 762 can be removed selective to the materials of the dielectric isolation layers 712, the optional pad silicon oxide layer 741, and the sacrificial semiconductor oxide layers 751. For example, if the patterned hard mask layer 762 comprises silicon nitride, a wet etch process employing hot phosphoric acid may be performed to remove the patterned hard mask layer 762. Subsequently, a selective etch process can be performed to remove the pad silicon oxide layer 741 (if present), the sacrificial semiconductor oxide layers 751, and top surface portions of the dielectric isolation layers 712. The top surface of the planar-FET gate electrode material layer 853L and the top surfaces of the semiconductor fins 730 can be physically exposed. The top surface of the second dielectric isolation layer 712 is located above a first horizontal plane including a top surface of the first dielectric isolation layer 712, and below a second horizontal plane (such as the horizontal plane HP) including topmost surfaces of the semiconductor fins 730.

In one embodiment, the top surface of the planar-FET gate electrode material layer 853L and the top surfaces of the semiconductor fins 730 can be formed within the same horizontal plane HP. In one embodiment, the top surface of the second dielectric isolation layer 712 may be formed within or in proximity to the horizontal plane HP. In this case, the height of the second dielectric isolation layer 712 may be the same as or may be about the same as the height of the semiconductor active region 830 and the height of the semiconductor fins 730. The height of the second dielectric isolation layer 712 in the second device region 801 is herein referred to as a first height h1. The height of the first dielectric isolation layer 712 in the first device region 701 is herein referred to as a second height h2, which is smaller than the first height h1. The ratio of the second height h2 to the first height h1 may be in a range from 0.05 to 0.5, such as from 0.1 to 0.4, although lesser and greater ratios may also be employed.

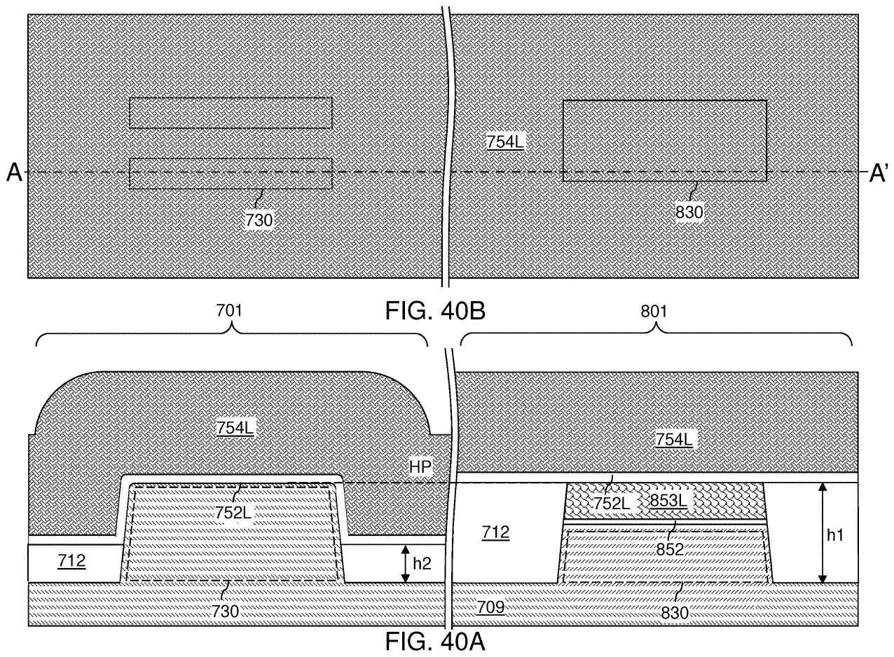

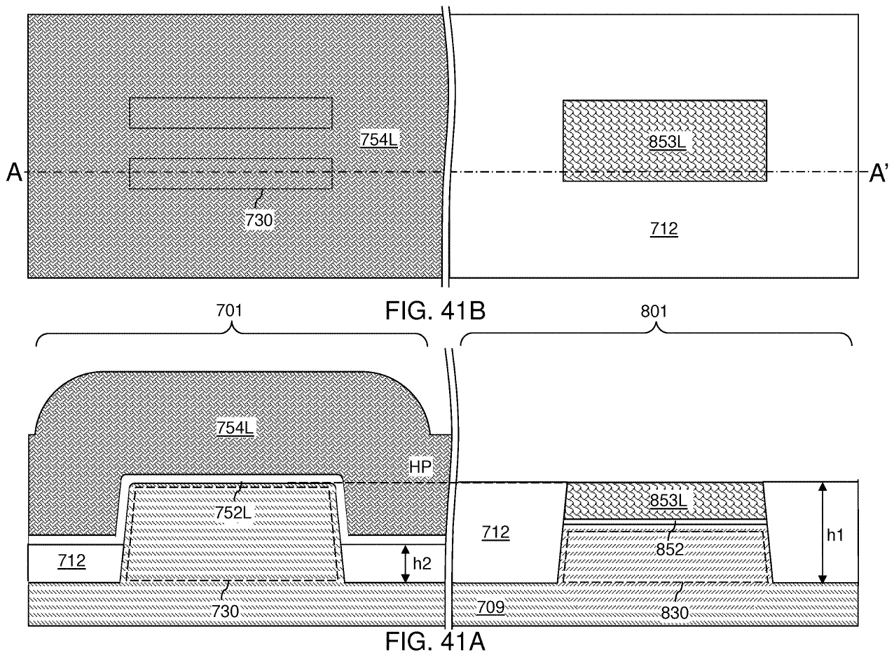

Referring to FIGS. 40A and 40B, a gate dielectric layer is formed over the physically exposed surfaces of the semiconductor fins 730 and the top surface of the planar-FET gate electrode material layer 853L. This gate dielectric layer is referred to as a finFET gate dielectric layer 752L, or as a first gate dielectric layer, or as a second gate dielectric layer. The finFET gate dielectric layer 752L may have the same material composition and the same thickness range as the first gate dielectric 752 described above with reference to FIGS. 17A and 17B. In one embodiment, the finFET gate dielectric layer 752L may have a thickness that is suitable for formation of high voltage devices such as word line drivers for a three-dimensional memory array. In one embodiment, the finFET gate dielectric layer 752L may comprise a silicon oxide layer having a thickness in a range from 20 nm to 50 nm, although lesser and greater thicknesses may also be employed.

A gate electrode material layer can be deposited. This gate electrode material layer is herein referred to as a finFET gate electrode material layer 754L, and may also be referred to as a first gate electrode material layer or a second gate electrode material layer. The finFET gate electrode material layer 754L may also comprise polysilicon. The polysilicon be undoped (i.e., does not include any intentionally-introduced dopants), or may be p-doped or n-doped. Generally, the finFET gate electrode material layer 754L may be doped during deposition (i.e., in-situ), or at a subsequent processing step, to provide electrical dopants of a suitable conductivity type at a suitable atomic concentration.

Referring to FIGS. 41A and 41B, a photoresist layer (not shown) can be applied over the finFET gate electrode material layer 754L, and can be lithographically patterned to cover the first device region 701 without covering the second device region 801. A first selective etch process can be performed to remove the portion of the finFET gate electrode material layer 754L in the second device region 801 selective to the material of the finFET gate dielectric layer 752L. A second selective etch process can be performed to remove the portion of the finFET gate dielectric layer 752L in the second device region 801 selective to the material of the planar-FET gate electrode material layer 853L. The photoresist layer can be subsequently removed, for example, by ashing.

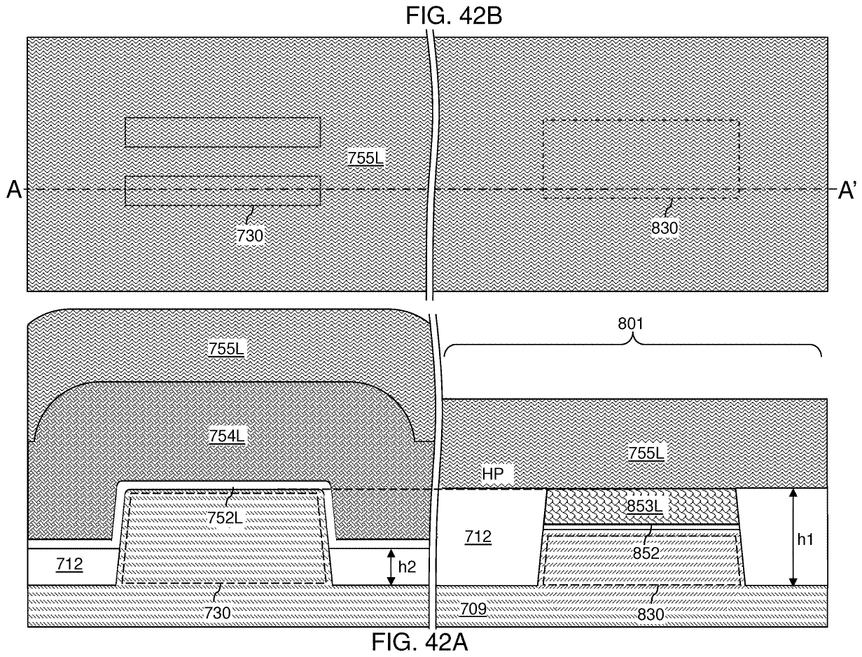

Referring to FIGS. 42A and 42B, an additional gate electrode material layer can be deposited. This gate electrode material layer is herein referred to as an upper gate electrode material layer 755L, and may also be referred to as a third gate electrode material layer. The upper gate electrode material layer 755L can be deposited directly on a top surface of the planar-FET gate electrode material layer 853L and directly on a top surface of the finFET gate electrode material layer 754L. The upper gate electrode material layer 755L may comprise undoped (i.e., intrinsic) polysilicon.

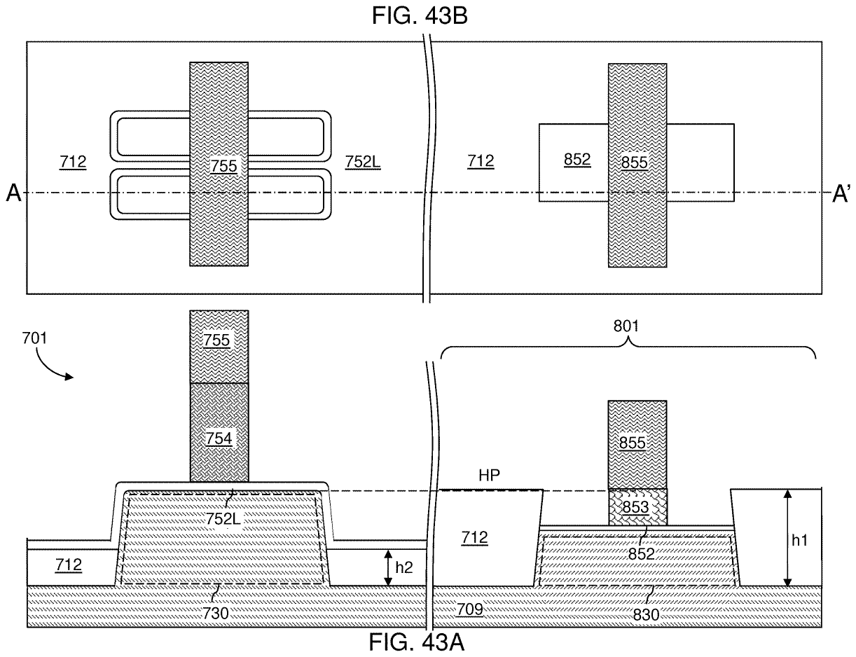

Referring to FIGS. 43A and 43B, a photoresist layer (not shown) can be applied over the third exemplary structure, and can be lithographically patterned into photoresist material portions having a pattern of gate electrodes. An anisotropic etch process that etches semiconductor materials of the upper gate electrode material layer 755L, the planar-FET gate electrode material layer 853L, and the finFET gate electrode material layer 754L selective to the dielectric materials of the finFET gate dielectric layer 752L, the planar transistor gate dielectric 852, and the dielectric isolation layers 712 is performed. Patterned portions of the upper gate electrode material layer 755L and the finFET gate electrode material layer 754L comprise a finFET gate electrode (754, 755) which is formed in the first device region 701. Patterned portions of the upper gate electrode material layer 755L and the planar-FET gate electrode material layer 853L comprise a planar-FET gate electrode (853, 855) which is formed in the second device region 801.

In one embodiment, the finFET gate electrode (754, 755) may include a stack of a lower finFET gate electrode portion 754 and an upper finFET gate electrode portion 755. The lower finFET gate electrode portion 754 comprises a patterned portion of the finFET gate electrode material layer 754L. The upper finFET gate electrode portion 755 comprises a first patterned portion of the upper gate electrode material layer 755L. The planar-FET gate electrode (853, 855) includes a stack of a lower planar-FET gate electrode portion 853 and an upper planar-FET gate electrode portion 855. The lower planar-FET gate electrode portion 853 comprises a patterned portion of the planar-FET gate electrode material layer 853L. The upper planar-FET gate electrode portion 855 comprises a second patterned portion of the upper gate electrode material layer 755L.

In one embodiment, an interface between the lower planar-FET gate electrode portion 853 and the upper planar-FET gate electrode portion 855 may be is located entirely within a horizontal plane HP including topmost surfaces of the semiconductor fins 730. In one embodiment, the upper planar-FET gate electrode portion 855 and the upper finFET gate electrode portion 755 comprise the same semiconductor material (e.g., polysilicon) and have the same thickness. In one embodiment, the lower planar-FET gate electrode portion (such as a first gate electrode material portion 853) and the lower finFET gate electrode portion 754 differ in at least one of material composition and/or thickness.

In one embodiment, the planar-FET gate electrode material layer 853L may comprise a first gate electrode material, the finFET gate electrode material layer 754L may comprise a second gate electrode material, and the upper gate electrode material layer 755L may comprise a third gate electrode material. The first gate electrode material, the second gate electrode material, and the third gate electrode material may differ from each other, in thickness, the type (e.g., p-type or n-type) and/or the atomic concentrations of the dopant atoms therein. In one embodiment, the lower planar-FET gate electrode portion 853 may comprise the first gate electrode material, the lower finFET gate electrode portion 754 may comprise the second semiconductor material, and the upper finFET gate electrode portion 755 and the upper planar-FET gate electrode portion 855 may comprise the third gate electrode material.

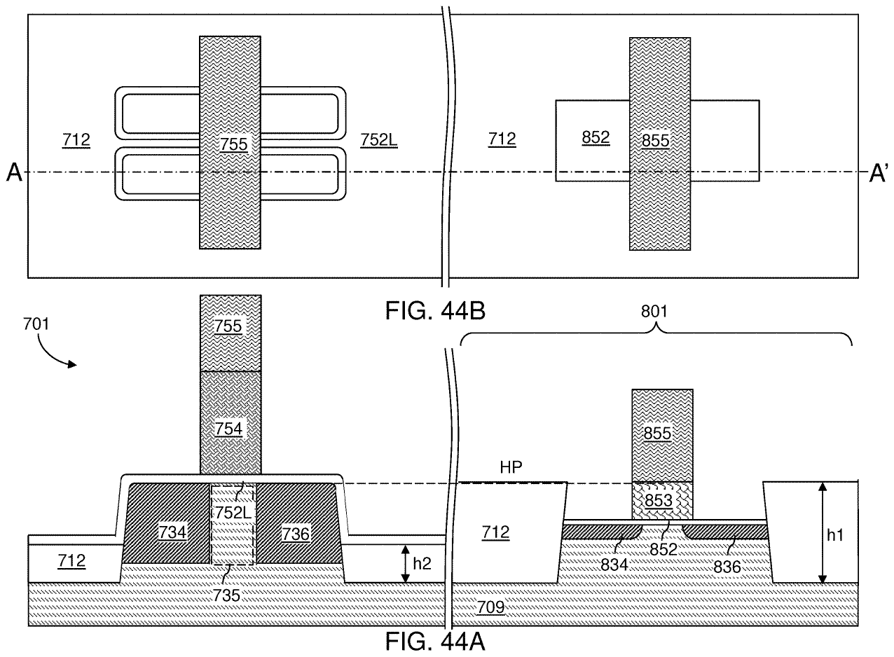

Referring to FIGS. 44A and 44B, a first photoresist layer (not shown) can be applied over the third exemplary structure, and can be lithographically patterned to cover the second device region 801 without covering the first device region 701. The processing steps described with reference to FIGS. 20A and 20B can be performed to form finFET source/drain extension regions (734, 736), which are also referred to as first source/drain extension regions (734, 736). The remaining unimplanted portion of each semiconductor fin 730 constitutes a finFET channel region 735, which may comprise a single crystal silicon channel region. The first photoresist layer can be subsequently removed, for example, by ashing.

A second photoresist layer (not shown) can be applied over the third exemplary structure, and can be lithographically patterned to cover the first device region 701 without covering the second device region 801. The processing steps described with reference to FIGS. 23A and 23B can be performed to form planar-FET source/drain extension regions (834, 836), which are also referred to as second source/drain extension regions (834, 836). The second photoresist layer can be subsequently removed, for example, by ashing.

In one embodiment, the finFET source/drain extension regions (734, 736) may have an opposite conductivity type from the second source/drain extension regions (834, 836). In one embodiment, an additional planar-FET transistor may be formed in a different region of the substrate 709 than regions 701 and 801. The additional planar-FET transistor may have the same conductivity type as the finFET and an opposite conductivity type from the planar-FET in region 801. In this embodiment, the source/drain extension regions of the additional planar-FET transistor may be formed at the same time as the finFET source/drain extension regions (734, 736).

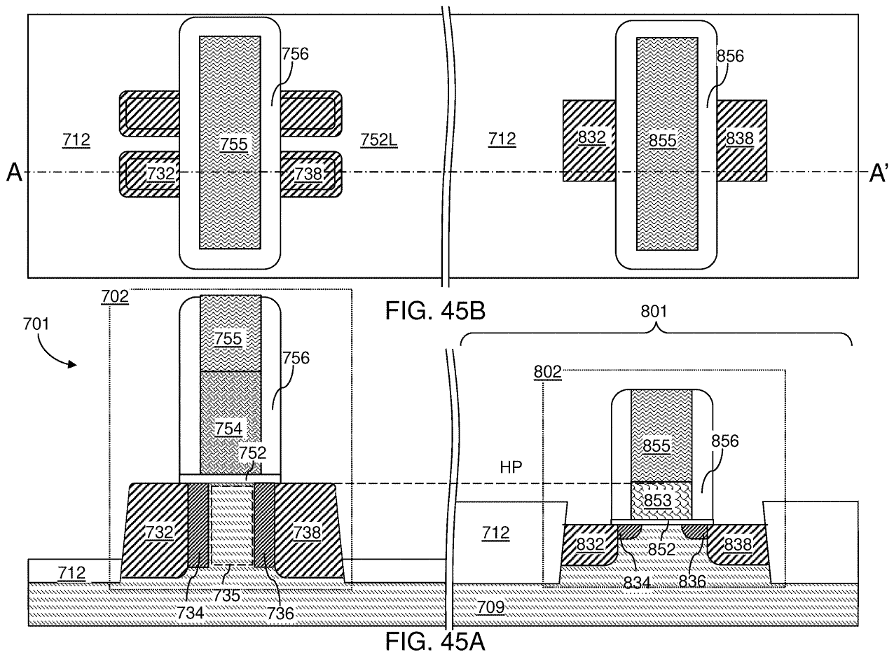

Referring to FIGS. 45A and 45B, a dielectric spacer material layer can be conformally deposited and can be subsequently anisotropically etched to form a first dielectric gate spacer 756 around the finFET gate electrode (754, 755), and to form a second dielectric gate spacer 856 around the planar-FET gate electrode (853, 855). The first dielectric gate spacer 756 may also be referred to as a finFET dielectric gate spacer (i.e., first sidewall spacer) 756. The second dielectric gate spacer 856 may also be referred to as a planar-FET dielectric gate spacer (i.e., second sidewall spacer) 856.

The processing steps described with reference to FIGS. 25A and 25B can be performed, optionally with at least one suitable patterned block-level photoresist layer, to implant dopants into portions of the semiconductor fins 730 and the semiconductor active regions 830 that are not masked by the gate electrodes {(754, 755), (853, 855)} and the dielectric gate spacers (756, 856). Source/drain regions are formed in the implanted portions of the semiconductor fins 730 and the semiconductor active region 830. The source/drain regions comprise at least one finFET source region 732 that incorporates a portion of a respective finFET source extension region 734, at least one finFET drain region 738 that incorporates a portion of a respective finFET drain extension region 736, a planar-FET source region 832 that incorporates an implanted portion of the planar-FET source extension region 834, and a planar-FET drain region 838 that incorporates an implanted portion of the planar-FET drain extension region 836.

If the finFET source/drain regions (732, 738) have an opposite conductivity type from the planar-FET source/drain regions (832, 838), then the finFET source/drain regions (732, 738) and planar-FET source/drain regions (832, 838) are implanted in different steps while the regions 801 and 701 are alternatively masked. If the additional planar-FET is present, then its source/drain regions (832, 838) can be implanted at the same time as the finFET source/drain regions (732, 738), provided that the area of the additional planar-FET is unmasked during this ion implantation step.

The depth of each finFET source region 732 and each finFET drain region 738 is greater than the depth of each finFET source extension region 734 and each finFET drain extension region 736. The depth of each planar-FET source region 832 and each planar-FET drain region 838 is greater than the depth of each planar-FET source extension region 834 and each planar-FET drain extension region 836.

In one embodiment, the vertical thickness of the finFET source/drain regions (732, 738) may be greater than the vertical thickness of the planar-FET source/drain regions (832, 838). In one embodiment, the vertical thickness of the finFET source/drain regions (732, 738) may be in a range from 300 nm to 2,000 nm, such as from 500 nm to 1,000 nm, although lesser and greater thicknesses may also be employed. In one embodiment, the vertical thickness of the planar-FET source/drain regions (832, 838) may be in a range from 60 nm to 600 nm, such as from 100 nm to 300 nm, although lesser and greater thicknesses may also be employed. In this embodiment, the finFET source/drain regions (732, 738) and the additional planar-FET source/drain regions may be implanted in different ion implantation steps.

Generally, a plurality of fin field effect transistors 702 including a respective set of at least one semiconductor fin 730 and a respective set of at least one first gate dielectric 752 having a first gate dielectric thickness can be formed. First planar field effect transistors 802 are also formed. The first planar field effect transistors each include a respective second gate dielectric 852 having a second gate dielectric thickness that is different from the first gate dielectric thickness. Each fin field effect transistor 702 comprises a respective finFET gate electrode (754, 755) and a respective first dielectric gate spacer 756 that laterally surrounds the respective finFET gate electrode (754, 755). Each first planar field effect transistor 802 comprises a respective planar-FET gate electrode (853, 855) and a respective second dielectric gate spacer 856 that laterally surrounds the respective planar-FET gate electrode (853, 855). Each first dielectric gate spacer 756 and each second dielectric gate spacer 856 comprise the same dielectric material. The plurality of fin field effect transistors 702 may be employed to form a word line switching circuit as described above. The first planar field effect transistors 802 of a first conductivity type and the second (e.g., additional) planar field effect transistors of a second conductivity type may be employed to provide other circuit components, such as sense amplifier transistors or bit line driver transistors in a peripheral circuit configured to operate a three-dimensional memory device.

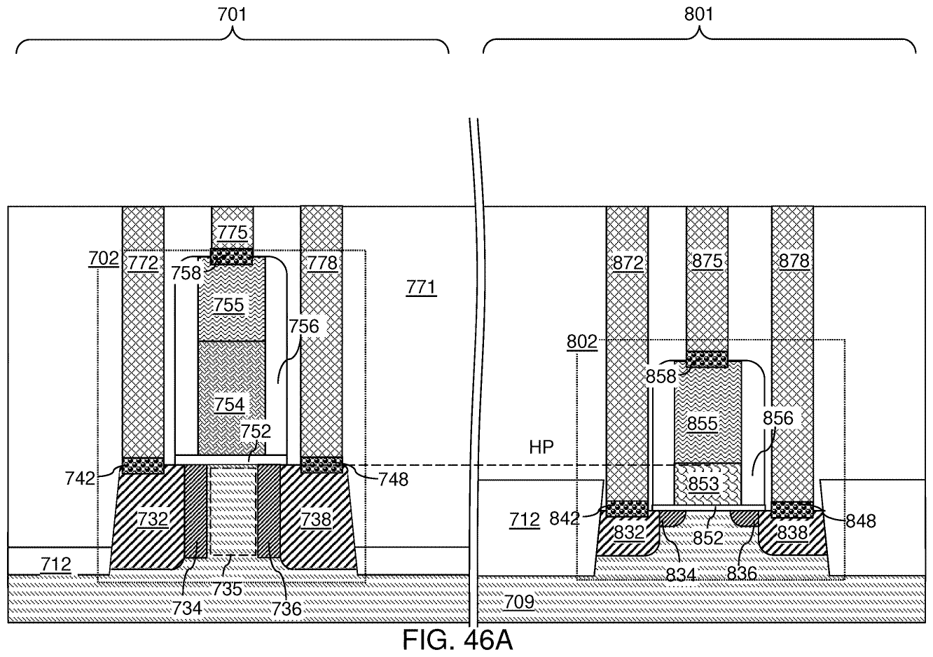

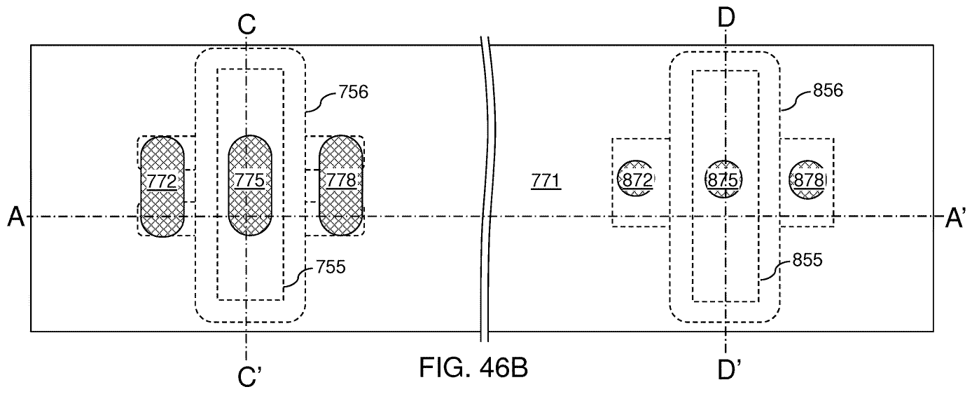

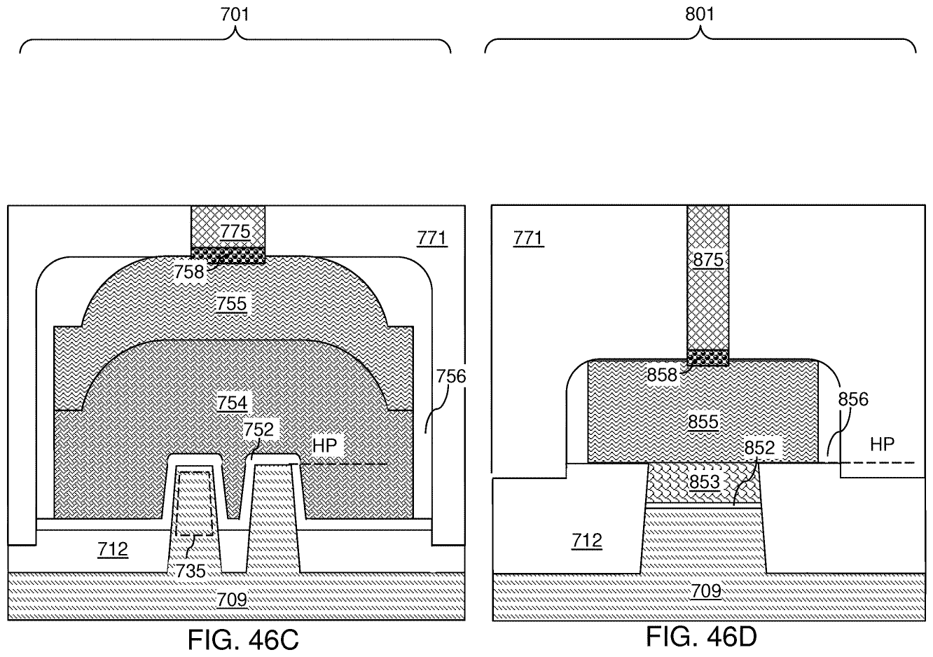

Referring to FIG. 46A-46D, the processing steps described with reference to FIG. 27A-27C can be performed to form a contact-level dielectric layer 771. The processing steps described with reference to FIG. 28A-28C can be performed to form various contact via structures (772, 775, 778, 872, 875, 878).

Subsequently, the processing steps described with reference to FIG. 30 can be performed to form logic-side metal interconnect structures 780 embedded within logic-side dielectric material layers 760 over the fin field effect transistors 702 and the planar field effect transistors 802 of the third exemplary structure. A logic die 700 is thus provided.

A memory die 900 can be provided, for example, by performing the processing steps described with reference to FIG. 1-13. The memory die 900 comprises a three-dimensional memory device and memory-side metal interconnect structures 980 and memory-side bonding pads 988 embedded within memory-side dielectric material layers 960 as described above.

The processing steps described with reference to FIG. 31 can be performed to bond the logic die 700 to the memory die 900, and thus, to form a bonded assembly. In one embodiment, the logic die 700 comprises a logic-side semiconductor substrate 709 supporting the fin field effect transistors 702 containing the semiconductor fins 730 and the first planar field effect transistors 802. The logic die 700 also comprises logic-side bonding pads 788 embedded within logic-side dielectric material layers 760; and the memory die 900 comprises memory-side bonding pads 988 that are embedded within memory-side dielectric material layers 960 and bonded to the logic-side bonding pads 788.

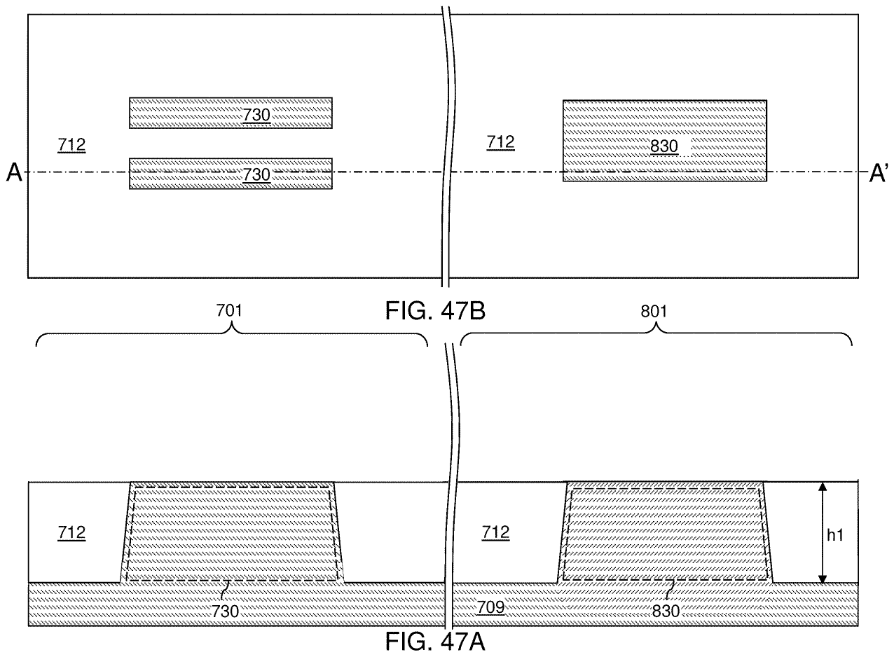

Referring to FIGS. 47A and 47B, a fourth exemplary structure according to an embodiment of the present disclosure is illustrated, which may be the same as the first exemplary structure illustrated in FIGS. 15A and 15B. Generally, the sidewalls of the semiconductor fin 730 and the semiconductor active region 830 may be vertical, substantially vertical, or may be tapered.

The fourth exemplary structure may be formed by forming the patterned hard mask layer 762 over a semiconductor substrate (such as a logic-side substrate 709) comprising a first device region 701 and a second device region 801, as described above with respect to FIGS. 34A, 34B, 35A and 35B. Moat trenches, such as portions of the continuous recess trench 711, can be formed in an upper portion of the semiconductor substrate 709 using the patterned hard mask layer 762 as a mask, as described above with respect to FIGS. 35A and 35B. The moat trenches comprise a first moat trench 711 that is formed in the first device region 701 and laterally surrounds the semiconductor fins 730 and a second moat trench 711 that is formed in the second device region 801 and laterally surrounds a semiconductor active region 830. The corners of the semiconductor fins 730 may then be rounded by forming the sacrificial semiconductor oxide layers 751, as described above with respect to FIGS. 38A and 38B.

A dielectric trench fill material can be deposited in the moat trenches 711 to form the dielectric isolation layers 712, as described above with respect to FIGS. 36A and 36B. A first dielectric isolation layer 712 laterally surrounds the semiconductor fins 730, and a second dielectric isolation layer 712 laterally surrounds the semiconductor active region 830. A bottom surface of the first dielectric isolation layer 712 and a bottom surface of the second dielectric isolation layer 712 may be formed within a same horizontal plane. The patterned hard mask layer 762 is then removed by selective etching, as described above with respect to FIGS. 39A and 39B. The dielectric isolation layers 712 are then planarized by chemical mechanical polishing to have top surfaces in the same horizontal plane as the top surfaces of the semiconductor fin 730 and the semiconductor active region 830.

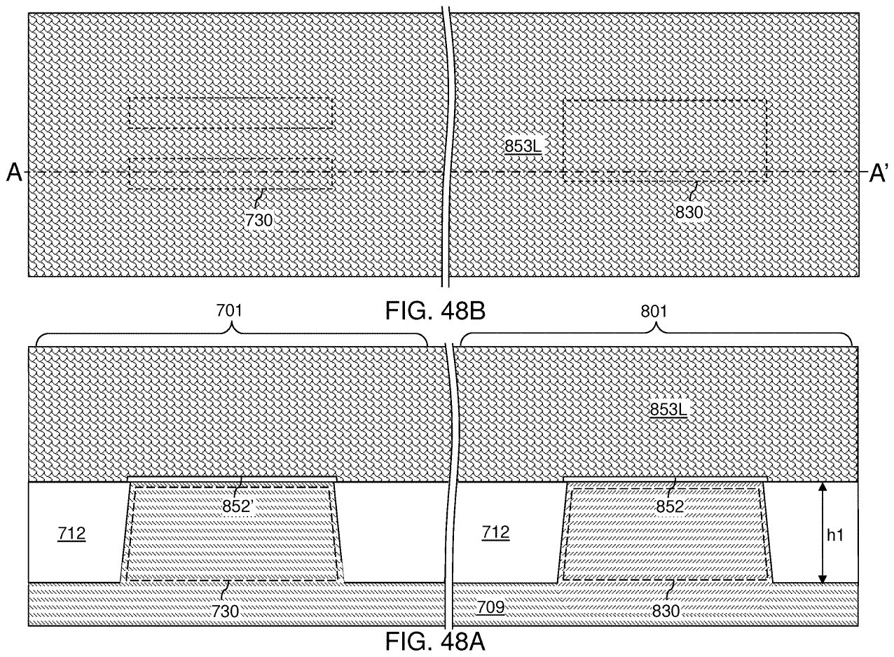

Referring to FIG. 48A FIG. 48B, a gate dielectric layer is formed, for example, by thermal oxidation of a surface portion of the semiconductor active region 830 and/or by deposition of a gate dielectric material. The gate dielectric layer that is formed on the top surface of the semiconductor active region 830 is subsequently employed as a gate dielectric for a second (e.g., planar) field effect transistor to be subsequently formed in the second device region 801, and may be referred to as a second gate dielectric 852, or as a planar-FET gate dielectric 852, or alternatively as a first gate dielectric layer. The second gate dielectric 852 may have any of the material compositions and thickness ranges as described with reference to the first exemplary structure and the second exemplary structure. A sacrificial gate dielectric 852′ may be formed on the top surfaces of the semiconductor fins 730 concurrently with formation of the second gate dielectric 852.

A gate electrode material layer can be deposited. This gate electrode material layer is herein referred to as a planar-FET gate electrode material layer 853L, and may also be referred to as a second gate electrode material layer or a first gate electrode material layer. The planar-FET gate electrode material layer 853L may be undoped (i.e., does not include any intentionally-introduced dopants) polysilicon, or may be p-doped or n-doped polysilicon. Generally, the planar-FET gate electrode material layer 853L may be doped during deposition (i.e., in-situ), or at a subsequent processing step, to provide electrical dopants of a suitable conductivity type at a suitable atomic concentration.

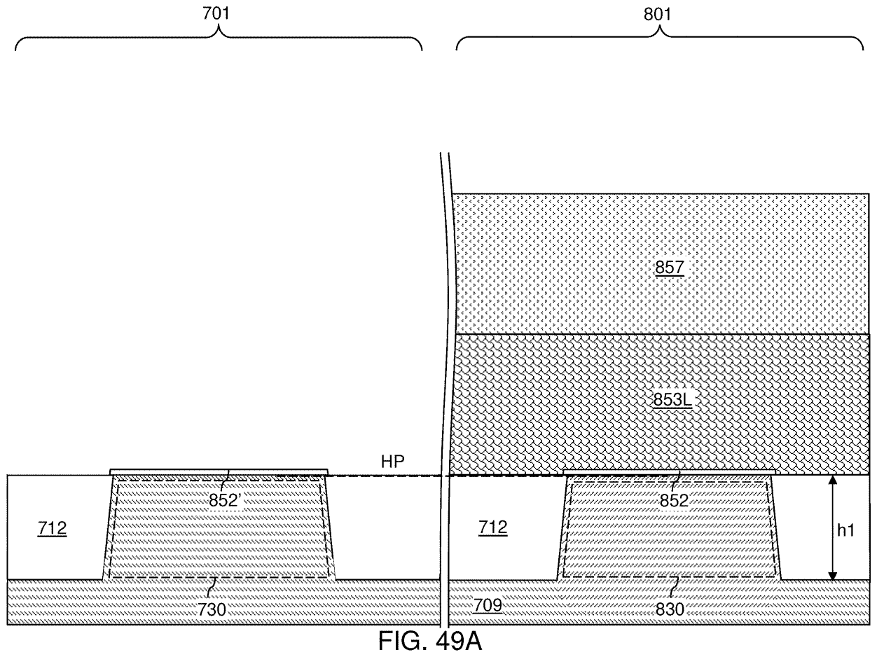

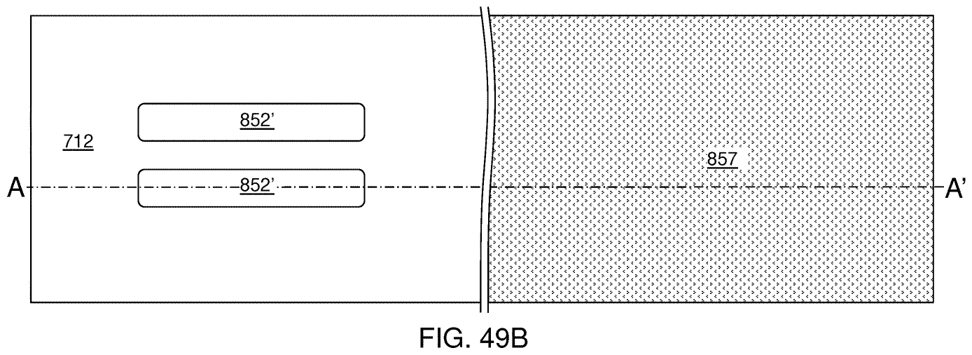

Referring to FIGS. 49A and 49B, a photoresist layer 857 can be formed over the planar-FET gate electrode material layer 853L, and can be patterned to cover the second device region 801 without covering the first device region 701. A selective etch process can be performed to remove the unmasked portion of the planar-FET gate electrode material layer 853L selective to the dielectric materials of the first dielectric isolation layer 712 and the sacrificial gate dielectrics 852′. The photoresist layer 857 can be subsequently removed, for example, by ashing. A planar-FET gate dielectric 852 (i.e., a second gate dielectric 852) and a planar-FET gate electrode material layer 853L (which may be referred to as a first gate electrode material layer 853L) comprising a first gate electrode material are formed in the second device region 801 without covering the first device region 701 with the first gate electrode material. The planar-FET gate dielectric 852 (i.e., the second gate dielectric 852) comprises a bottom surface that is formed within a horizontal plane HP including topmost surfaces of the semiconductor fins 730.

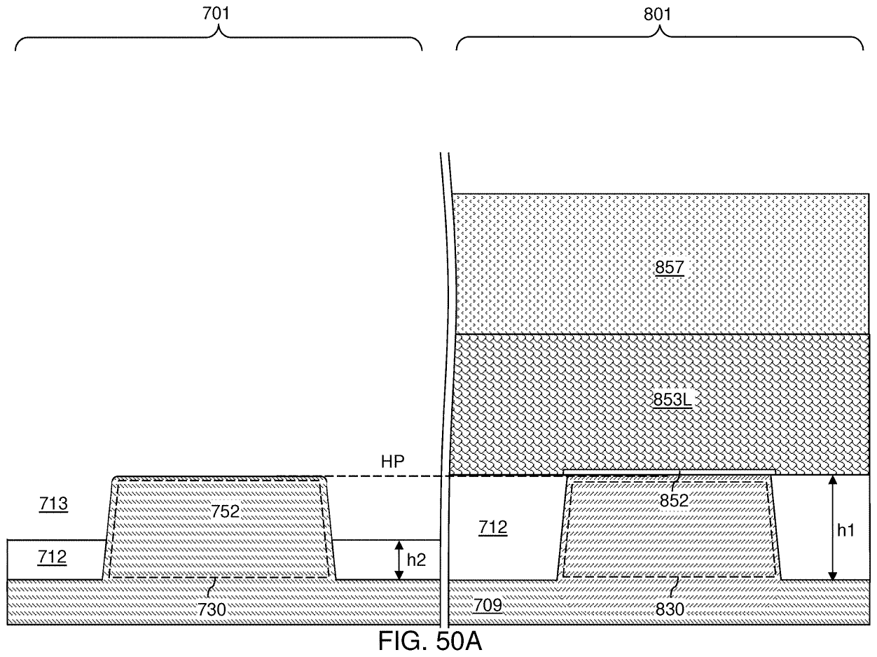

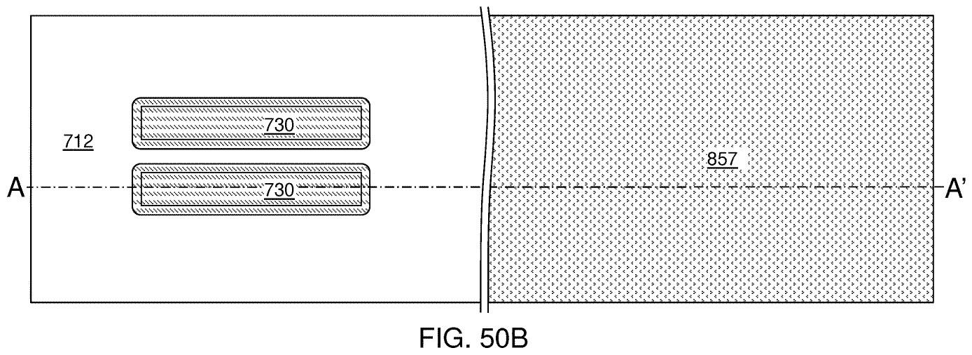

Referring to FIGS. 50A and 50B, a recess etch process can be performed to vertically recess the dielectric trench fill material of the first dielectric isolation layer 712 in the first moat trench selective to the semiconductor material of the semiconductor fins 730. The remaining portion of the first dielectric isolation layer 712 laterally surrounds lower portions of the semiconductor fins 730, and an overlying unfilled volume of the first moat trench comprises a moat cavity 713 that laterally surrounds the upper portions of the semiconductor fins 30. The height of the second dielectric isolation layer 712 in the second device region 801 is herein referred to as a first height h1. The height of the first dielectric isolation layer 712 in the first device region 701 is herein referred to as a second height h2, which is less than the first height hd1. The ratio of the second height h2 to the first height h1 may be in a range from 0.05 to 0.5, such as from 0.1 to 0.4, although lesser and greater ratios may also be employed.

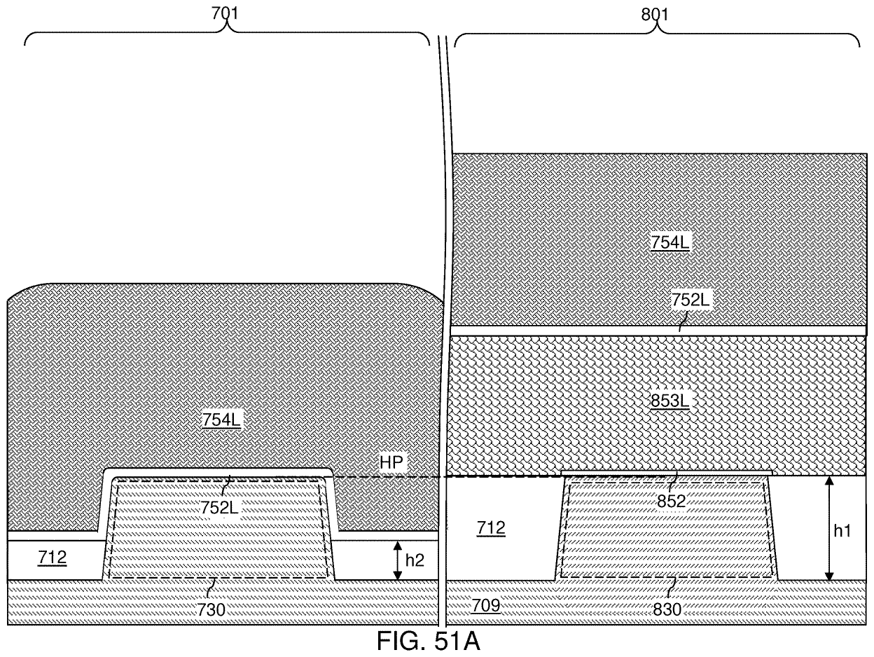

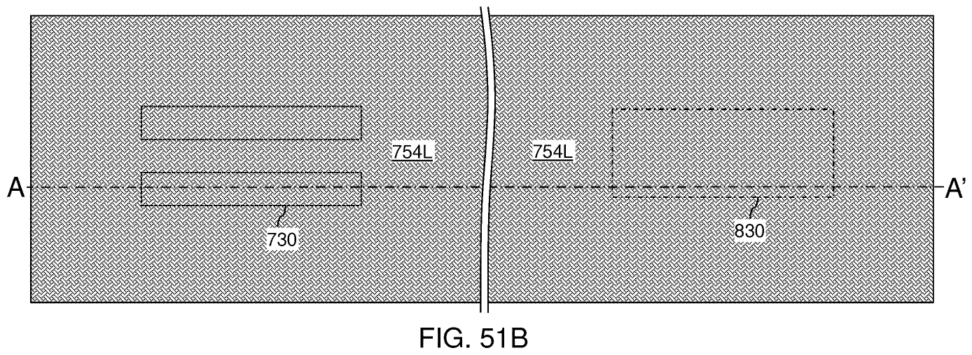

Referring to FIGS. 51A and 51B, a gate dielectric layer is formed over the physically exposed surfaces of the semiconductor fins 730 and the top surface of the planar-FET gate electrode material layer 853L. This gate dielectric layer is referred to as a finFET gate dielectric layer 752L, or as a first gate dielectric layer, or as a second gate dielectric layer. The finFET gate dielectric layer 752L may have the same material composition and the same thickness range as the first gate dielectric 752 described with reference to FIGS. 17A and 17B. In one embodiment, the finFET gate dielectric layer 752L may have a thickness that is suitable for formation of high voltage devices, such as word line drivers for a three-dimensional memory array. In one embodiment, the thickness of the finFET gate dielectric layer 752L may comprise silicon oxide having a thickness in a range from 20 nm to 50 nm, although lesser and greater thicknesses may also be employed.

A gate electrode material layer can be deposited over the planar-FET gate electrode material layer 853L in the first device region 701 and in the second device region 801. This gate electrode material layer is herein referred to as a finFET gate electrode material layer 754L, and may also be referred to as a first gate electrode material layer or a second gate electrode material layer. The finFET gate electrode material layer 754L may be undoped (i.e., does not include any intentionally-introduced dopants) polysilicon, or may be p-doped or n-doped polysilicon. Generally, the finFET gate electrode material layer 754L may be doped during deposition (i.e., in-situ), or at a subsequent processing step, to provide electrical dopants of a suitable conductivity type at a suitable atomic concentration.

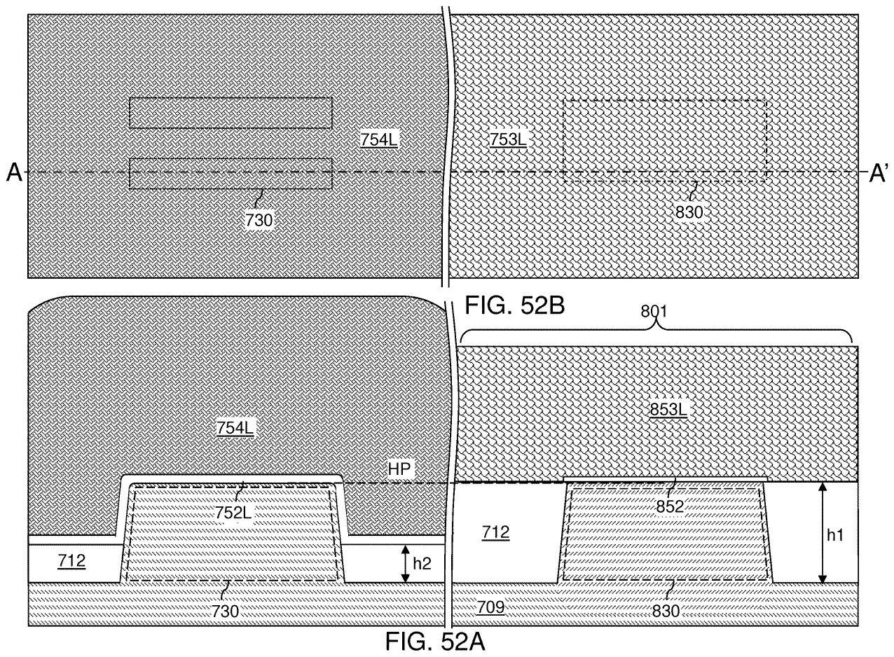

Referring to FIGS. 52A and 52B, a photoresist layer (not shown) can be applied over the finFET gate electrode material layer 754L, and can be lithographically patterned to cover the first device region 701 without covering the second device region 801. A first selective etch process can be performed to remove the portion of the finFET gate electrode material layer 754L in the second device region 801 selective to the material of the finFET gate dielectric layer 752L. A second selective etch process can be performed to remove the portion of the finFET gate dielectric layer 752L in the second device region 801 selective to the material of the planar-FET gate electrode material layer 853L. The photoresist layer can be subsequently removed, for example, by ashing.

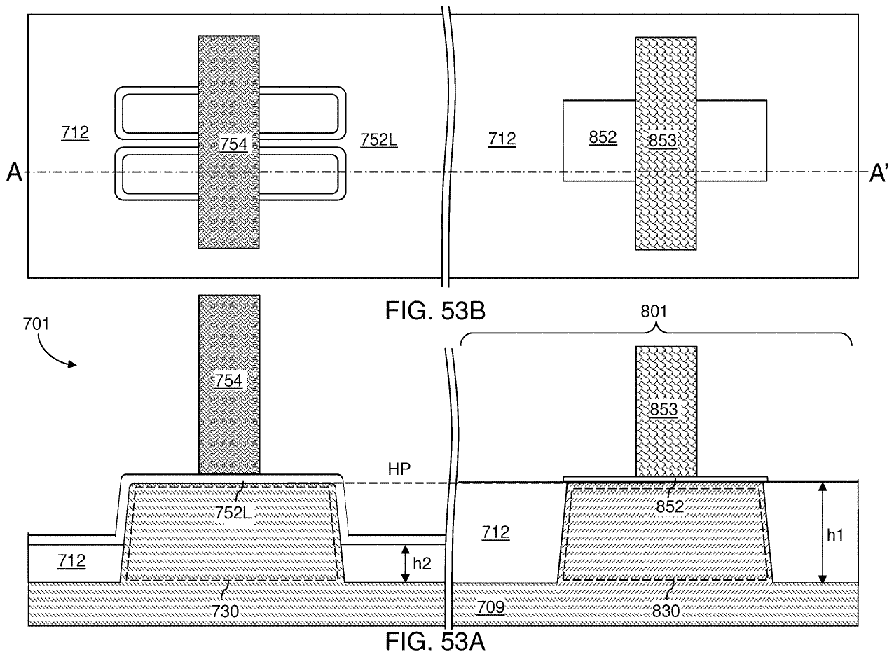

Referring to FIGS. 53A and 53B, a photoresist layer (not shown) can be applied over the fourth exemplary structure, and can be lithographically patterned into photoresist material portions having a pattern of gate electrodes. An anisotropic etch process that etches semiconductor materials of the planar-FET gate electrode material layer 853L and the finFET gate electrode material layer 754L selective to the dielectric materials of the finFET gate dielectric layer 752L, the planar transistor gate dielectric 852, and the dielectric isolation layers 712. Patterned portion of the finFET gate electrode material layer 754L comprises a finFET gate electrode 754 which is formed in the first device region 701. Patterned portion of the planar-FET gate electrode material layer 853 comprises a planar-FET gate electrode 853 which is formed in the second device region 801.

In one embodiment, the planar-FET gate electrode material layer 853L may comprise a first gate electrode material, and the finFET gate electrode material layer 754L may comprise a second gate electrode material that is different from the first gate electrode material, for example, in the type of dopant atoms and/or the atomic concentrations of the dopant atoms therein. In one embodiment, the planar-FET gate electrode 853 comprises a first gate electrode material and has a first gate height, and the finFET gate electrode 754 comprises a second gate electrode material and has a second height that is higher than the first height.

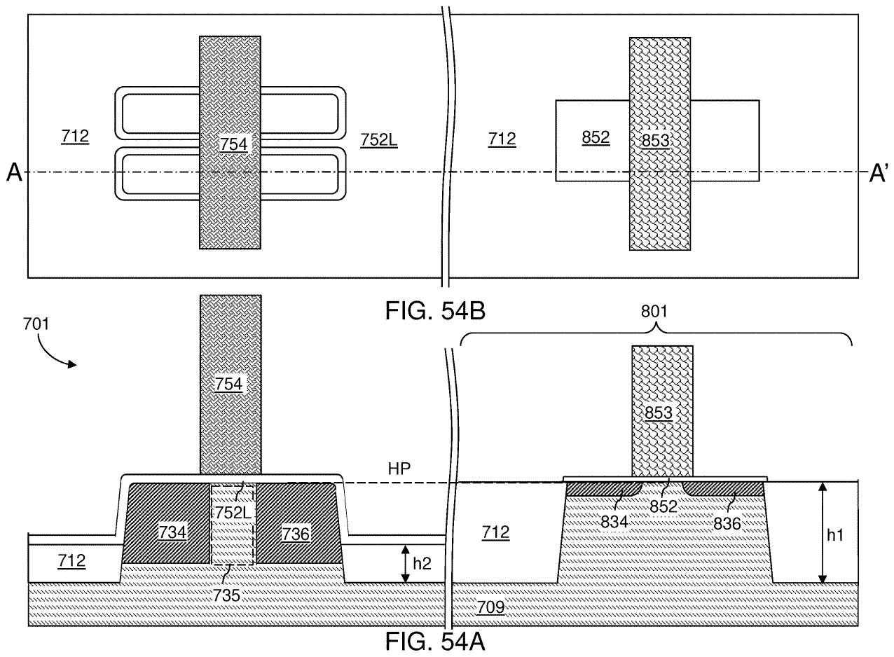

Referring to FIGS. 54A and 54B, the processing steps described with reference to FIGS. 44A and 44B can be performed to form finFET source/drain extension regions (734, 736), which are also referred to as first source/drain extension regions (734, 736), and to form planar-FET source/drain extension regions (834, 836), which are also referred to as second source/drain extension regions (834, 836).

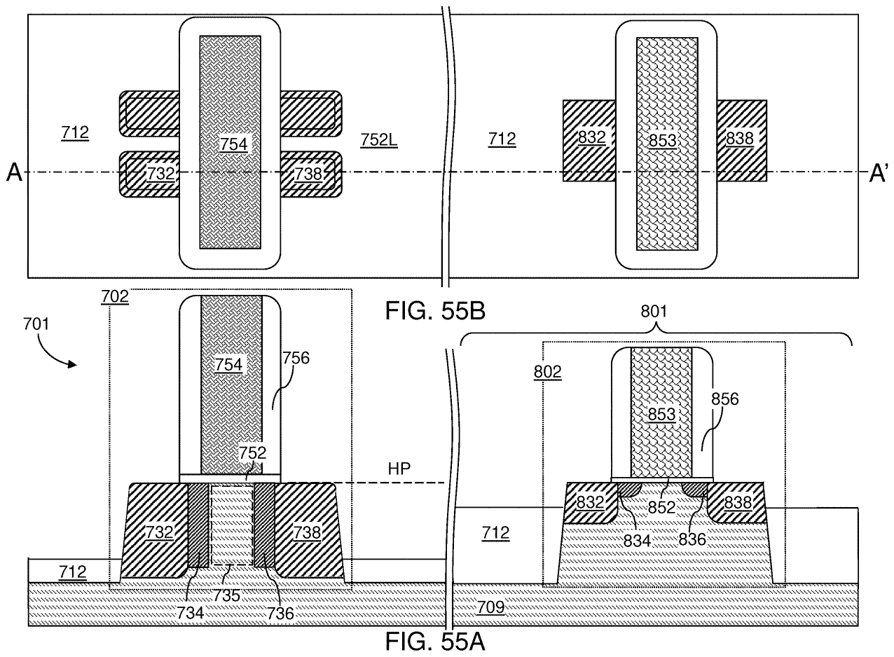

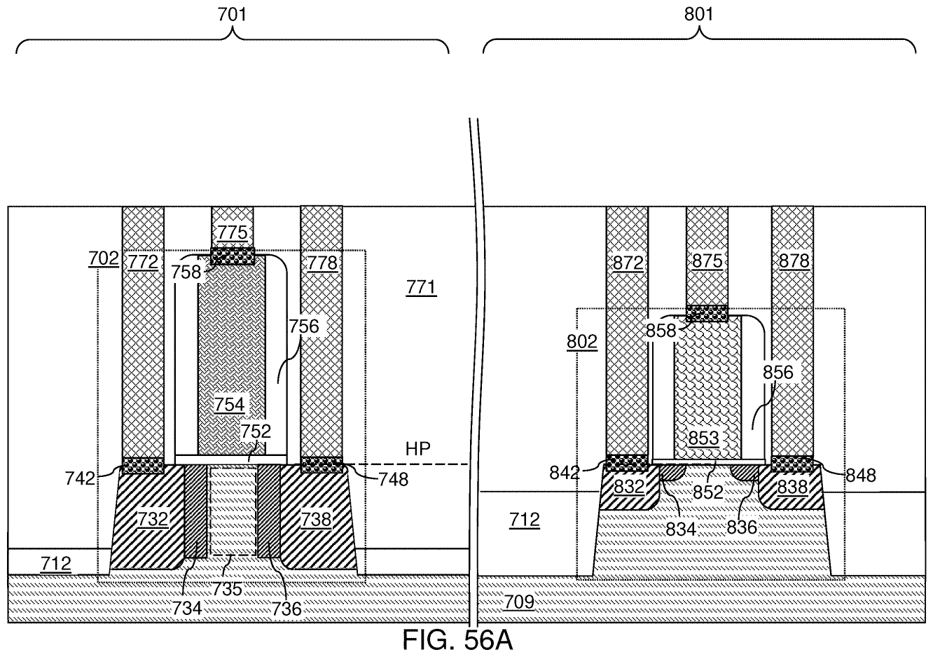

Referring to FIGS. 55A and 55B, a dielectric spacer material layer can be conformally deposited and can be subsequently anisotropically etched to form a first dielectric gate spacer 756 around the finFET gate electrode (754, 755), and to form a second dielectric gate spacer 856 around the planar-FET gate electrode (853, 855). The first dielectric gate spacer 756 may also be referred to as a finFET dielectric gate spacer 756. The second dielectric gate spacer 856 may also be referred to as a planar-FET dielectric gate spacer 856.

The processing steps described with reference to FIGS. 45A and 45B can be performed, optionally with at least one suitable patterned block-level photoresist layer, to implant dopants into portions of the semiconductor fins 730 and the semiconductor active regions 830 that are not masked by the gate electrodes {(754, 755), (853, 855)} and the dielectric gate spacers (756, 856). Source/drain regions are formed in the implanted portions of the semiconductor fins 730 and the semiconductor active region 830. The source/drain regions comprise at least one finFET source region 732 that incorporates a portion of a respective finFET source extension region 734, at least one finFET drain region 738 that incorporates a portion of a respective finFET drain extension region 736, a planar-FET source region 832 that incorporates an implanted portion of the planar-FET source extension region 834, and a planar-FET drain region 838 that incorporates an implanted portion of the planar-FET drain extension region 836. The depth of each finFET source region 732 and each finFET drain region 738 is greater than the depth of each finFET source extension region 734 and each finFET drain extension region 736. The depth of each planar-FET source region 832 and each planar-FET drain region 838 is greater than the depth of each planar-FET source extension region 834 and each planar-FET drain extension region 836.

In summary, a plurality of fin field effect transistors 702 including a respective set of at least one semiconductor fin 730 and a respective set of at least one first gate dielectric 752 having a first gate dielectric thickness can be formed. First planar field effect transistors, including a respective second gate dielectric 852 having a second gate dielectric thickness that is different from the first gate dielectric thickness, can also be formed. Each fin field effect transistor 702 comprises a respective finFET gate electrode 754 and a respective first dielectric gate spacer 756 that laterally surrounds the respective finFET gate electrode 754. Each first planar field effect transistor 802 comprises a respective planar-FET gate electrode 853 and a respective second dielectric gate spacer 856 that laterally surrounds the respective planar-FET gate electrode 853. Each first dielectric gate spacer 756 and each second dielectric gate spacer 856 comprise the same dielectric material. The plurality of fin field effect transistors 702 may be employed to form a word line switching circuit as described above. The first additional field effect transistors 802 may be employed to provide other circuit components in a peripheral circuit configured to operate a three-dimensional memory device.

A top surface of the first dielectric isolation layer 712 that is not masked by the finFET gate electrode 754 or the first dielectric gate spacer 756 may be vertically recessed, and can be formed below a first horizontal plane including a top surface of the second dielectric isolation layer 712, and below a second horizontal plane (such as the horizontal plane HP) including a topmost surface of the semiconductor fin 730. The unrecessed top surface of the second dielectric isolation layer 712 that is masked by the planar-FET gate electrode 853 or the first dielectric gate spacer 856 constitutes a topmost horizontal surface of the second dielectric isolation layer 712, and can be located within the second horizontal plane (such as the horizontal plane HP) including the topmost surface of the semiconductor fin 730.

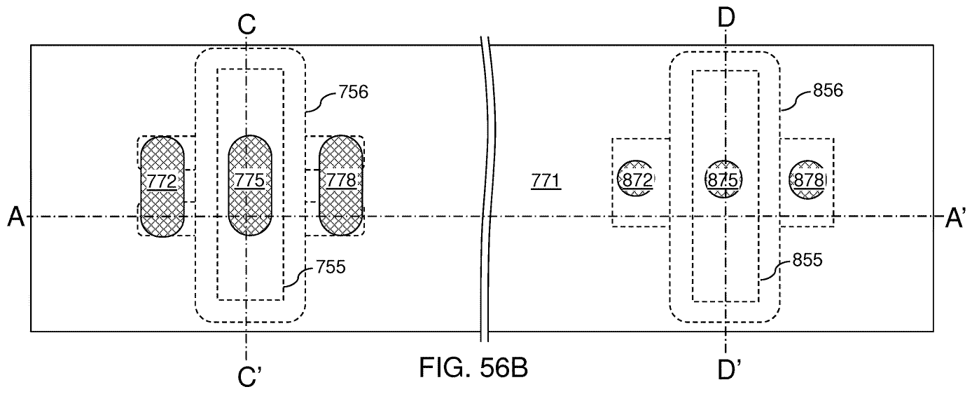

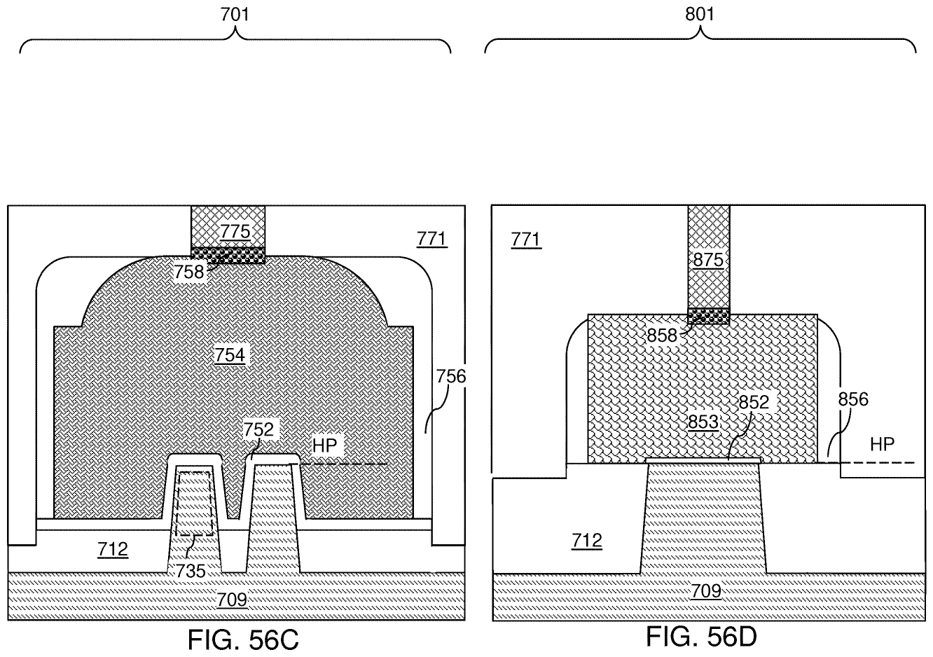

Referring to FIG. 56A-56D, the processing steps described with reference to FIG. 27A-27C can be performed to form a contact-level dielectric layer 771. The processing steps described with reference to FIG. 28A-28C can be performed to form various contact via structures (772, 775, 778, 872, 875, 878).

Subsequently, the processing steps described with reference to FIG. 30 can be performed to form logic-side metal interconnect structures 780 embedded within logic-side dielectric material layers 760 over the fin field effect transistors 702 and the planar field effect transistors 802 of the third exemplary structure. A logic die 700 is thus provided.

A memory die 900 can be provided, for example, by performing the processing steps described with reference to FIG. 1-13. The memory die 900 comprises a three-dimensional memory device and memory-side metal interconnect structures 980 and memory-side bonding pads 988 embedded within memory-side dielectric material layers 960 as described above.

The processing steps described with reference to FIG. 31 can be performed to bond the logic die 700 to the memory die 900, and thus, to form a bonded assembly. The logic die 700 comprises logic-side bonding pads 788 embedded within logic-side dielectric material layers 760; and the memory die 900 comprises memory-side bonding pads 988 that are embedded within memory-side dielectric material layers 960 and bonded to the logic-side bonding pads 788.

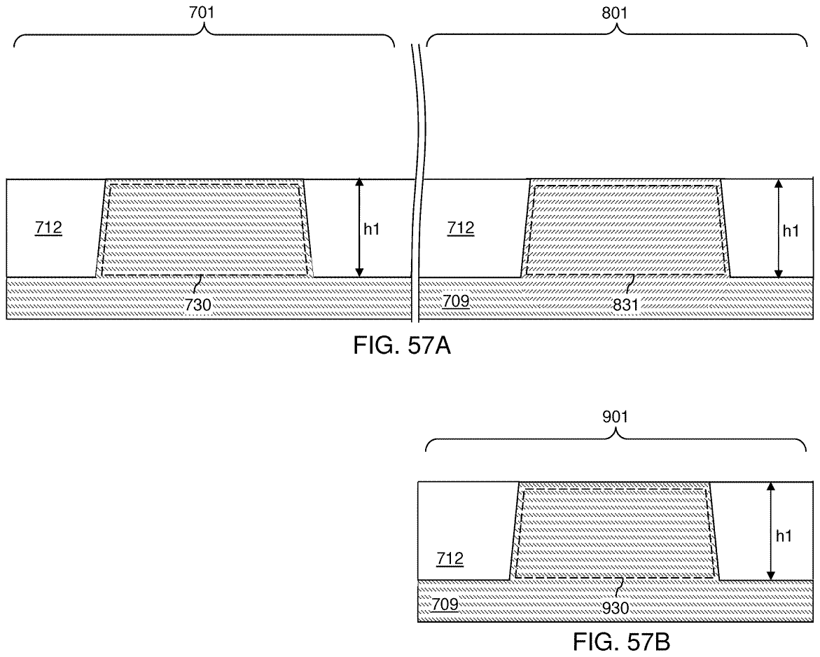

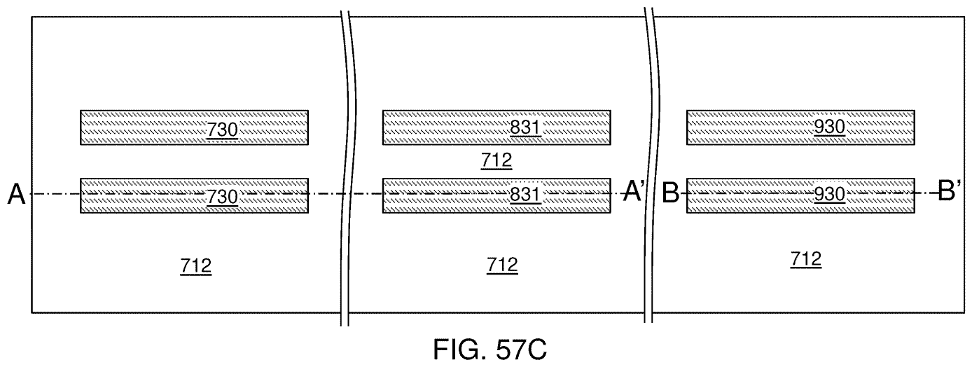

Referring to FIG. 57A-57C, a fifth exemplary structure according to an embodiment of the present disclosure is illustrated, which can be derived from the first exemplary structure illustrated in FIGS. 15A and 15B by forming first additional semiconductor fins 831 in lieu of a semiconductor active region 830 in the second device region 810, and by forming second additional semiconductor fins 930 in a third device region 910. The first additional semiconductor fins 831 and the second additional semiconductor fins 930 may be formed concurrently with formation of the semiconductor fins 730, and may have the same configuration as the semiconductor fins 730. The lateral dimensions (such as the lengths and the widths) of the first additional semiconductor fins 831 and the second additional semiconductor fins 930 may be adjusted as needed.

The fifth exemplary structure may be formed by forming the patterned hard mask layer 762 over a semiconductor substrate (such as a logic-side substrate 709) comprising a first device region 701 and a second device region 801, as described above with respect to FIGS. 34A, 34B, 35A and 35B, as well as the third device region 901. Moat trenches, such as portions of the continuous recess trench 711, can be formed in an upper portion of the semiconductor substrate 709 using the patterned hard mask layer 762 as a mask, as described above with respect to FIGS. 35A and 35B. The moat trenches comprise a first moat trench 711 that is formed in the first device region 701 and laterally surrounds the semiconductor fins 730, a second moat trench 711 that is formed in the second device region 801 and laterally surrounds the first additional semiconductor fins 831, and a third moat trench 711 that is formed in the third device region 901 and laterally surrounds the second additional semiconductor fins 930. The corners of all of the semiconductor fins 730, 831 and 930 may then be rounded by forming the sacrificial semiconductor oxide layers 751, as described above with respect to FIGS. 38A and 38B.

A dielectric trench fill material can be deposited in the moat trenches 711 to form the dielectric isolation layers 712, as described above with respect to FIGS. 36A and 36B. A first dielectric isolation layer 712 laterally surrounds the semiconductor fins 730, a second dielectric isolation layer 712 laterally surrounds the first additional semiconductor fins 831, and a third dielectric isolation layer 712 laterally surrounds the second additional semiconductor fins 930. The patterned hard mask layer 762 is then removed by selective etching, as described above with respect to FIGS. 39A and 39B. The dielectric isolation layers 712 are then planarized by chemical mechanical polishing to have top surfaces in the same horizontal plane as the top surfaces of all of the semiconductor fins 730, 831 and 930. Each of the first dielectric isolation layer 712, the second dielectric isolation layer 712, and the third dielectric isolation layer 712 may have a first height h1.

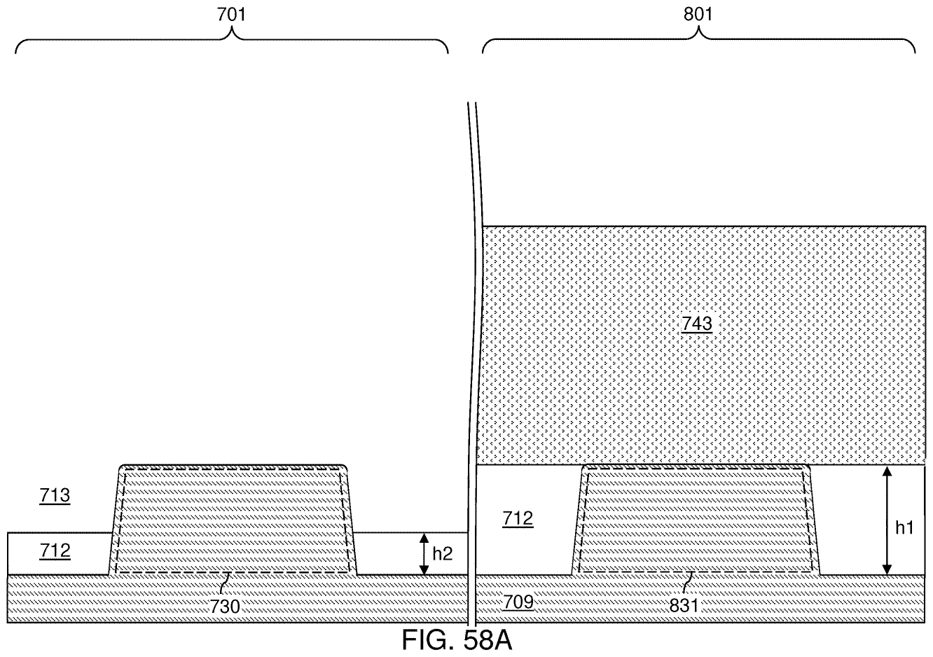

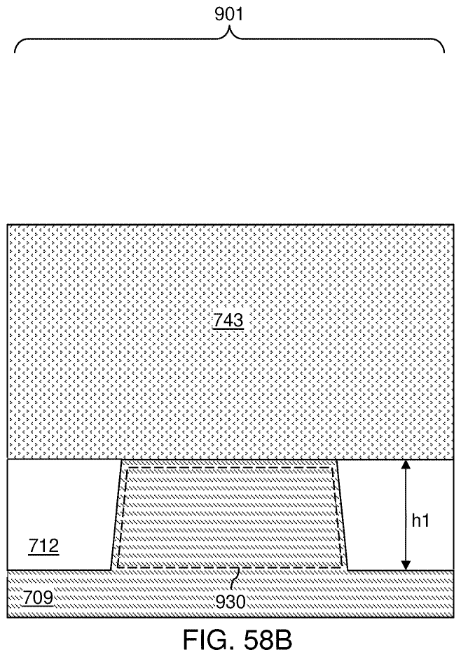

Referring to FIGS. 58A and 58B, a first photoresist layer 743 can be applied over the fifth exemplary structure, and can be lithographically patterned to cover the second device region 801 and the third device region 901 without covering the first device region 701. A first selective etch process can be performed to vertically recess the top surface of the first dielectric isolation layer 712. The first dielectric isolation layer 712 may have a second height h2 which is less than the first height hd1. The first photoresist layer 743 can be subsequently removed, for example, by ashing.

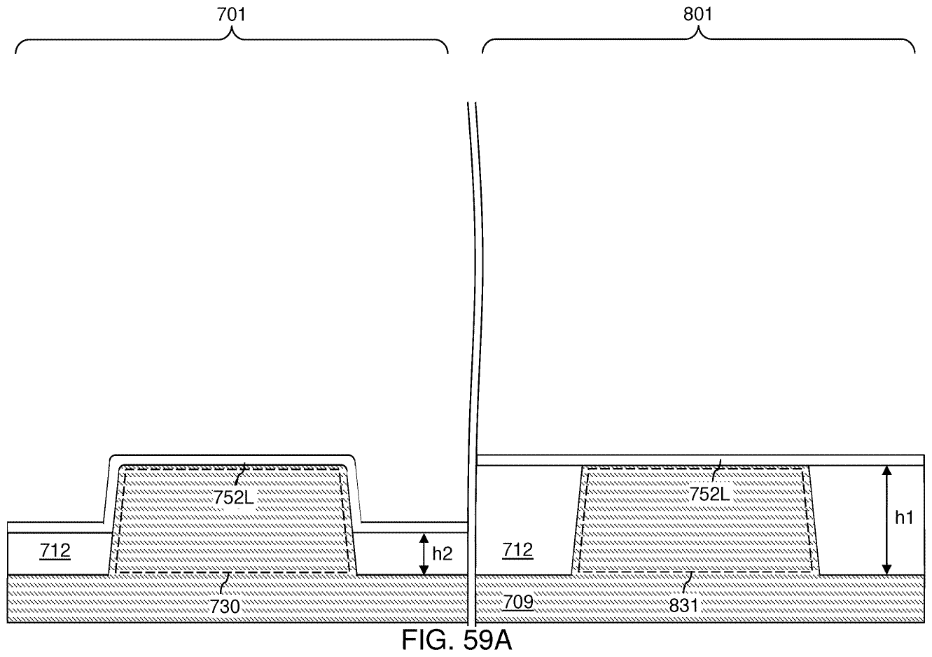

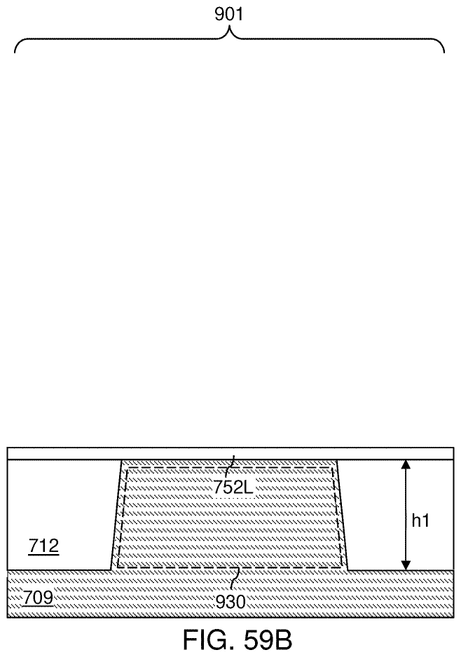

Referring to FIGS. 59A and 59B, the processing steps described with reference to FIGS. 40A and 40B can be performed to form a first gate dielectric layer 752L.

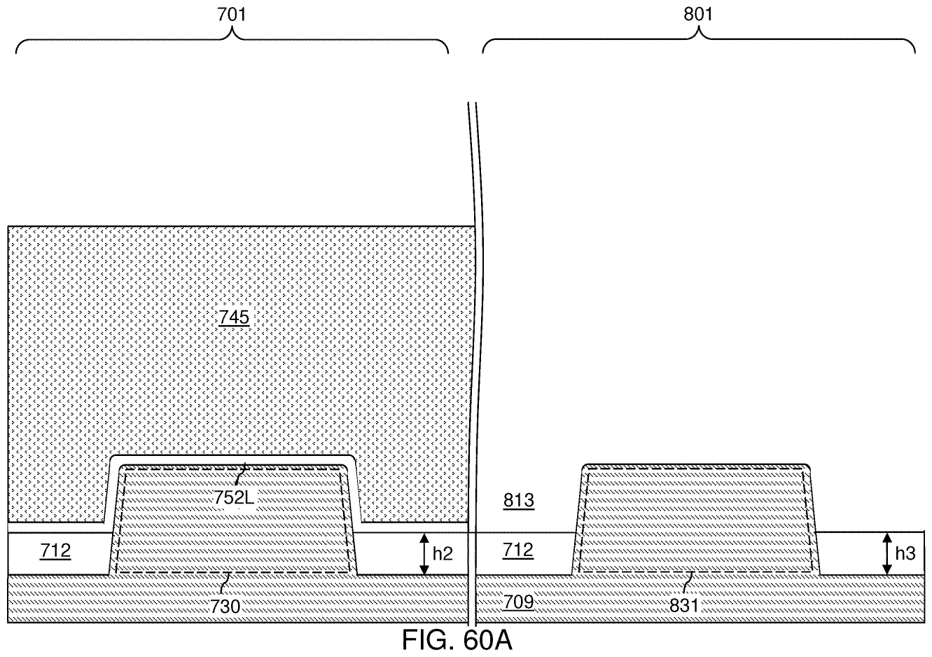

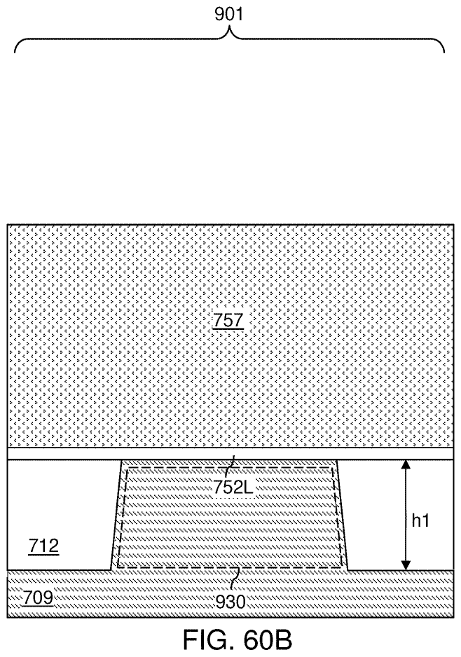

Referring to FIGS. 60A and 60B, a second photoresist layer 745 can be applied over the fifth exemplary structure, and can be lithographically patterned to cover the first device region 701 and the third device region 901 without covering the second device region 801. A second selective etch process can be performed to remove unmasked portions of the first gate dielectric layer 752L in the second device region 801 and to vertically recess the top surface of the second dielectric isolation layer 712. The second dielectric isolation layer 712 may have a third height h3 which is less than the first height hd1. The second photoresist layer 745 can be subsequently removed, for example, by ashing. A second gate cavity 813 can be formed around the upper portions of the second semiconductor fins 831.

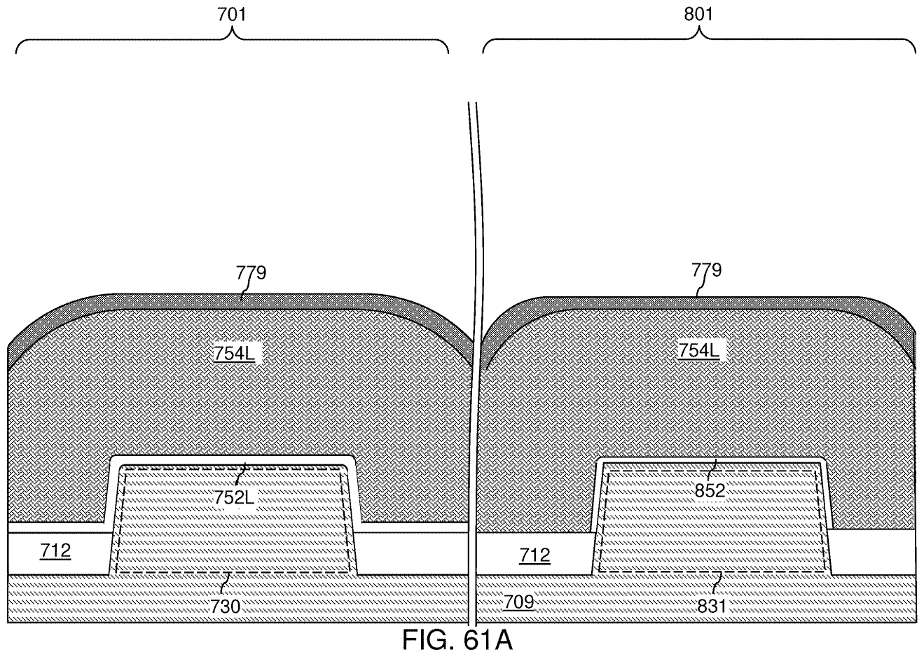

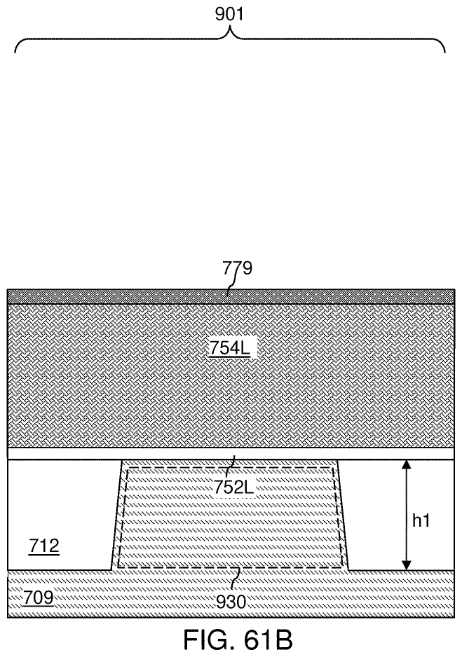

Referring to FIGS. 61A and 61B, a second gate dielectric 852 can be formed on the physically exposed surfaces of the second semiconductor fins 831, for example, by performing a surface oxidation process. The second gate dielectric 852 may be thinner than the first gate dielectric layer 752L. A first gate electrode material layer 754L can be formed by deposition of a first gate electrode material. The first gate electrode material layer 754L may have any material composition that may be employed for the finFET gate electrode material layer 754L described with reference to the first through fourth exemplary structures. For example, the first gate electrode material layer 754L may comprise n-type polysilicon, such as phosphorus and/or arsenic doped polysilicon. An etch stop dielectric layer 779, such as a silicon nitride layer, may be formed on a top surface of the first gate electrode material layer 754L.

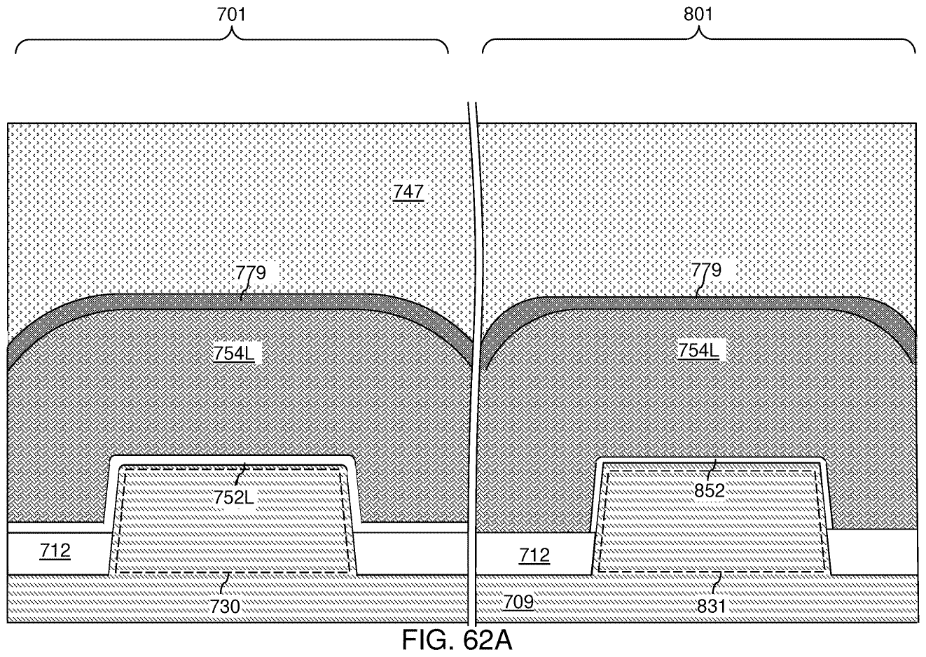

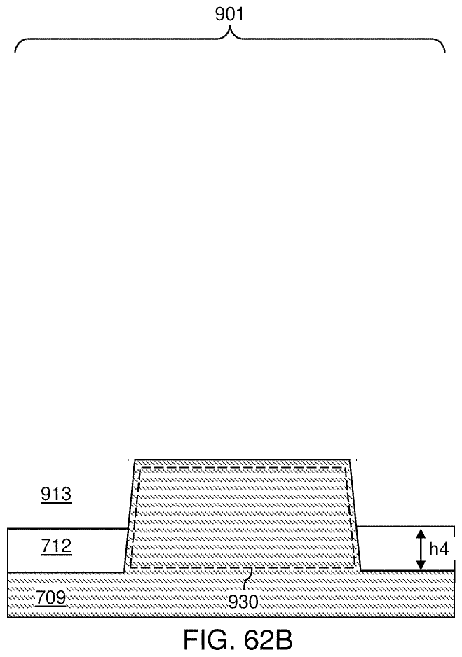

Referring to FIGS. 62A and 62B, a third photoresist layer 747 can be applied over the fifth exemplary structure, and can be lithographically patterned to cover the first device region 701 and the second device region 801 without covering the third device region 901. An etch process can be performed to remove unmasked portions of the etch stop dielectric layer 779 and the first gate electrode material layer 754L from the third device region 901. Subsequently, a third selective etch process can be performed to remove the unmasked portions of the first gate dielectric layer 752L in the third device region 901 and to vertically recess the top surface of the third dielectric isolation layer 712 in the third device region 901. The third dielectric isolation layer 712 may have a fourth height h4 which is less than the first height h1. The third photoresist layer 747 can be subsequently removed, for example, by ashing. A third gate cavity 913 can be formed around the upper portions of the third semiconductor fins 930.

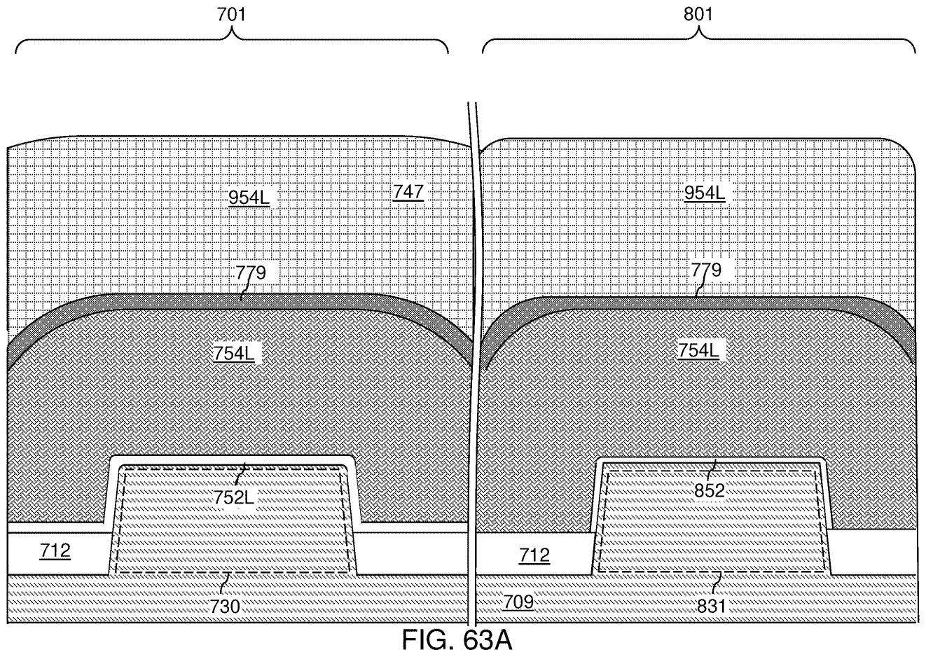

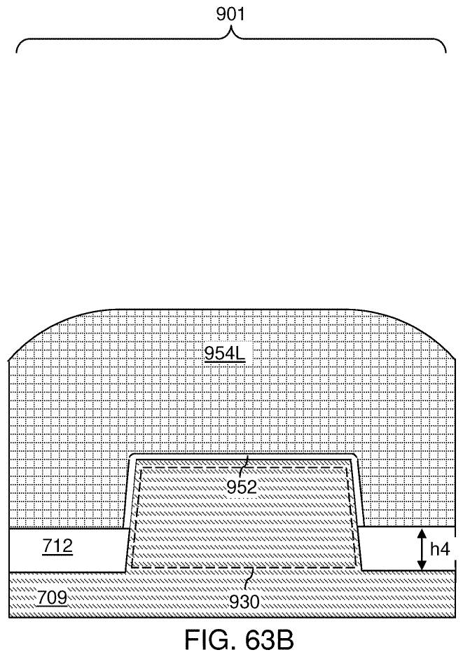

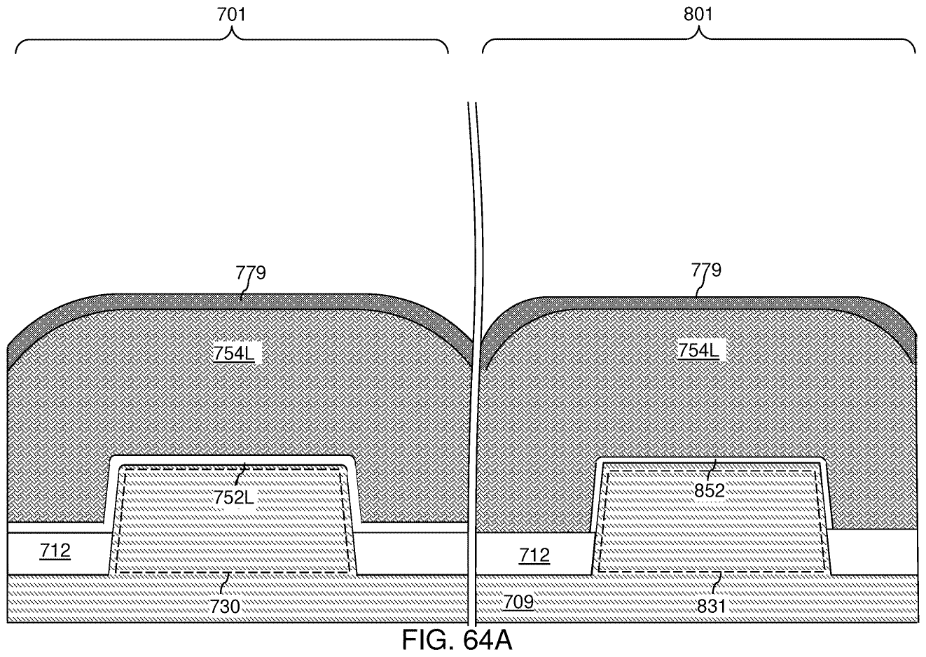

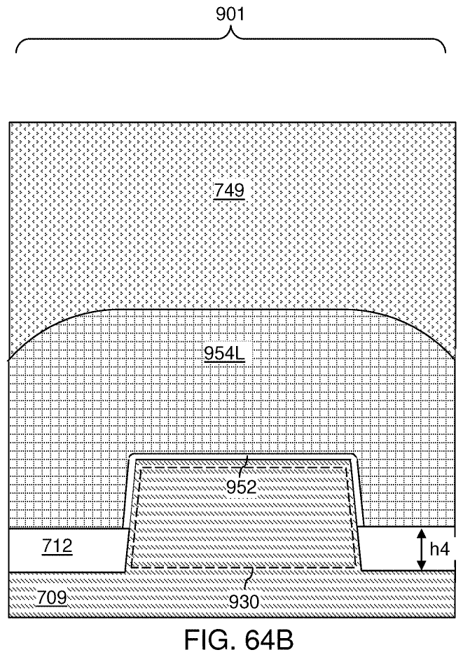

Referring to FIGS. 63A and 63B, a third gate dielectric 952 can be formed on the physically exposed surfaces of the third semiconductor fins 930, for example, by thermal surface oxidation of the semiconductor material of the third semiconductor fins 930. For example, the third gate dielectric 952 may comprise silicon oxide if the third semiconductor fins 930 comprise silicon. The third gate dielectric 952 may be thinner than the first gate dielectric layer 752L. A second gate electrode material layer 954L including a second gate electrode material can be formed over the third gate dielectric 952 and over the first gate electrode material layer 754L and the etch stop dielectric layer 779. The second gate electrode material layer 954L may have an opposite doping type to the doping type of the first gate electrode material layer 754L. For example, the second gate electrode material layer 954L may comprise p-type polysilicon, such as boron doped polysilicon.

Referring to FIGS. 64A and 64B, a fourth photoresist layer 749 can be applied over the fifth exemplary structure, and can be lithographically patterned to cover the third device region 901 without covering the first device region 701 or the second device region 801. Unmasked portions of the second gate electrode material layer 954L and the etch stop dielectric layer 779 can be removed without removing the first gate electrode material layer 754L. The fourth photoresist layer 749 can be subsequently removed, for example, by ashing.

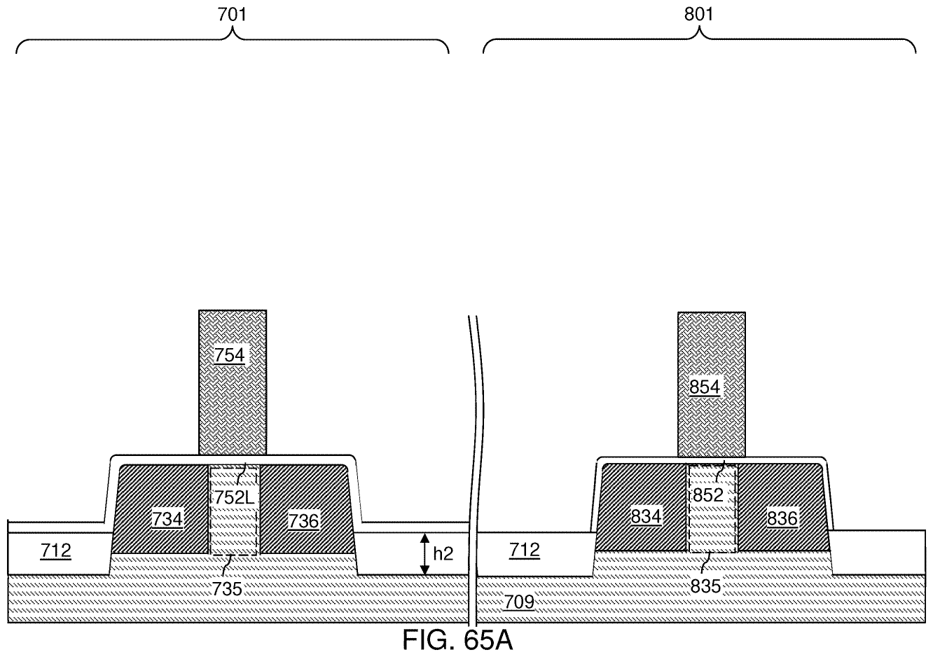

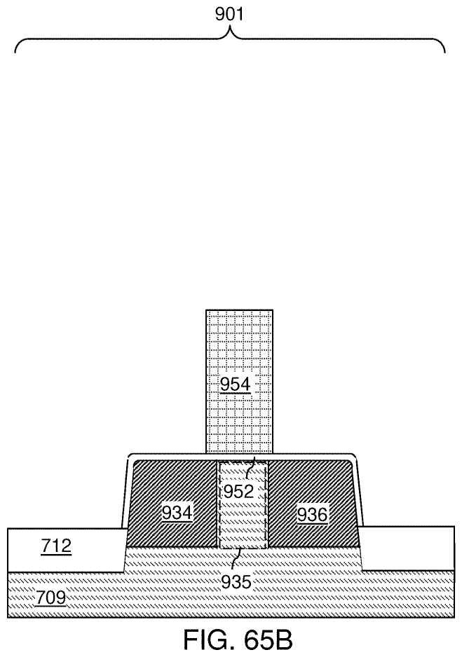

Referring to FIGS. 65A and 65B, a photoresist layer (not shown) can be applied over the fifth exemplary structure, and can be lithographically patterned into photoresist material portions having a pattern of gate electrodes. An anisotropic etch process can be performed to etch semiconductor materials of gate electrode material layers (754L, 954L) selective to the dielectric materials of the first gate dielectric layer 752L, the second gate dielectric 852 the third gate dielectric 952, and the dielectric isolation layers 712. Patterned portion of the first gate electrode material layer 754L comprises a first gate electrode 754 and a second gate electrode 854 in regions 701 and 801, respectively, and a patterned portion of the second gate electrode material layer 954L comprises a third gate electrode 954 in region 901.

The processing steps described with reference to FIG. 20A-20C can be performed with suitable modifications, which may comprise use of suitable patterned block-level ion implantation masks, to form various finFET source/drain extension regions, which may comprise first source/drain extension regions (734, 736), second source/drain extension regions (834, 836), and third source/drain extension regions (934, 936). Various fin channel regions can be provided, which comprise first fin channel regions 735, second fin channel regions 835, and third fin channel regions 935.

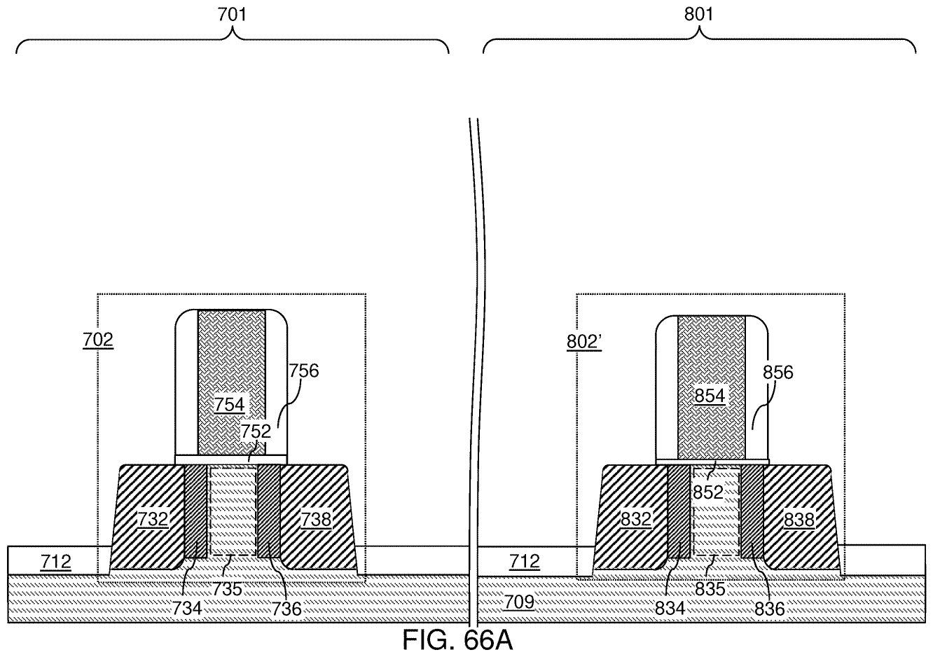

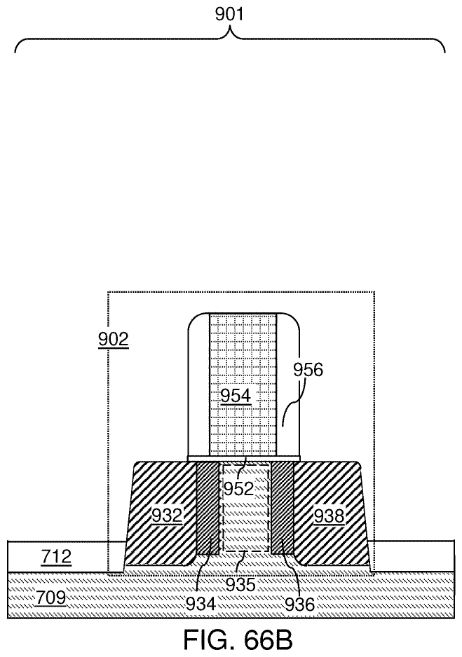

Referring to FIGS. 66A and 66B, the processing steps described with reference to FIGS. 25A and 25B can be performed, optionally with at least one suitable patterned block-level photoresist layer, to implant dopants into portions of the semiconductor fins (730, 831, 930) that are not masked by the gate electrodes (754, 854, 954) and the dielectric gate spacers (756, 856, 956). Source/drain regions are formed in the implanted portions of the semiconductor fins (730, 831, 930). The source/drain regions comprise at least one first finFET source region 732, at least one first finFET drain region 738, at least one second finFET source region 832, at least one second finFET drain region 838, at least one third finFET source region 932, and at least one third finFET drain region 938. A first finFET 702 is formed in the first device region 701, a second finFET 802′ is formed in the second device region 801, and a third finFET 902 is formed in the third device region 901.

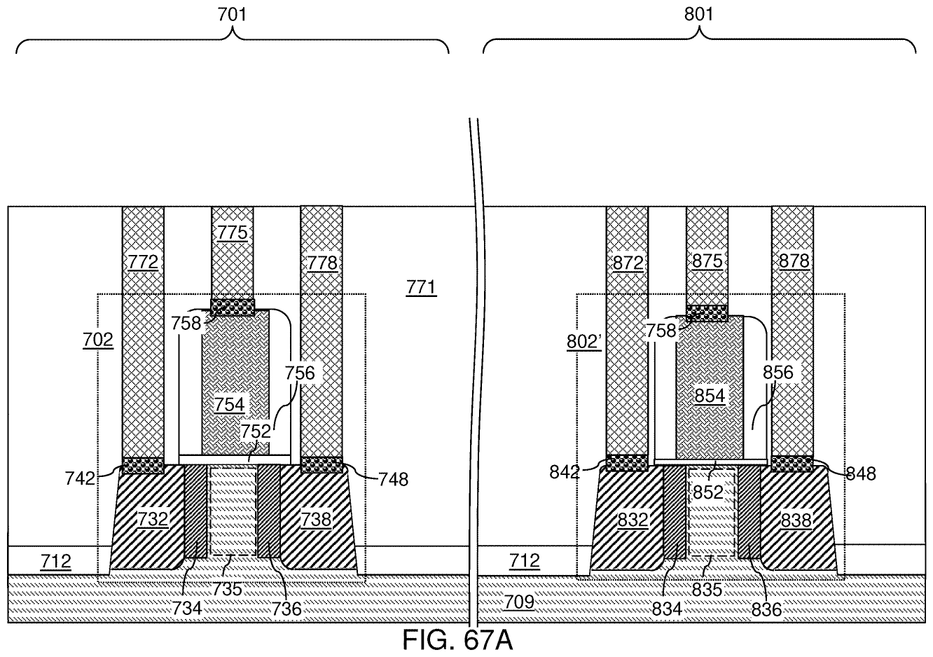

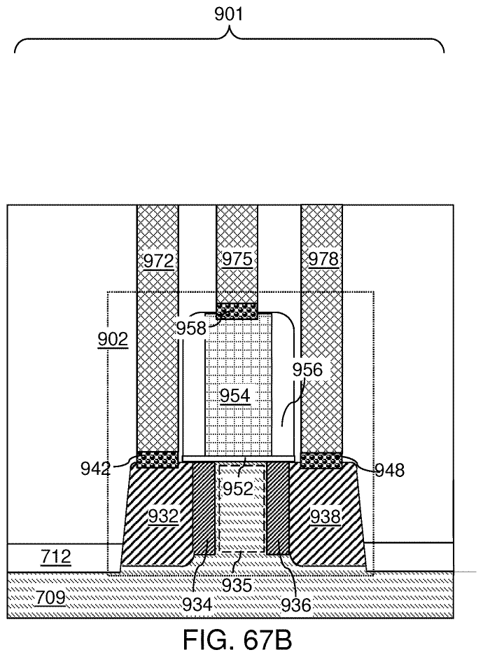

Referring to FIGS. 67A and 67B, the processing steps described with reference to FIG. 27A-27C can be performed to form a contact-level dielectric layer 771. Various contact via cavities can be formed through the contact-level dielectric layer 771, and metal-semiconductor alloy regions (742, 748, 842, 848, 942, 948) can be formed at the bottom of the via cavities. Various contact via structures (772, 775, 778, 872, 875, 878) can be formed in the various via cavities.

Subsequently, the processing steps described with reference to FIG. 30 can be performed to form logic-side metal interconnect structures 780 embedded within logic-side dielectric material layers 760 over the fin field effect transistors 702, 702′ and 902. A logic die 700 is thus provided.

A memory die 900 can be provided, for example, by performing the processing steps described with reference to FIG. 1-13. The memory die 900 comprises a three-dimensional memory device and memory-side metal interconnect structures 980 and memory-side bonding pads 988 embedded within memory-side dielectric material layers 960 as described above.

The processing steps described with reference to FIG. 31 can be performed to bond the logic die 700 to the memory die 900, and thus, to form a bonded assembly. In one embodiment, the logic die 700 comprises logic-side bonding pads 788 embedded within logic-side dielectric material layers 760; and the memory die 900 comprises memory-side bonding pads 988 that are embedded within memory-side dielectric material layers 960 and bonded to the logic-side bonding pads 788.

In one embodiment, the fifth exemplary structure comprises a first fin field effect transistor 702 having a first finFET gate electrode 754 comprising a first gate electrode material and comprising a first gate dielectric 752 having a first thickness; a first additional fin field effect transistor 802′ comprising a second finFET gate electrode 854 comprising the same first gate electrode material and comprising a second gate dielectric having a second gate dielectric thickness that is different from (e.g., smaller than) the first gate dielectric thickness; and a second additional fin field effect transistor 902 comprising a third finFET gate electrode 954 comprising a second gate electrode material different from the first gate electrode material, and comprising a third gate dielectric 952 having a third gate dielectric thickness (e.g., smaller than) that is different from the first gate dielectric thickness and optionally different than (e.g., smaller than) the second gate dielectric thickness.

In one embodiment, the first fin field effect transistor 702 may comprise a high voltage p-type or n-type transistor, the second fin field effect transistor 802 may comprise a low voltage p-type or n-type transistor or a very low voltage n-type transistor (e.g., having n-type source and drain regions and a p-type channel region), and the third fin field effect transistor 702 may be comprise a very low voltage p-type transistor (e.g., having p-type source and drain regions and a n-type channel region).

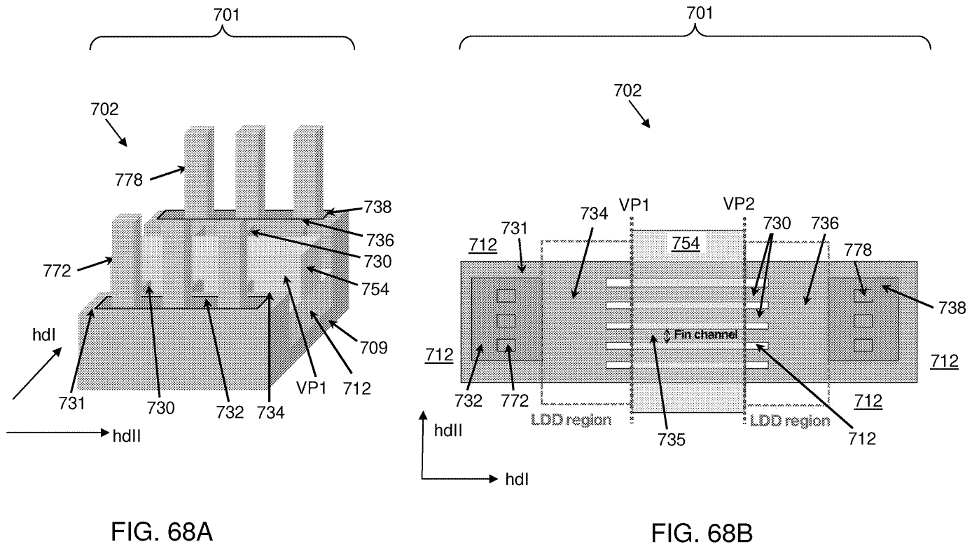

FIGS. 68A and 68B illustrate a sixth exemplary structure according to another embodiment of the present disclosure. The sixth exemplary structure may be derived from the finFET 702 of the first exemplary structure illustrated in FIG. 29A-29C by forming a finFET source/drain extension regions (734, 736) that are located in finFET semiconductor active region 731 and that contact ends of plural semiconductor fins 730. The second device region 801 may also be present in the sixth exemplary structure, but is not illustrated in FIGS. 68A and 68B for simplicity.

Referring to FIG. 68B, the first device region 701 of the sixth exemplary structure may include a finFET semiconductor active region 731 that is surrounded by the dielectric isolation layer 712. In one embodiment, the finFET semiconductor active region 731 may have the same doping type as the semiconductor active region 830, which may be a doping of a first conductivity type, which may be p-type or n-type. The atomic concentration of dopants in the finFET semiconductor active region 731 may be in a range from 1.0×10¹⁴/cm³ to 3.0×10¹⁷/cm³, such as from 1.0×10¹⁵/cm³ to 1.0×10¹⁷/cm³, although lesser and greater atomic concentrations of dopants of the first conductivity type may also be employed. In one embodiment, the entirety of the logic-side substrate 709, the finFET semiconductor active region 731 and the semiconductor active region 830 may be single crystalline (e.g., single crystal silicon), and may be epitaxially aligned to each other with a same set of crystallographic orientations throughout.

The finFET semiconductor active region 731 may be patterned to include a plurality of the above described semiconductor fins 730. In the sixth exemplary structure, the semiconductor fins 730 extend along the first horizontal direction hdI (i.e., have sidewalls parallel to the first horizontal direction), and the finFET gate electrode 754 extends along the second horizontal direction hdII that is perpendicular to the first horizontal direction, as in the first exemplary structure. The semiconductor fins 730 are spaced apart from each other along the second horizontal direction hdII by portions of the dielectric isolation layer 712. However, in the sixth exemplary structure, the semiconductor fins 730 extend only partially into the lightly doped finFET source/drain extension regions (734, 736) along the first horizontal direction hdI. Thus, the semiconductor fins 730 do not reach the heavily doped finFET source and drain regions (732, 738), and the semiconductor fins 730 protrude only slightly beyond the vertical planes (VP1, VP2) that include the sidewalls of the finFET gate electrode 754 that extend along the second horizontal direction hdII. Each finFET source extension region 734 contacts and connects first ends of plural semiconductor fins 730, and each finFET drain extension region 736 contacts and connects opposing second ends of plural semiconductor fins 730. In the sixth exemplary structure, the lightly doped finFET source/drain extension regions (734, 736) comprise LDD (lightly doped drain) regions formed in a relatively large finFET semiconductor active region 731. Thus, the finFET source/drain extension region (734, 736) resistance is reduced, resulting in a higher on-current (I_{ON}) for the finFET 702 of the sixth exemplary structure.

The finFET 702 of the sixth exemplary structure may also include the above described finFET channel regions 735, finFET gate dielectric (e.g., first gate dielectric) 752, metal-semiconductor alloy regions (e.g., metal silicide regions) (742, 748, 758), gate-level dielectric layer 770, contact-level dielectric layer 771 and contact via structures (775, 772, 778), as in the first exemplary structure. Furthermore, the second device region 801 containing the planar FET 802 may also be formed in the sixth exemplary structure, in the same manner as in the first exemplary structure. Although multiple square contacts (778) are illustrated herein, a single or multiple rectangular contacts may alternatively be provided.

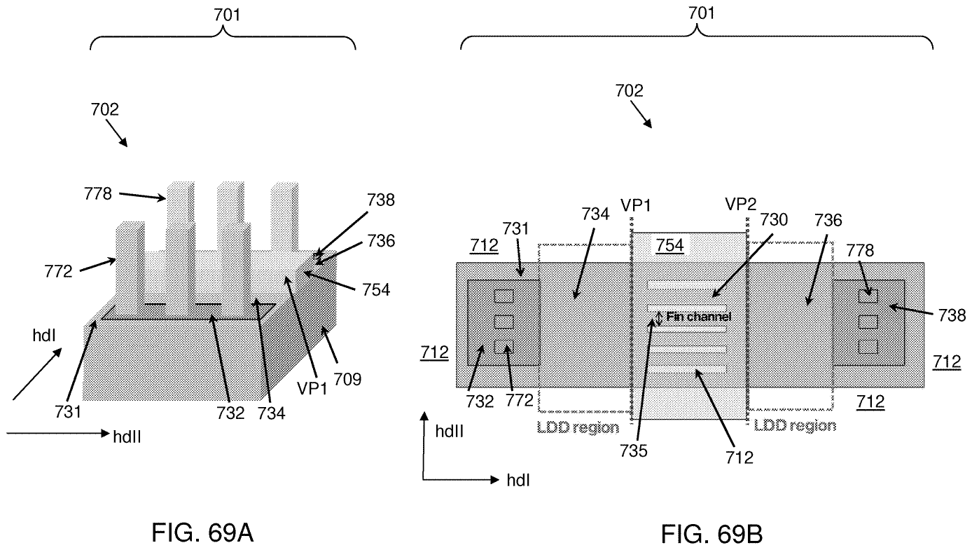

FIGS. 69A and 69B illustrate a seventh exemplary structure according to another embodiment of the present disclosure. The seventh exemplary structure may be derived from the finFET 702 of the sixth exemplary structure illustrated in FIGS. 68A and 68B by shortening the length of the semiconductor fins 730 along the first horizontal direction hdI. In the seventh exemplary structure, the semiconductor fins 730 are located only under the finFET gate electrode 754. Thus, the semiconductor fins 730 do not reach the heavily doped finFET source and drain regions (732, 738), and the semiconductor fins 730 do not protrude beyond the vertical planes (VP1, VP2) that include the sidewalls of the finFET gate electrode 754 that extend along the second horizontal direction hdII. Thus, the respective first and second ends of the semiconductor fins 730 contact the sidewalls of the respective lightly doped finFET source/drain extension regions (734, 736) in or slightly inward of the vertical planes (VP1, VP2) that include the sidewalls of the finFET gate electrode 754. In other words, the implanted and activated (i.e., annealed) finFET source/drain extension regions (734, 736) extend slightly under the finFET gate electrode 754 along the first horizontal direction and contact the ends of the semiconductor fins 730 and the finFET channel regions 735 located therein. The seventh exemplary structure also improves the on-current of the finFET 702.

The finFET 702 of the sixth and seventh exemplary structures may be formed using the same steps as those shown in FIG. 14A-29C of the first exemplary structure, with a modification to the shape of the photolithography mask used to form the continuous recess cavity 711. In the sixth exemplary structure, the mask used to form the continuous recess cavity 711 in FIGS. 14A and 14B covers a portion of the logic-side substrate 709 that is used to form the finFET active region 731. Furthermore, dopants are implanted into the finFET active region 731 using the finFET gate electrode 754 as a mask as described above with respect to FIG. 20A-20C, to form the continuous finFET source/drain extension regions (734, 736) that connect respective ends of a plurality of semiconductor fins 730.

Referring to the sixth and seventh exemplary structures, a semiconductor structure (700, 900) comprises a logic die 700 containing a fin field effect transistor (finFET) 702, and a memory die 900 bonded to the logic die 700, wherein the memory die 900 comprises a three-dimensional memory device (32, 46, 58). The finFET 702 comprises at least one semiconductor fin 730 extending along a first horizontal direction hdI; a finFET channel region 735 located in the at least one semiconductor fin 730; a finFET source extension region 734 contacting the finFET channel region; a finFET drain extension region 736 contacting the finFET channel region 735; a finFET source region 732 contacting the finFET source extension region 734; a finFET drain region 738 contacting the finFET drain extension region 736; a finFET gate electrode 754 overlying the finFET channel region 735; and a finFET gate dielectric 752 located between the finFET channel region 735 and the finFET gate electrode 754.

In one embodiment, the at least one semiconductor fin 730 comprises plural semiconductor fins 730 extending along the first horizontal direction hdI and separated from each other along a second horizontal direction hdII perpendicular to the first horizontal direction hdI. In one embodiment, the finFET source extension region 734 contacts first ends of the plural semiconductor fins 730, and the finFET drain extension region 736 contacts opposing second ends of the plural semiconductor fins 730. In one embodiment, the plural semiconductor fins 730 do not contact the finFET source region 732 or the finFET drain region 738.

In one embodiment, the finFET gate electrode 754 extends along the second horizontal direction hdII and has sidewalls located in first and second vertical planes (VP1, VP2) that extend parallel to the second horizontal direction hdII. In the sixth exemplary structure shown in FIG. 68B, the plural semiconductor fins 730 extend through the first and second vertical planes (VP1, VP2) along the first horizontal direction hdI. In the seventh exemplary structure shown in FIG. 69B, the plural semiconductor fins 730 are located entirely under the finFET gate electrode 754 and do not extend through the first and second vertical planes (VP1, VP2) along the first horizontal direction hdI.

In one embodiment, the finFET channel 735 has a doping of a first conductivity type (e.g., p-type or n-type), the finFET source and drain regions (732, 738) have a doping of a second conductivity type (e.g., n-type or p-type) opposite to the first conductivity type, and the finFET source and drain extension regions (734, 736) have a doping of the second conductivity type at a lower concentration than the finFET source and drain regions (732, 738). In one embodiment, the logic die 700 further comprises a finFET semiconductor active region 731 having a doping of the first conductivity type, and the finFET 702 is located in the finFET active region 702.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A semiconductor structure, comprising:
a logic die containing a fin field effect transistor (finFET) comprising:
at least one semiconductor fin extending along a first horizontal direction;
a finFET channel region located in the at least one semiconductor fin;
a finFET source extension region contacting the finFET channel region;
a finFET drain extension region contacting the finFET channel region;
a finFET source region contacting the finFET source extension region;
a finFET drain region contacting the finFET drain extension region;
a finFET gate electrode overlying the finFET channel region; and
a finFET gate dielectric located between the finFET channel region and
the finFET gate electrode; and
a memory die bonded to the logic die, wherein the memory die comprises a three-dimensional memory device.

2. The semiconductor structure of claim 1, wherein the at least one semiconductor fin comprises plural semiconductor fins extending along the first horizontal direction and separated from each other along a second horizontal direction perpendicular to the first horizontal direction.

3. The semiconductor structure of claim 2, wherein:
the finFET source extension region contacts first ends of the plural semiconductor fins; and
the finFET drain extension region contacts opposing second ends of the plural semiconductor fins.

4. The semiconductor structure of claim 3, wherein the plural semiconductor fins do not contact the finFET source region or the finFET drain region.

5. The semiconductor structure of claim 4, wherein the finFET gate electrode extends along the second horizontal direction and has sidewalls located in first and second vertical planes that extend parallel to the second horizontal direction.

6. The semiconductor structure of claim 5, wherein the plural semiconductor fins extend through the first and second vertical planes along the first horizontal direction.

7. The semiconductor structure of claim 5, wherein the plural semiconductor fins are located entirely under the finFET gate electrode and do not extend through the first and second vertical planes along the first horizontal direction.

8. The semiconductor structure of claim 5, wherein the finFET channel has a doping of a first conductivity type, the finFET source and drain regions have a doping of a second conductivity type opposite to the first conductivity type, and the finFET source and drain extension regions have a doping of the second conductivity type at a lower concentration than the finFET source and drain regions.

9. The semiconductor structure of claim 8, wherein the logic die further comprises a finFET semiconductor active region having a doping of the first conductivity type, and the finFET is located in the finFET semiconductor active region.

10. The semiconductor structure of claim 9, wherein the logic die comprises a word line switching circuit that includes the finFET.

11. The semiconductor structure of claim 10, wherein the logic die further comprises a planar field effect transistor.

12. The semiconductor structure of claim 11, wherein:
the finFET is located in a first device region of the logic die;
the finFET further comprises a dielectric isolation layer, wherein the finFET semiconductor active region is laterally surrounded by a first portion of the dielectric isolation layer, and a gate-level dielectric layer laterally surrounding the finFET gate electrode and having a planar top surface that is coplanar with a top surface of the first gate electrode;
the planar field effect transistor is located in a second device region of the logic die;
the planar field effect transistor comprises an active semiconductor region that is laterally surrounded by a second portion of the dielectric isolation layer, a second gate dielectric overlying a top surface of the active semiconductor region, and a second gate electrode overlying the second gate dielectric; and
the gate-level dielectric layer is not present within the second device region.

13. The semiconductor structure of claim 12, further comprising a contact-level dielectric layer having a first bottom surface contacting a top surface of the second portion of the dielectric isolation layer in the second device region and having a second bottom surface overlying the gate-level dielectric layer in the first device region.

14. The semiconductor structure of claim 13, further comprising a dielectric gate spacer that laterally surrounds the second gate electrode and having a different material composition than the gate-level dielectric layer.

15. The semiconductor structure of claim 13, wherein the gate-level dielectric layer continuously extends from each top surface of the finFET gate dielectric to a top surface of the first portion of the dielectric isolation layer.

16. The semiconductor structure of claim 13, wherein the gate-level dielectric layer continuously extends from sidewalls of the finFET gate electrode to a top surface of the first portion of the dielectric isolation layer.

17. The semiconductor structure of claim 13, wherein an entirety of a dielectric-to-dielectric interface containing the top surface of the second portion of the dielectric isolation layer is an interface between the top surface of the second portion of the dielectric isolation layer and the contact-level dielectric layer.

18. The semiconductor structure of claim 13, wherein an entirety of the top surface of the second portion of the dielectric isolation layer contacts the first bottom surface of the contact-level dielectric layer.

19. The semiconductor structure of claim 13, wherein:
the gate-level dielectric layer comprises at least one source opening overlying the finFET source region and at least one drain opening overlying the finFET drain region;
at least one first source contact via structure vertically extends through the at least one source opening and is electrically connected to the finFET source region; and
at least one first drain contact via structure vertically extends through the at least one drain opening and is electrically connected to the finFET drain region.

20. The semiconductor structure of claim 12, wherein:
the logic die comprises a logic-side semiconductor substrate;
the finFET semiconductor active region and the active semiconductor region comprise portions of the logic-side semiconductor substrate;
the logic die comprises logic-side bonding pads embedded within logic-side dielectric material layers; and
the memory die comprises memory-side bonding pads that are embedded within memory-side dielectric material layers and bonded to the logic-side bonding pads.
